(19) United States
(12) Patent Application Publication
(10) Pub. No.: US 2024/0425530 A1
(43) Pub. Date: Dec. 26, 2024

(54) ORGANIC COMPOUNDS AND ORGANIC LIGHT-EMITTING DEVICE COMPRISING THE SAME

(71) Applicant: SFC CO., LTD., Chungcheongbuk-do (KR)

(72) Inventors: Jin-hwi CHO, Chungcheongbuk-do (KR); So-Young SHIM, Chungcheongbuk-do (KR)

(21) Appl. No.: 18/658,215

(22) Filed: May 8, 2024

(30) Foreign Application Priority Data
May 30, 2023 (KR) 10-2023-0069255
May 7, 2024 (KR) 10-2024-0059724

(51) Int. Cl. C07F 7/08; C07B 59/00; C07F 7/30; C07F 11/00; C09K 11/02; C09K 11/06; H10K 50/12; H10K 85/40; H10K 85/60

(52) U.S. Cl. CPC C07F 7/0812; C07B 59/004; C07F 7/0816; C07F 7/30; C07F 11/00; C09K 11/02; C09K 11/06; H10K 50/12; H10K 85/40; H10K 85/615; H10K 85/653; H10K 85/655; H10K 85/656; H10K 85/6572; H10K 85/6574; H10K 85/6576; C07B 2200/05

(57) ABSTRACT

The present invention relates to an organic compound represented by the following [Formula 1], and an organic light emitting device having significantly improved low voltage driving and long lifetime and excellent luminous efficiency by employing the same as a light emitting layer host material in the device.

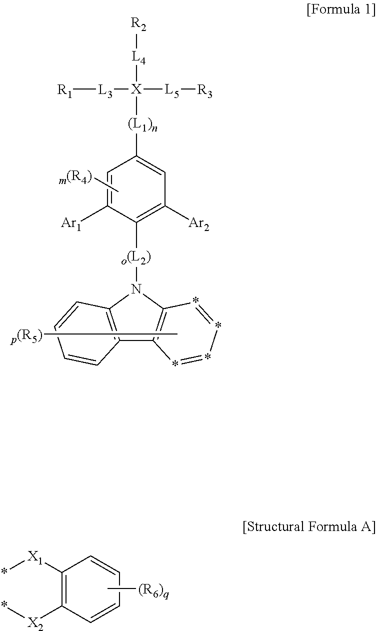

### CROSS-REFERENCE TO RELATED APPLICATIONS

This application claims benefit of Korean Patent Application Nos. 10-2023-0069255, filed May 30, 2023 and 10-2024-0059724, filed on May 7, 2024. The entire disclosure of the applications identified in this paragraph are incorporated herein by reference.

### TECHNICAL FIELD

The present invention relates to an organic compound employed in a light emitting layer of an organic light emitting device and an organic light emitting device including the organic compound.

### BACKGROUND ART

Organic light emitting devices are self-luminous devices in which electrons injected from an electron injecting electrode (cathode) recombine with holes injected from a hole injecting electrode (anode) in a light emitting layer to form excitons, which emit light while releasing energy. Such organic light emitting devices have the advantages of low driving voltage, high luminance, large viewing angle, and short response time and can be applied to full-color light emitting flat panel displays. Due to these advantages, organic light emitting devices have received attention as next-generation light sources.

The above characteristics of organic light emitting devices are achieved by structural optimization of organic layers of the devices and are supported by stable and efficient materials for the organic layers, such as hole injecting materials, hole transport materials, light emitting materials, electron transport materials, electron injecting materials, and electron blocking materials. However, more research still needs to be done to develop structurally optimized structures of organic layers for organic light emitting devices and stable and efficient materials for organic layers of organic light emitting devices.

Particularly, for maximum efficiency in a light emitting layer, an appropriate combination of energy band gaps of a host and a dopant is required such that holes and electrons migrate to the dopant through stable electrochemical paths to form excitons.

### DETAILED DESCRIPTION OF THF INVENTION

### Problems to be Solved by the Invention

Therefore, the present invention is intended to provide a host material with a specific structure for a light emitting layer and an organic light emitting device including the host material that can be driven at low voltage and has significantly long lifetime and improved luminous efficiency.

### Means for Solving the Problems

One aspect of the present invention provides an organic compound represented by the following [Formula 1], and an organic light emitting device including the same as a host in a light emitting layer.

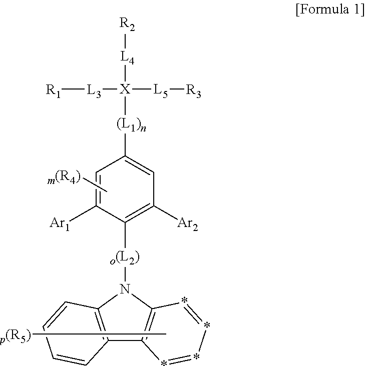

Two adjacent carbon atoms represented by * in [Formula 1] are linked to sites represented by * of the following [Structural Formula A] to form a ring.

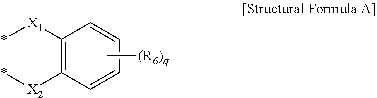

Specific structures of [Formula 1] and [Structural Formula A], specific compounds according to the present invention obtained therefrom, and a definition of each substituent will be described later.

### Effects of the Invention

The organic compound of the present invention has a structure in which specific silyl moieties are introduced to a specific fused carbazole-derived skeleton. The organic light emitting device of the present invention includes a light emitting layer employing the organic compound as a host. The use of the organic compound enables low voltage driving of the organic light emitting device and ensures significantly long lifetime and improved luminous efficiency of the device. Due to these advantages, the long-lasting and highly efficient organic light emitting device of the present invention can find useful applications in not only lighting systems but also a variety of displays, including flat panel displays, flexible displays, wearable displays, displays for virtual reality, and displays for augmented reality.

### BEST MODE FOR CARRYING OUT THF INVENTION

Hereinafter, the present invention will be described in more detail.

The present invention relates to a compound represented by the following [Formula 1].

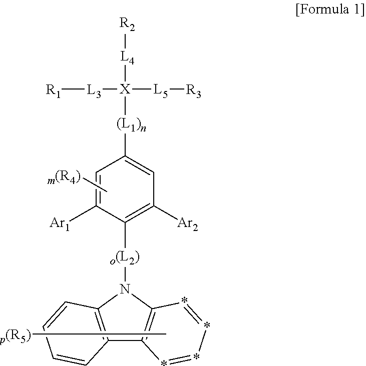

Two adjacent carbon atoms represented by * in [Formula 1] are linked to sites represented by * of the following [Structural Formula A] to form a ring, however, the remaining two *s in [Formula 1] not forming a ring are defined by R₅ substitution.

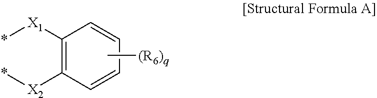

In [Formula 1] and [Structural Formula A],

X is Si or Ge.

R₁ to R₅ are the same as or different from each other, and each independently selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted amine, substituted or unsubstituted silyl, substituted or unsubstituted germanium, and cyano.

Ar₁ and Ar₂ are the same as or different from each other, and each independently selected from substituted or unsubstituted C₁-C₃₀ alkyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, and substituted or unsubstituted cyclic groups in which a C₃-C₃₀ aliphatic ring and a C₅-C₃₀ aromatic ring are fused together.

L₁ to L₅ are the same as or different from each other, and each independently a single bond, or selected from substituted or unsubstituted C₆-C₃₀ arylene, substituted or unsubstituted C₂-C₃₀ heteroarylene, and substituted or unsubstituted divalent cyclic groups in which a C₃-C₂₄ aliphatic ring and a C₅-C₂₄ aromatic ring are fused together.

X₁ and X₂ are the same as or different from each other, and each independently a single bond, or selected from O, S, Se, NR₇, CR₈R₉, SiR₁₀R₁₁ and GeR₁₂R₁₃.

R₆ to R₁₃ are the same as or different from each other, and each independently selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted amine, substituted or unsubstituted silyl, substituted or unsubstituted germanium, and cyano.

m is an integer of 2, and R₄s are the same as or different from each other.

p is an integer of 6, and R₅s are the same as or different from each other.

q is an integer of 4, and R₆s are the same as or different from each other.

n and o are an integer of 1 to 3, and when they are each an integer of 2 or greater, L₁s and L₂s are the same as or different from each other.

When X₁ is a single bond, one of the carbon atoms represented by * in [Formula 1] is linked to a carbon atom of benzene linked to X₁ in [Structural Formula A] through the single bond.

When X₂ is a single bond, one of the carbon atoms represented by * in [Formula 1] is linked to a carbon atom of benzene linked to X₂ in [Structural Formula A] through the single bond.

In addition, the adjacent plurality of R₅s and R₆s are optionally linked to each other to further form an alicyclic or aromatic monocyclic or polycyclic ring.

In addition, R₈ and R₉, R₁₀ and R₁₁, and R₁₂ are R₁₃ are optionally linked to each other to further form an alicyclic or aromatic monocyclic or polycyclic ring.

According to one embodiment of the present invention, in the compound according to the present invention, at least one or more deuterium atoms substitute in the organic compound represented by [Formula 1].

According to one embodiment of the present invention, Ar₁ and Ar₂ are the same as or different from each other, and may be each independently any one selected from substituted or unsubstituted C₆-C₃₀ aryl, substituted or unsubstituted C₂-C₃₀ heteroaryl, and substituted or unsubstituted cyclic groups in which a C₃-C₂₄ aliphatic ring and a C₅-C₂₄ aromatic ring are fused together.

According to one embodiment of the present invention, R₁ to R₃ are the same as or different from each other, and may be each independently any one selected from substituted or unsubstituted C₆-C₃₀ aryl, substituted or unsubstituted C₂-C₃₀ heteroaryl, and substituted or unsubstituted cyclic groups in which a C₃-C₂₄ aliphatic ring and a C₅-C₂₄ aromatic ring are fused together.

According to one embodiment of the present invention, at least one of X₁ and X₂ may be a single bond.

According to one embodiment of the present invention, at least one of X₁ and X₂ may be O or S.

According to one embodiment of the present invention, R₄ to R₆ are the same as or different from each other, and each independently hydrogen or deuterium.

As used herein, the term “substituted” in the definitions of Formula 1 and Structural Formula A indicates substitution with one or more substituents selected from deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl, and nitro, or a combination thereof. The term “unsubstituted” in the same definition indicates having no substituent. One or more hydrogen atoms in each of the substituents are optionally replaced by deuterium atoms and two or more adjacent ones of the substituents are optionally linked to each other to form an alicyclic or aromatic mono- or polycyclic ring.

According to one embodiment of the present invention, the organic compound represented by [Formula 1] is represented by the following [Formula 1-1] to [Formula 1-12].

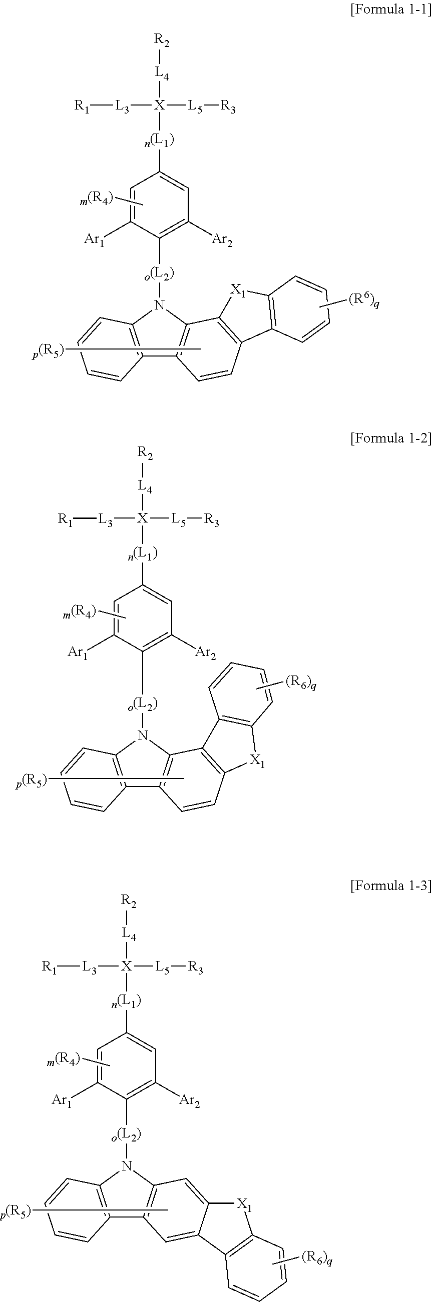

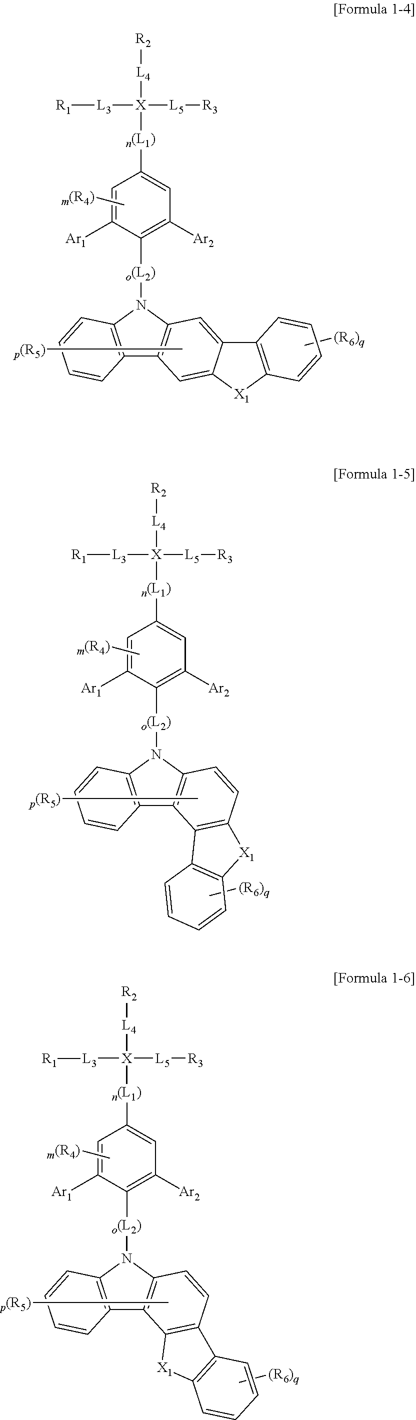

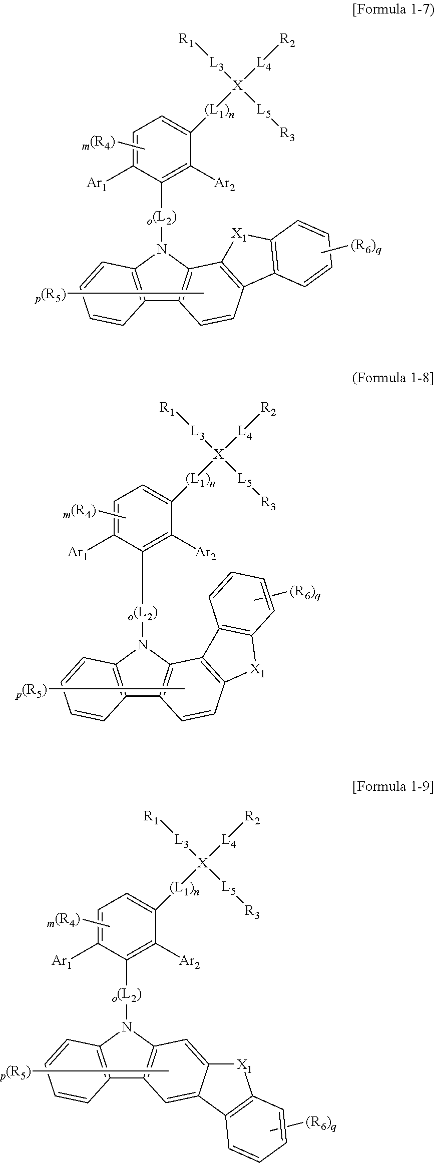

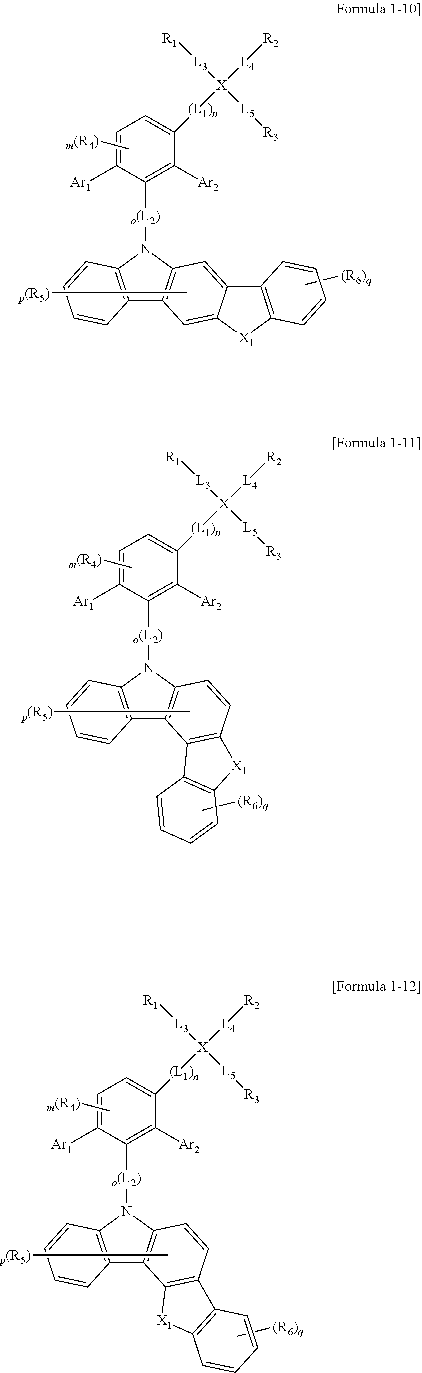

In [Formula 1-1] to [Formula 1-12],

X is Si or Ge.

X₁s are each independently any one selected from O, S, Se, NR₇, CR₈R₉, SiR₁₀R₁₁ and GeR₁₂R₁₃.

R₁ to R₁₃ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₃₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted amine, substituted or unsubstituted silyl, substituted or unsubstituted germanium, and cyano.

Ar₁ and Ar₂ are the same as or different from each other, and each independently any one selected from substituted or unsubstituted C₁-C₃₀ alkyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, and substituted or unsubstituted cyclic groups in which a C₃-C₃₀ aliphatic ring and a C₅-C₃₀ aromatic ring are fused together.

L₁ to L₅ are the same as or different from each other, and each independently a single bond, or any one selected from substituted or unsubstituted C₆-C₃₀ arylene, substituted or unsubstituted C₂-C₃₀ heteroarylene, and substituted or unsubstituted divalent cyclic groups in which a C₃-C₂₄ aliphatic ring and a C₅-C₂₄ aromatic ring are fused together.

m is an integer of 2, and R₄s are the same as or different from each other.

p is an integer of 6, and R₅s are the same as or different from each other.

q is an integer of 4, and R₆s are the same as or different from each other.

n and o are an integer of 1 to 3, and when they are each an integer of 2 or greater, L₁s and L₂s are the same as or different from each other.

The adjacent plurality of R₅s and R₆s are optionally linked to each other to further form an alicyclic or aromatic monocyclic or polycyclic ring.

R₈ and R₉, R₁₀ and R₁₁, and R₁₂ and R₁₃ are optionally linked to each other to further form an alicyclic or aromatic monocyclic or polycyclic ring.

As used herein, the term “substituted” in the definitions of Formula 1-1 and Formula 1-12 indicates substitution with one or more substituents selected from deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl, and nitro, or a combination thereof. The term “unsubstituted” in the same definition indicates having no substituent. One or more hydrogen atoms in each of the substituents are optionally replaced by deuterium atoms and two or more adjacent ones of the substituents are optionally linked to each other to form an alicyclic or aromatic mono- or polycyclic ring.

In the “substituted or unsubstituted C₁-C₃₀ alkyl”, “substituted or unsubstituted C₆-C₅₀ aryl”, etc., the number of carbon atoms in the alkyl or aryl group indicates the number of carbon atoms constituting the unsubstituted alkyl or aryl moiety without considering the number of carbon atoms in the substituent(s). For example, a phenyl group substituted with a butyl group at the para-position corresponds to a C₆ aryl group substituted with a C₄ butyl group.

As used herein, the expression “optionally linked to each other or an adjacent group to form a ring” means that the corresponding adjacent substituents are bonded to each other or each of the corresponding substituents is bonded to an adjacent group to form a substituted or unsubstituted alicyclic or aromatic ring. The term “adjacent group” may mean a substituent on an atom directly attached to an atom substituted with the corresponding substituent, a substituent disposed sterically closest to the corresponding substituent or another substituent on an atom substituted with the corresponding substituent. For example, two substituents substituted at the ortho position of a benzene ring or two substituents on the same carbon in an aliphatic ring may be considered “adjacent” to each other. Optionally, the paired substituents each lose one hydrogen radical and are linked to each other to form a ring. The carbon atoms in the resulting alicyclic, aromatic mono- or polycyclic ring may be replaced by one or more heteroatoms such as O, S, N, P, Si, and Ge.

In the present invention, the alkyl groups may be straight or branched. Specific examples of the alkyl groups include, but are not limited to, methyl, ethyl, propyl, n-propyl, isopropyl, butyl, n-butyl, isobutyl, tert-butyl, sec-butyl, 1-methylbutyl, 1-ethylbutyl, pentyl, n-pentyl, isopentyl, neopentyl, tert-pentyl, hexyl, n-hexyl, 1-methylpentyl, 2-methylpentyl, 4-methyl-2-pentyl, 3,3-dimethylbutyl, 2-ethylbutyl, heptyl, n-heptyl, 1-methylhexyl, cyclopentylmethyl, cyclohexylmethyl, octyl, n-octyl, tert-octyl, 1-methylheptyl, 2-ethylhexyl, 2-propylpentyl, n-nonyl, 2,2-dimethylheptyl, 1-ethylpropyl, 1,1-dimethylpropyl, isohexyl, 2-methylpentyl, 4-methylhexyl, and 5-methylhexyl groups.

In the present invention, specific examples of the arylalkyl groups include, but are not limited to, phenylmethyl(benzyl), phenylethyl, phenylpropyl, naphthylmethyl, and naphthylethyl.

In the present invention, specific examples of the alkylaryl groups include, but are not limited to, tolyl, xylenyl, dimethylnaphthyl, t-butylphenyl, t-butylnaphthyl, and t-butylphenanthryl.

The alkenyl group is intended to include straight and branched ones and may be optionally substituted with one or more other substituents. The alkenyl group may be specifically a vinyl, 1-propenyl, isopropenyl, 1-butenyl, 2-butenyl, 3-butenyl, 1-pentenyl, 2-pentenyl, 3-pentenyl, 3-methyl-1-butenyl, 1,3-butadienyl, allyl, 1-phenylvinyl-1-yl, 2-phenylvinyl-1-yl, 2,2-diphenylvinyl-1-yl, 2-phenyl-2-(naphthyl-1-yl)vinyl-1-yl, 2,2-bis(diphenyl-1-yl)vinyl-1-yl, stilbenyl or styrenyl group but is not limited thereto.

The alkynyl group is intended to include straight and branched ones and may be optionally substituted with one or more other substituents. The alkynyl group may be, for example, ethynyl or 2-propynyl but is not limited thereto.

The cycloalkenyl group is a non-aromatic cyclic unsaturated hydrocarbon group having one or more carbon-carbon double bonds. The cycloalkenyl group may be, for example, cyclopropenyl, cyclobutenyl, cyclopentenyl, cyclohexenyl, cycloheptenyl, 1,3-cyclohexadienyl, 1,4-cyclohexadienyl, 2,4-cycloheptadienyl or 1,5-cyclooctadienyl but is not limited thereto.

The aromatic hydrocarbon rings or aryl groups may be monocyclic or polycyclic ones. As used herein, the term “polycyclic” means that the aromatic hydrocarbon ring may be directly attached or fused to one or more other cyclic groups. The other cyclic groups may be aromatic hydrocarbon rings and other examples thereof include aliphatic heterocyclic rings, aliphatic hydrocarbon rings, and aromatic heterocyclic rings. Examples of the monocyclic aryl groups include, but are not limited to, phenyl, biphenyl, and terphenyl. Examples of the polycyclic aryl groups include naphthyl, anthracenyl, phenanthrenyl, pyrenyl, perylenyl, tetracenyl, chrysenyl, fluorenyl, acenaphthenyl, triphenylene, and fluoranthene groups but the scope of the present invention is not limited thereto.

The aromatic heterocyclic rings or heteroaryl groups refer to aromatic groups containing one or more heteroatoms such as O, S, N, P, Si, and Ge. Examples of the aromatic heterocyclic rings or heteroaryl groups include, but are not limited to, thiophene, furan, pyrrole, imidazole, thiazole, oxazole, oxadiazole, triazole, pyridyl, bipyridyl, pyrimidyl, triazine, triazole, acridyl, pyridazine, pyrazinyl, quinolinyl, quinazoline, quinoxalinyl, phthalazinyl, pyridopyrimidinyl, pyridopyrazinyl, pyrazinopyrazinyl, isoquinoline, indole, carbazole, benzoxazole, benzimidazole, benzothiazole, benzocarbazole, benzothiophene, dibenzothiophene, benzofuranyl, dibenzofuranyl, phenanthroline, thiazolyl, isoxazolyl, oxadiazolyl, thiadiazolyl, benzothiazolyl, and phenothiazinyl groups.

The aliphatic hydrocarbon rings or cycloalkyl groups refer to non-aromatic rings consisting only of carbon and hydrogen atoms. The aliphatic hydrocarbon ring is intended to include monocyclic and polycyclic ones and may be optionally substituted with one or more other substituents. As used herein, the term “polycyclic” means that the aliphatic hydrocarbon ring may be directly attached or fused to one or more other cyclic groups. The other cyclic groups may be aliphatic hydrocarbon rings and other examples thereof include aliphatic heterocyclic, aryl, and heteroaryl groups. Specific examples of the aliphatic hydrocarbon rings include, but are not limited to, cycloalkyl groups such as cyclopropyl, cyclobutyl, cyclopentyl, adamantyl, 3-methylcyclopentyl, 2,3-dimethylcyclopentyl, cyclohexyl, 3-methylcyclohexyl, 4-methylcyclohexyl, 2,3-dimethylcyclohexyl, 3,4,5-trimethylcyclohexyl, 4-tert-butylcyclohexyl, cycloheptyl, and cyclooctyl, cycloalkanes such as cyclohexane and cyclopentane, and cycloalkenes such as cyclohexene and cyclobutene.

The aliphatic heterocyclic rings or heterocycloalkyl groups refer to aliphatic rings containing one or more heteroatoms such as O, S, Se, N, Si and Ge. The aliphatic heterocyclic ring is intended to include monocyclic or polycyclic ones and may be optionally substituted with one or more other substituents. As used herein, the term “polycyclic” means that the aliphatic heterocyclic ring such as heterocycloalkyl, heterocycloalkane or heterocycloalkene may be directly attached or fused to one or more other cyclic groups. The other cyclic groups may be aliphatic heterocyclic rings and other examples thereof include aliphatic hydrocarbon rings, aryl groups, and heteroaryl groups.

The cyclic groups in which an aliphatic ring and an aromatic ring are fused together refers to mixed aliphatic-aromatic cyclic groups in which at least one aliphatic ring and at least one aromatic ring are linked and fused together and which are overall non-aromatic. More specifically, the cyclic groups in which an aliphatic ring and an aromatic ring are fused together may be an aromatic hydrocarbon cyclic group fused with an aliphatic hydrocarbon ring, an aromatic hydrocarbon cyclic group fused with an aliphatic heterocyclic ring, an aromatic heterocyclic group fused with an aliphatic hydrocarbon ring, an aromatic heterocyclic group fused with an aliphatic heterocyclic ring, an aliphatic hydrocarbon cyclic group fused with an aromatic hydrocarbon ring, an aliphatic hydrocarbon cyclic group fused with an aromatic hydrocarbon ring, an aliphatic heterocyclic group fused with an aromatic hydrocarbon ring, and an aliphatic heterocyclic group fused with an aromatic heterocyclic ring. Specific examples of the cyclic groups in which an aliphatic ring and an aromatic ring are fused together include tetrahydronaphthyl, tetrahydrobenzocycloheptene, tetrahydrophenanthrene, tetrahydroanthracenyl, octahydrotriphenylene, tetrahydrobenzothiophene, tetrahydrobenzofuranyl, tetrahydrocarbazole, and tetrahydroquinoline. The cyclic groups in which an aliphatic ring and an aromatic ring are fused together may be interrupted by at least one heteroatom other than carbon. The heteroatom may be, for example, O, S, N, P, Si or Ge.

The alkoxy group may be specifically a methoxy, ethoxy, propoxy, isobutyloxy, sec-butyloxy, pentyloxy, iso-amyloxy or hexyloxy group but is not limited thereto.

The silyl group is intended to include —SiH₃, alkylsilyl, arylsilyl, alkylarylsilyl, arylheteroarylsilyl, and heteroarylsilyl. The arylsilyl refers to a silyl group obtained by substituting one, two or three of the hydrogen atoms in —SiH₃ with aryl groups. The alkylsilyl refers to a silyl group obtained by substituting one, two or three of the hydrogen atoms in —SiH₃ with alkyl groups. The alkylarylsilyl refers to a silyl group obtained by substituting one of the hydrogen atoms in —SiH₃ with an alkyl group and the other two hydrogen atoms with aryl groups or substituting two of the hydrogen atoms in —SiH₃ with alkyl groups and the remaining hydrogen atom with an aryl group. The arylheteroarylsilyl refers to a silyl group obtained by substituting one of the hydrogen atoms in —SiH₃ with an aryl group and the other two hydrogen atoms with heteroaryl groups or substituting two of the hydrogen atoms in —SiH₃ with aryl groups and the remaining hydrogen atom with a heteroaryl group. The heteroarylsilyl refers to a silyl group obtained by substituting one, two or three of the hydrogen atoms in —SiH₃ with heteroaryl groups. The arylsilyl group may be, for example, substituted or unsubstituted monoarylsilyl, substituted or unsubstituted diarylsilyl, or substituted or unsubstituted triarylsilyl. The same applies to the alkylsilyl and heteroarylsilyl groups.

Each of the aryl groups in the arylsilyl, heteroarylsilyl, and arylheteroarylsilyl groups may be a monocyclic or polycyclic one. Each of the heteroaryl groups in the arylsilyl, heteroarylsilyl, and arylheteroarylsilyl groups may be a monocyclic or polycyclic one.

Specific examples of the silyl groups include trimethylsilyl, triethylsilyl, triphenylsilyl, trimethoxysilyl, dimethoxyphenylsilyl, diphenylmethylsilyl, diphenylvinylsilyl, methylcyclobutylsilyl, and dimethylfurylsilyl. One or more of the hydrogen atoms in each of the silyl groups may be substituted with the substituents mentioned in the aryl groups.

The amine group is intended to include —NH₂, alkylamine, arylamine, arylheteroarylamine, and heteroarylamine. The arylamine refers to an amine group obtained by substituting one or two of the hydrogen atoms in —NH₂ with aryl groups. The alkylamine refers to an amine group obtained by substituting one or two of the hydrogen atoms in —NH₂ with alkyl groups. The alkylarylamine refers to an amine group obtained by substituting one of the hydrogen atoms in —NH₂ with an alkyl group and the other hydrogen atom with an aryl group. The arylheteroarylamine refers to an amine group obtained by substituting one of the hydrogen atoms in —NH₂ with an aryl group and the other hydrogen atom with a heteroaryl group. The heteroarylamine refers to an amine group obtained by substituting one or two of the hydrogen atoms in —NH₂ with heteroaryl groups. The arylamine may be, for example, substituted or unsubstituted monoarylamine, substituted or unsubstituted diarylamine, or substituted or unsubstituted triarylamine. The same applies to the alkylamine and heteroarylamine groups.

Each of the aryl groups in the arylamine, heteroarylamine, and arylheteroarylamine groups may be a monocyclic or polycyclic one. Each of the heteroaryl groups in the arylamine, heteroarylamine, and arylheteroarylamine groups may be a monocyclic or polycyclic one.

The germanium group is intended to include —GeH₃, alkylgermanium, arylgermanium, heteroarylgermanium, alkylarylgermanium, alkylheteroarylgermanium, and arylheteroarylgermanium. The definitions of the substituents in the germanium groups follow those described for the silyl groups, except that the silicon (Si) atom in each silyl group is changed to a germanium (Ge) atom.

Specific examples of the germanium groups include trimethylgermane, triethylgermane, triphenylgermane, trimethoxygermane, dimethoxyphenylgermane, diphenylmethylgermane, diphenylvinylgermane, methylcyclobutylgermane, and dimethylfurylgermane. One or more of the hydrogen atoms in each of the germanium groups may be substituted with the substituents mentioned in the aryl groups.

The cycloalkyl, aryl, and heteroaryl groups in the cycloalkyloxy, aryloxy, heteroaryloxy, cycloalkylthioxy, arylthioxy, and heteroarylthioxy groups are the same as those exemplified above. Specific examples of the aryloxy groups include, but are not limited to, phenoxy, p-tolyloxy, m-tolyloxy, 3,5-dimethylphenoxy, 2,4,6-trimethylphenoxy, p-tert-butylphenoxy, 3-biphenyloxy, 4-biphenyloxy, 1-naphthyloxy, 2-naphthyloxy, 4-methyl-1-naphthyloxy, 5-methyl-2-naphthyloxy, 1-anthryloxy, 2-anthryloxy, 9-anthryloxy, 1-phenanthryloxy, 3-phenanthryloxy, and 9-phenanthryloxy groups. Specific examples of the arylthioxy groups include, but are not limited to, phenylthioxy, 2-methylphenylthioxy, and 4-tert-butylphenylthioxy groups.

The halogen group may be, for example, fluorine, chlorine, bromine or iodine.

According to one embodiment of the present invention, the anthracene derivative represented by Formula 1 may be selected from the following compounds:

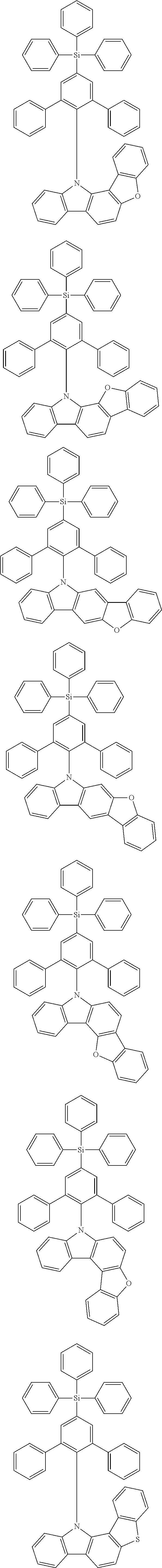

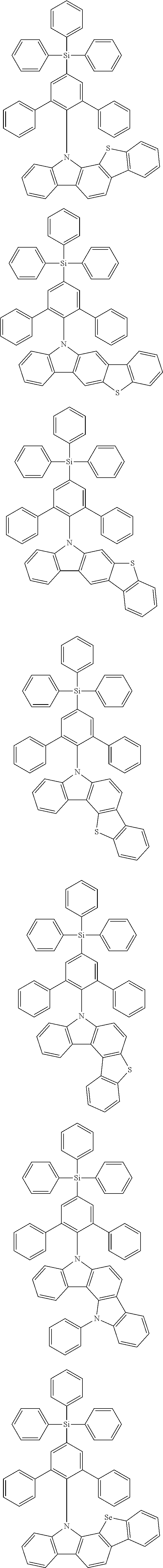

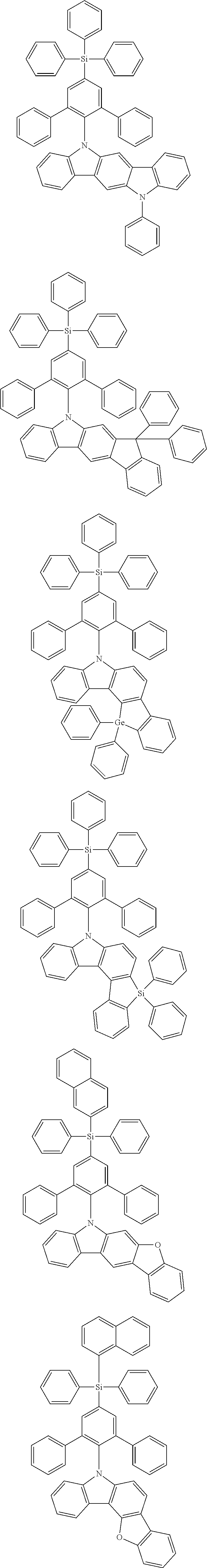

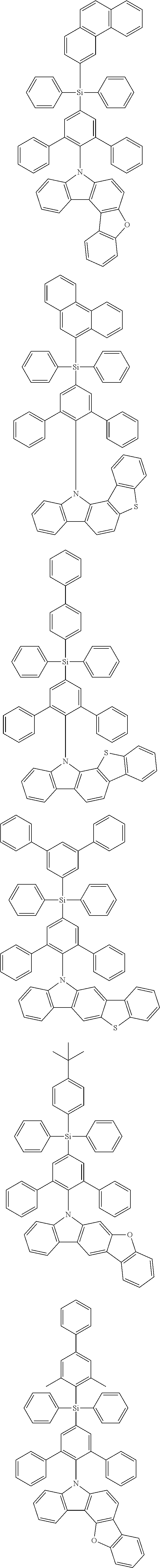

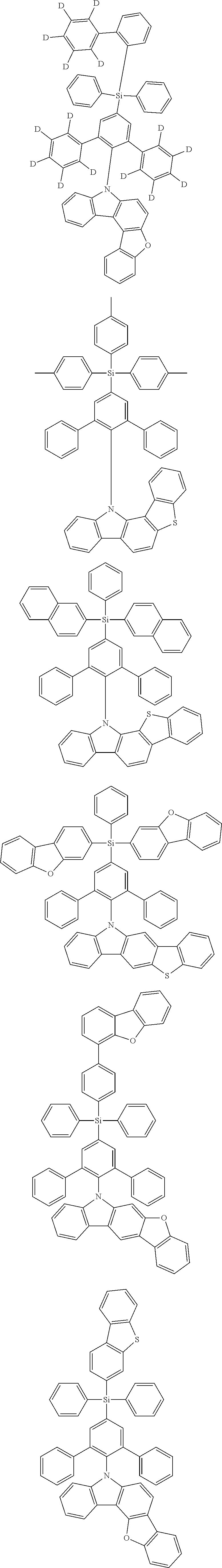

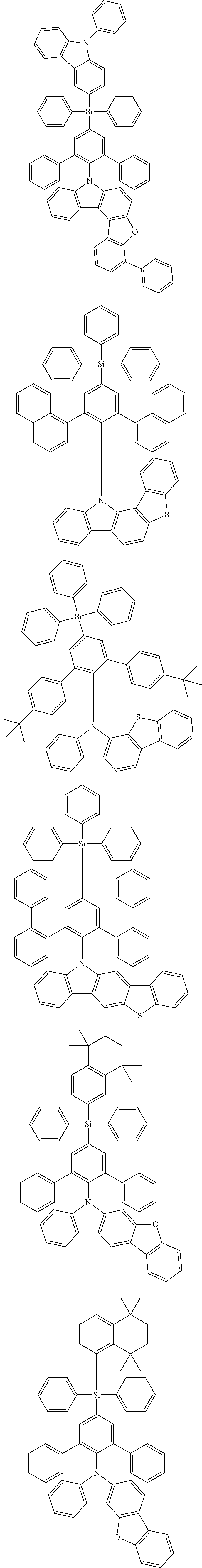

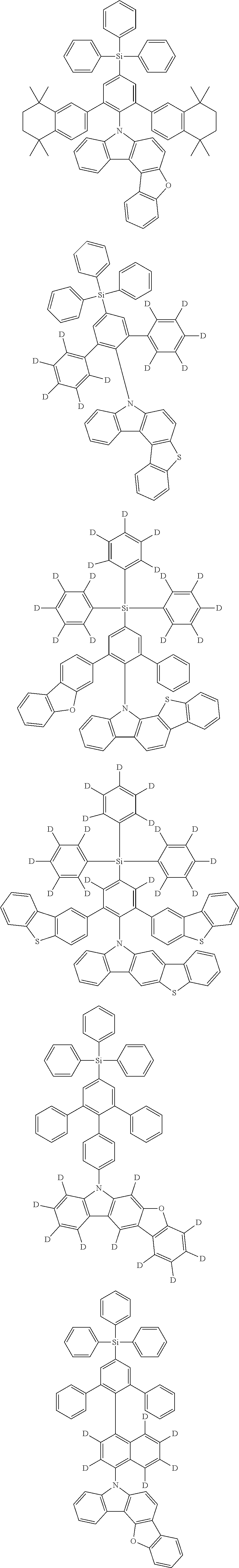

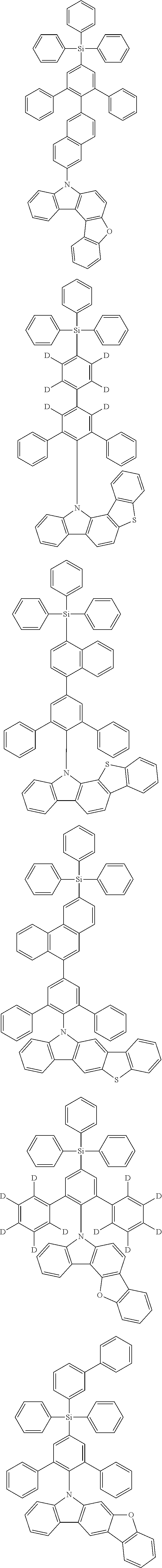

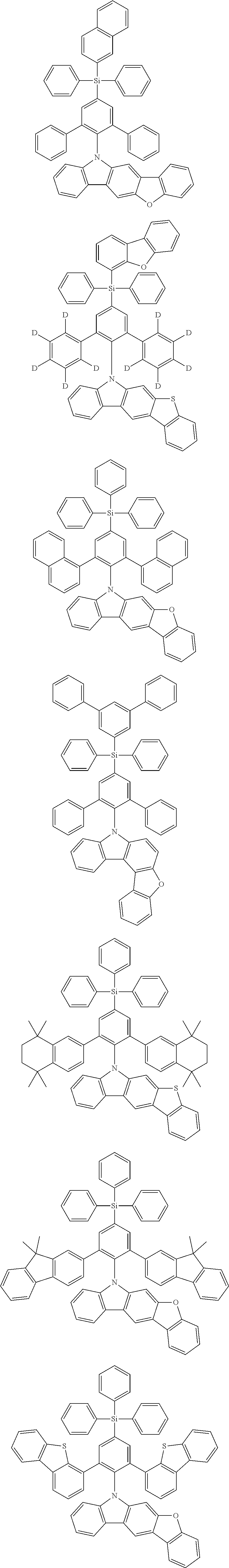

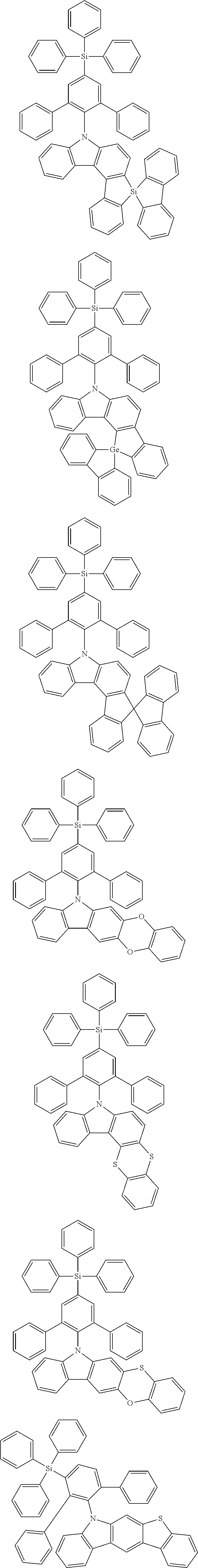

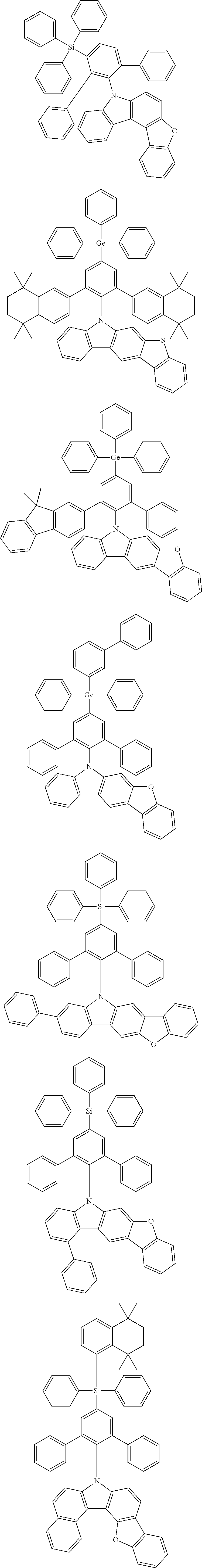

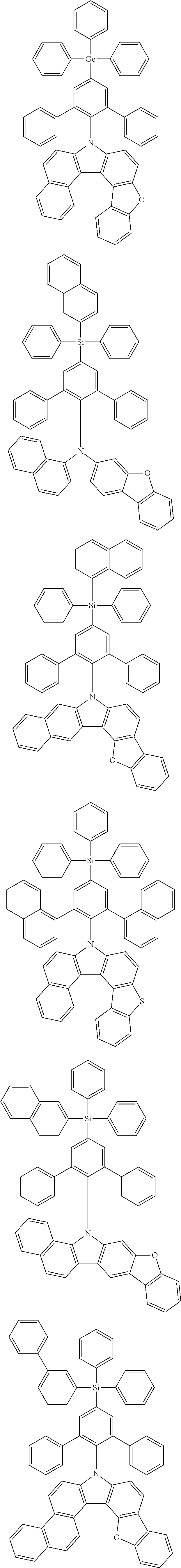

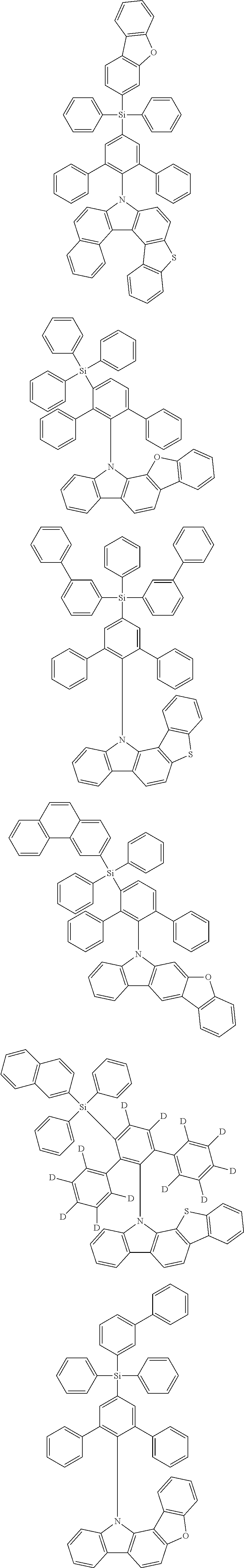

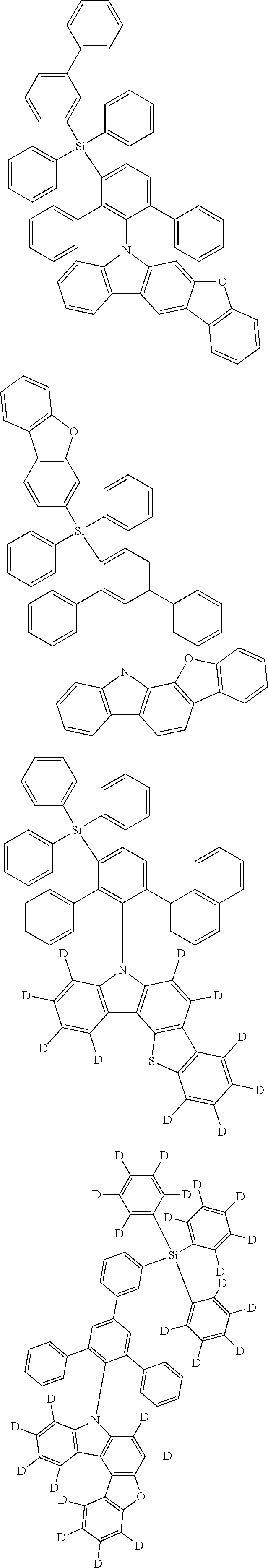

A further aspect of the present invention is directed to an organic light emitting device including a first electrode, a second electrode, and one or more organic layers interposed between the first and second electrodes wherein one of the organic layers is preferably a light emitting layer including a host and a dopant and the host includes the compound represented by Formula 1.

The light emitting layer may further include a dopant material. In this case, the total content of the dopants in the light emitting layer is typically in the range of about 0.01 to about 20 parts by weight, based on about 100 parts by weight of the hosts but is not limited to this range.

The dopant compounds employed in the light emitting layer of the organic light emitting device according to the present invention are not fluorescent dopant materials that are transferred only to singlet states based on Forster energy transfer in traditional host-dopant systems but phosphorescent dopant materials that are transferred to both singlet and triplet states irrespective of whether their state based on Dexter energy transfer. The phosphorescent dopant materials are metal complexes containing at least one metal selected from Ir, Pt, Os, Ti, Zr, Hf, Eu, Tb, Tm, Fe, Co, Ni, Ru, Rh, Re, and Pd but are not particularly limited thereto as long as they emit light from triplet excitons. The metal is preferably selected from Ir, Pt, and Pd and specific examples of the metal complexes include, but are not limited to, Ir(ppy)₃, Ir(ppy)₂acac, Ir(Bt)₂acac, Ir(MDQ)₂acac, Ir(mppy)₃, Ir(piq)₃, Ir(piq)₂acac, Ir(pq)₂acac, Ir(mpp)₂acac, F₂Irpic, (F₂ppy)₂Ir(tmd), Ir(ppy)₂tmd, Ir(pmi)₃, Ir(pmb)₃, FCNIr, FCNIrpic, Flr₆, FIrN₄, FIrpic, PtOEP, Ir(chpy)₃, P0-01(C₃₁H₂₃IrN₂O₂S₂), Ir(ppz)₃, Ir(dfppz)₃, PtNON, Pt-10, and Pt-11.

The light emitting layer may further include one or more other dopant materials and one or more other hosts. Thus, two or more different dopant materials and two or more different host materials may be mixed or stacked in the light emitting layer.

According to one embodiment of the present invention, the light emitting layer as one of the organic layers interposed between the first and second electrodes may include one or more host compounds other than the compound represented by Formula 1 wherein the two or more host compounds may be mixed or stacked in the light emitting layer.

In this embodiment, the additional host compound may be a compound having an electron acceptor moiety. The mixing and stacking of the additional host compound with the compound represented by Formula 1 having a fused carbazole moiety as an electron donor moiety increases the HOMO/LUMO levels of hole injection and electron injection barriers, and as a result, the recombination zone is limited to the interface of the two hosts, leading to minimal current loss. Due to this advantage, the organic light emitting device has high efficiency and long lifetime.

The compound having an electron acceptor moiety refers to a compound that has a moiety by which electrons from the outside are easily accepted. The compound having an electron acceptor moiety may be an azine compound that has an aromatic heterocyclic moiety containing nitrogen in the molecule, such as pyridine, pyrimidine or triazine, or a cyano (—CN)-substituted compound. The compound having an electron acceptor moiety is preferably a compound that has a heteroaryl group containing one to three nitrogen (N) atoms in the molecule or an aryl group containing one to three cyano groups (—CN) in the molecule.

More specifically, the hosts employed in the light emitting layer of the organic light emitting device according to the present invention compound may be the compound represented by Formula 1 and an organic compound represented by Formula 2:

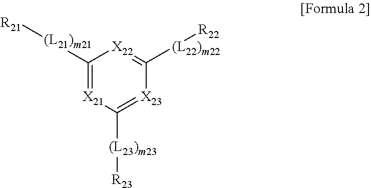

In [Formula 2],

X₂₁ to X₂₃ are the same as or different from each other and each independently N or CR₂₄, at least one of X₂₁ to X₂₃ is N, and when two or more of X₂₁ to X₂₃ are CR₂₄, CR₂₄s are the same as or different from each other.

L₂₁ to L₂₃ are the same as or different from each other, and each independently a single bond, or any one selected from substituted or unsubstituted C₆-C₃₀ arylene, substituted or unsubstituted C₂-C₃₀ heteroarylene, and substituted or unsubstituted divalent cyclic groups in which a C₃-C₂₄ aliphatic ring and a C₅-C₂₄ aromatic ring are fused together.

m₂₁ to m₂₃ are the same as or different from each other, and each independently an integer of 1 to 2, and when they are each an integer of 2, L₂₁s to L₂₃s are the same as or different from each other.

R₂₁ to R₂₄ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₃₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano and halogen.

As used herein, the term “substituted” in the definitions of Formula 2 indicates substitution with one or more substituents selected from deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl, and nitro, or a combination thereof. The term “unsubstituted” in the same definition indicates having no substituent. One or more hydrogen atoms in each of the substituents are optionally replaced by deuterium atoms and two or more adjacent ones of the substituents are optionally linked to each other to form an alicyclic or aromatic mono- or polycyclic ring.

In addition, the light emitting layer may further include various host materials and various dopant materials in addition to the dopant and the host.

The organic layer of the organic light emitting device according to the present invention may be formed in a single layer structure, but may be formed in a multilayer structure in which two or more organic layers are laminated. For example, the organic layer may have a structure including a hole injecting layer, a hole transport layer, a hole blocking layer, a light emitting layer, an electron blocking layer, an electron transport layer, an electron injecting layer and the like. However, the structure is not limited thereto, and may also include a smaller or larger number of organic layers, and a preferred organic layer structure of the organic light emitting device according to the present invention will be described in more detail in examples to be described later.

According to one embodiment of the present invention, the dopants may include at least one organometallic compound.

The organometallic compound may be mixed or stacked with one or more other dopants. One of the additional dopants may be a polycyclic compound represented by Formula 3.

Accordingly, according to one embodiment of the present invention, the light emitting layer of the organic light emitting device may include a first host, a second host, an organometallic compound, and the polycyclic compound (thermally activated delayed boron-based fluorescent material) of Formula 3.

The organometallic compound functions as a sensitizer and the polycyclic compound functions as a light emitting dopant. The sensitizer compound receives excitons from the first host and the second host and transfer the excitons to the light emitting dopant.

Accordingly, excitons are transferred from the sensitizer to the light emitting dopant compound through the Dexter energy transfer (DET) or Forster resonance transfer (FRET) mechanism, and the exciton energy delivered to the light emitting dopant compound is transferred to the ground state. In this process, the energy is emitted as light. The excitons can be transferred from the first and second hosts to the sensitizer through the FRET or DET mechanism.

In conclusion, the FRET or DET mechanism facilitates energy transfer between the sensitizer and the light emitting dopant and suppresses triplet-triplet annihilation, ensuring high efficiency of the organic light emitting device.

Forster energy transfer from the triplet of the phosphorescence sensitizer to the singlet of the polycyclic compound (thermally activated delayed boron-based fluorescent material) represented by Formula 3, contributes to a reduction in the number of long-lived triplet excitons involved in the degradation of the device, ensuring long lifetime of the device.

In addition, the high molar extinction coefficient of the polycyclic compound ensures fast fluorescence resonance energy transfer from the phosphorescence sensitizer to the fluorescent material and the multiple resonance effect of the polycyclic compound narrows the emission spectrum to increase the color purity of the device, achieving improved efficiency and lifetime of the device.

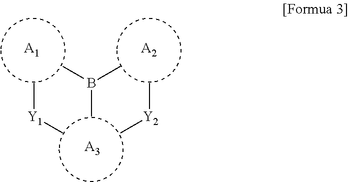

wherein Y₁ and Y₂ are the same as or different from each other and are each independently selected from O, S, NR₃₁, CR₃₂R₃₃, SiR₃₄R₃₅, and GeR₃₆R₃₇, A₁ to A₃ are the same as or different from each other and are each independently selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and cyclic groups in which a substituted or unsubstituted C₃-C₂₄ aliphatic ring and a C₅-C₂₄ aromatic ring are fused together, R₃₁ to R₃₇ are the same as or different from each other and are each independently selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, cyclic groups in which a substituted or unsubstituted C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano, and halogen, with the proviso that each of R₃₁ to R₃₇ is optionally linked to one or more of the C₁ to C₃ rings to form an alicyclic or aromatic monocyclic or polycyclic ring, R₃₂ and R₃₃ are optionally linked to each other to form an alicyclic or aromatic monocyclic or polycyclic ring, R₃₄ and R₃₅ are optionally linked to each other to form an alicyclic or aromatic monocyclic or polycyclic ring, and R₃₆ and R₃₇ are optionally linked to each other to form an alicyclic or aromatic monocyclic or polycyclic ring.

As used herein, the term “substituted” in the definitions of Formula 3 indicates substitution with one or more substituents selected from deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl, and nitro, or a combination thereof. The term “unsubstituted” in the same definition indicates having no substituent. One or more hydrogen atoms in each of the substituents are optionally replaced by deuterium atoms and two or more adjacent ones of the substituents are optionally linked to each other to form an alicyclic or aromatic mono- or polycyclic ring.

A more detailed description will be given concerning exemplary embodiments of the organic light emitting device according to the present invention.

The organic light emitting device of the present invention includes an anode, a hole transport layer, a light emitting layer, an electron transport layer, and a cathode. The organic light emitting device of the present invention may optionally further include a hole injecting layer between the anode and the hole transport layer and an electron injecting layer between the electron transport layer and the cathode. If necessary, the organic light emitting device of the present invention may further include one or two intermediate layers such as a hole blocking layer or an electron blocking layer. The organic light emitting device of the present invention may further include one or more organic layers such as a capping layer that have various functions depending on the desired characteristics of the device.

A specific structure of the organic light emitting device according to one embodiment of the present invention, a method for fabricating the device, and materials for the organic layers are as follows.

First, an anode material is coated on a substrate to form an anode. The substrate may be any of those used in general organic light emitting devices. The substrate is preferably an organic substrate or a transparent plastic substrate that is excellent in transparency, surface smoothness, ease of handling, and waterproofness. A highly transparent and conductive metal oxide such as indium tin oxide (ITO), indium zinc oxide (IZO), tin oxide (SnO₂) or zinc oxide (ZnO) is used as the anode material.

A hole injecting material is coated on the anode by vacuum thermal evaporation or spin coating to form a hole injecting layer. Then, a hole transport material is coated on the hole injecting layer by vacuum thermal evaporation or spin coating to form a hole transport layer.

The hole injecting material is not specially limited so long as it is usually used in the art. Specific examples of such materials include 1,4,5,8,9,11-hexaazatriphenylenehexacarbonitrile (HAT-CN), 4,4′,4″-tris(2-naphthylphenyl-phenylamino)triphenylamine (2-TNATA), N,N′-di(1-naphthyl)-N,N′-diphenylbenzidine (NPD), N,N′-diphenyl-N,N′-bis(3-methylphenyl)-1,1′-biphenyl-4,4′-diamine (TPD), and N,N′-diphenyl-N,N′-bis(4-(phenyl-m-tolylamino)phenyl)biphenyl-4,4′-diamine (DNTPD).

The hole transport material is not specially limited so long as it is commonly used in the art. Examples of such materials include N,N′-bis(3-methylphenyl)-N,N′-diphenyl-(1,1-biphenyl)-4,4′-diamine (TPD) and N,N′-di(naphthalen-1-yl)-N,N′-diphenylbenzidine (α-NPD).

Subsequently, a hole auxiliary layer and a light emitting layer are sequentially stacked on the hole transport layer. A hole blocking layer may be optionally formed on the light emitting layer by vacuum thermal evaporation or spin coating. The hole blocking layer is formed as a thin film and blocks holes from entering a cathode through the organic light emitting layer. This role of the hole blocking layer prevents the lifetime and efficiency of the device from deteriorating. A material having a very low highest occupied molecular orbital (HOMO) energy level is used for the hole blocking layer. The hole blocking material is not particularly limited so long as it can transport electrons and has a higher ionization potential than the light emitting compound. Representative examples of suitable hole blocking materials include BAIq, BCP, and TPBI.

Examples of materials for the hole blocking layer include, but are not limited to, BAIq, BCP, Bphen, TPBI, TAZ, BeBq₂, OXD-7, and Liq.

An electron transport layer is deposited on the hole blocking layer by vacuum thermal evaporation or spin coating, and an electron injecting layer is formed thereon. A cathode metal is deposited on the electron injecting layer by vacuum thermal evaporation to form a cathode, completing the fabrication of the organic light emitting device.

For example, lithium (Li), magnesium (Mg), aluminum (Al), aluminum-lithium (Al—Li), calcium (Ca), magnesium-indium (Mg—In) or magnesium-silver (Mg—Ag) may be used as the metal for the formation of the cathode. The organic light emitting device may be of top emission type. In this case, a transmissive material such as ITO or IZO may be used to form the cathode.

A material for the electron transport layer functions to stably transport electrons injected from the cathode. The electron transport material may be any of those known in the art and examples thereof include, but are not limited to, quinoline derivatives, particularly tris(8-quinolinolato)aluminum (Alq₃), TAZ, BAIq, beryllium bis(benzoquinolin-10-olate) (Bebq₂), and oxadiazole derivatives such as PBD, BMD, and BND.

The organic light emitting device of the present invention may further include a light emitting layer composed of a material that emits blue, green or red light in the wavelength range of 380 nm to 800 nm. That is, the organic light emitting device of the present invention may include a plurality of light emitting layers. The blue, green or red light emitting material for the additional light emitting layer may be a fluorescent or phosphorescent material.

Each of the organic layers can be formed by a monomolecular deposition or solution process. According to the monomolecular deposition process, the material for each layer is evaporated into a thin film under heat and vacuum or reduced pressure. According to the solution process, the material for each layer is mixed with a suitable solvent and the mixture is then formed into a thin film by a suitable method such as ink-jet printing, roll-to-roll coating, screen printing, spray coating, dip coating or spin coating.

The organic light emitting device of the present invention can be used in a display or lighting system selected from flat panel displays, flexible displays, monochromatic flat panel lighting systems, white flat panel lighting systems, flexible monochromatic lighting systems, flexible white lighting systems, displays for automotive applications, displays for virtual reality, and displays for augmented reality.

The present invention will be more specifically explained with reference to the following synthesis examples and fabrication examples. However, these examples are provided to assist in understanding the invention and are not intended to limit the scope of the present invention.

### Synthesis Example 1: Synthesis of [BH-1]

### Synthesis Example 1-1: Synthesis of A-1

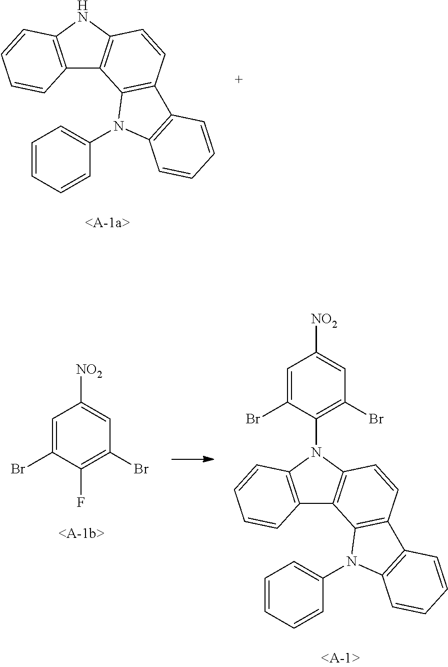 [SMILES: c1ccc(-n2c3ccccc3c3ccc4[nH]c5ccccc5c4c32)cc1 ; O=[N+]([O-])c1cc(Br)c(F)c(Br)c1 ; O=[N+]([O-])c1cc(Br)c(-n2c3ccccc3c3c2ccc2c4ccccc4n(-c4ccccc4)c23)c(Br)c1]

To a round bottom flask, <A-1a> (20 g), <A-1b> (19.8 g), K₂CO₃ (16.6 g) and N,N-dimethylformamide (150 mL) were introduced, and the mixture was stirred and refluxed for 12 hours after raising the temperature to 70° C. under a nitrogen condition. After the reaction was finished, the reaction material was separated into layers. The organic layer was concentrated under reduced pressure, and then separated and purified by column chromatography to obtain <A-1>. (22 g, 59.8%)

### Synthesis Example 1-2: Synthesis of A-2

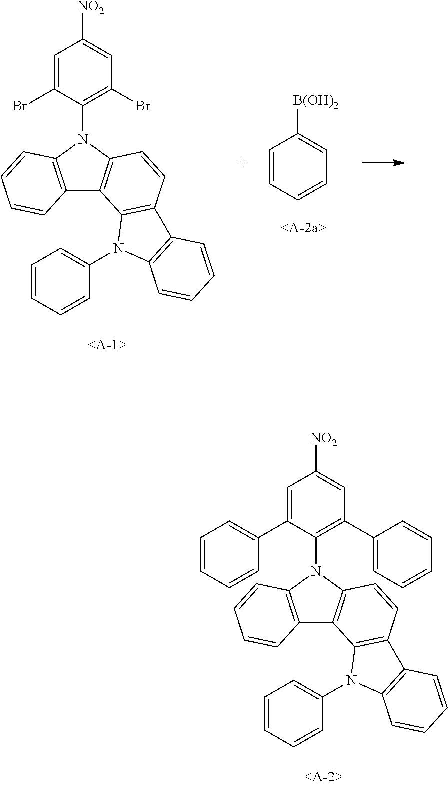 [SMILES: O=[N+]([O-])c1cc(Br)c(-n2c3ccccc3c3c2ccc2c4ccccc4n(-c4ccccc4)c23)c(Br)c1 ; OB(O)c1ccccc1 ; O=[N+]([O-])c1cc(-c2ccccc2)c(-n2c3ccccc3c3c2ccc2c4ccccc4n(-c4ccccc4)c23)c(-c2ccccc2)c1]

To a round bottom flask, <A-1> (25 g), <A-2a> (11 g), Pd(pph₃)₄ (1 g), K₂CO₃ (10.2 g), toluene (160 mL), ethanol (40 mL) and water (40 mL) were introduced, and the mixture was stirred and refluxed. After the reaction was finished, the reaction material was separated into layers. The organic layer was concentrated under reduced pressure, and then separated and purified by column chromatography to obtain <A-2>. (12.3 g, 49.7%)

### Synthesis Example 1-3: Synthesis of A-3

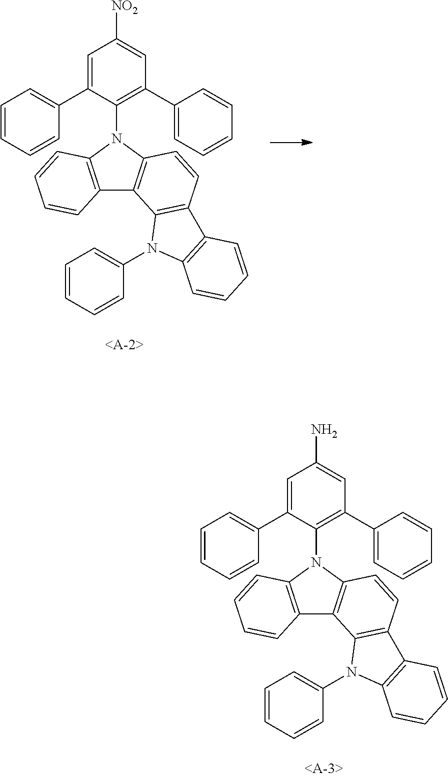 [SMILES: O=[N+]([O-])c1cc(-c2ccccc2)c(-n2c3ccccc3c3c2ccc2c4ccccc4n(-c4ccccc4)c23)c(-c2ccccc2)c1 ; Nc1cc(-c2ccccc2)c(-n2c3ccccc3c3c2ccc2c4ccccc4n(-c4ccccc4)c23)c(-c2ccccc2)c1]

To a round bottom flask, <A-2>(10 g), Fe (4.6 g), NH₄Cl (4.4 g), ethanol (135 mL) and water (15 mL) were introduced, and the mixture was stirred and refluxed under a nitrogen condition. After the reaction was finished, the reaction material was separated into layers. The organic layer was concentrated under reduced pressure, and then separated and purified by column chromatography to obtain <A-3>. (7.7 g, 81%)

### Synthesis Example 1-4: Synthesis of A-4

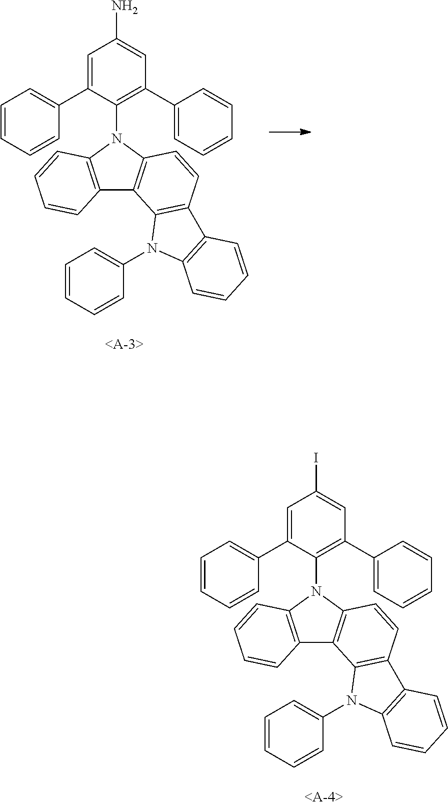 [SMILES: Nc1cc(-c2ccccc2)c(-n2c3ccccc3c3c2ccc2c4ccccc4n(-c4ccccc4)c23)c(-c2ccccc2)c1 ; Ic1cc(-c2ccccc2)c(-n2c3ccccc3c3c2ccc2c4ccccc4n(-c4ccccc4)c23)c(-c2ccccc2)c1]

To a round bottom flask, <A-3>(5 g) dissolved in HCl was introduced, and NaNO₂ (0.9 g) dissolved in water was added dropwise thereto over 30 minutes. After that, the mixture was cooled to 0° C. and stirred for 2 hours, and KI (4 g) dissolved in water was added dropwise thereto over 10 minutes. The result was heated to 80° C. and then stirred for 14 hours, then cooled to room temperature, and then Na₂SO₃ was added thereto. After the reaction was finished, the reaction material was separated into layers. The organic layer was concentrated under reduced pressure, and then separated and purified by column chromatography to obtain <A-4>. (5.2 g, 87.2%)

### Synthesis Example 1-5: Synthesis of [BH-1]

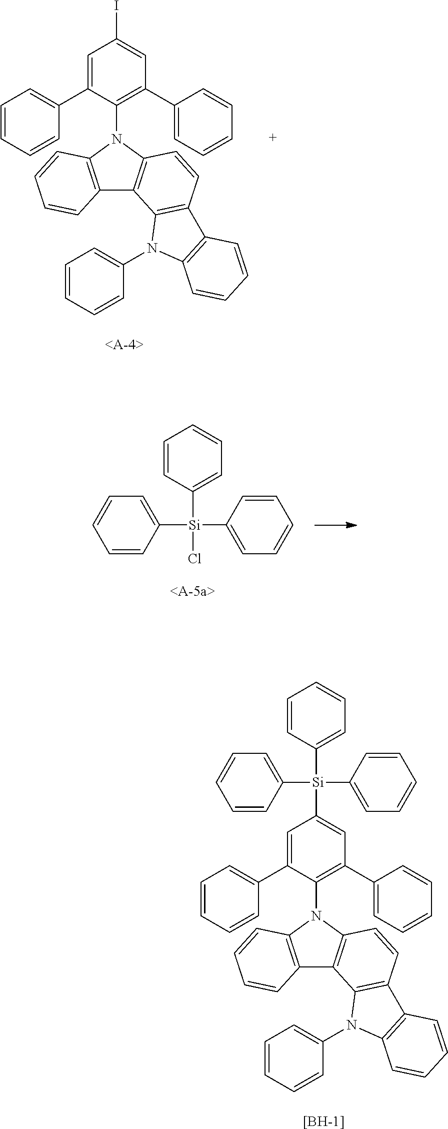

To a round bottom flask, <A-4> (20 g) and THF (100 mL) were introduced, and the mixture was cooled to −78° C. and stirred under a nitrogen condition. n-BuLi (21 mL) was slowly added dropwise thereto, and the result was stirred for 30 minutes at the low temperature. After that, <A-5a> (8.6 g) was added dropwise thereto, and then the temperature was raised to room temperature while stirring. After the reaction was finished, the reaction material was separated into layers. The organic layer was concentrated under reduced pressure, and then separated and purified by column chromatography to obtain [BH-1]. (12 g, 50%)

MS (MALDI-TOF): m/z 818.31 [M⁺]

### Synthesis Example 2: Synthesis of [BH-2]

### Synthesis Example 1-1: Synthesis of B-1

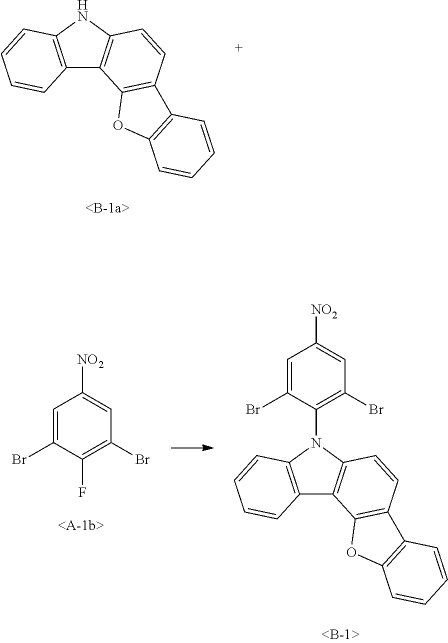 [SMILES: c1ccc2c(c1)[nH]c1ccc3c4ccccc4oc3c12 ; O=[N+]([O-])c1cc(Br)c(F)c(Br)c1 ; O=[N+]([O-])c1cc(Br)c(-n2c3ccccc3c3c4oc5ccccc5c4ccc32)c(Br)c1]

<B-1> was obtained in the same manner as in Synthesis Example 1-1, except that <B-1a> was used instead of <A-1a>. (Yield 46%)

### Synthesis Example 2-2: Synthesis of B-2

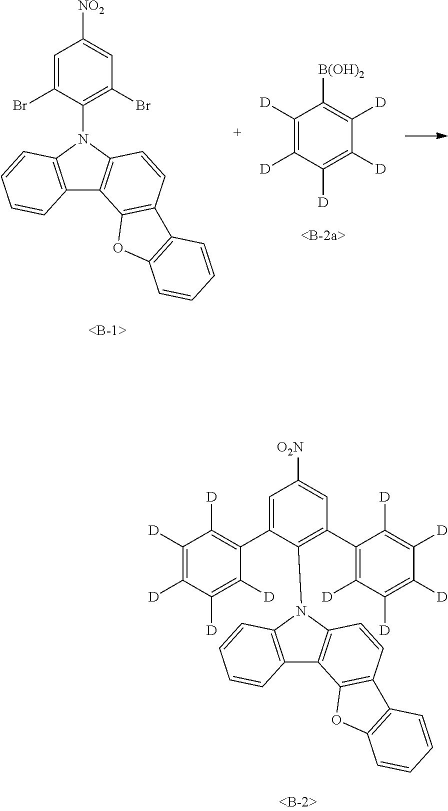 [SMILES: O=[N+]([O-])c1cc(Br)c(-n2c3ccccc3c3c4oc5ccccc5c4ccc32)c(Br)c1 ; [2H]c1c([2H])c([2H])c(B(O)O)c([2H])c1[2H] ; [2H]c1c([2H])c([2H])c(-c2cc([N+](=O)[O-])cc(-c3c([2H])c([2H])c([2H])c([2H])c3[2H])c2-n2c3ccccc3c3c4oc5ccccc5c4ccc32)c([2H])c1[2H]]

<B-2> was obtained in the same manner as in Synthesis Example 1-2, except that <B-1> was used instead of <A-1> and <B-2a> was used instead of <A-2a>. (Yield 51.3%)

### Synthesis Example 2-3: Synthesis of B-3

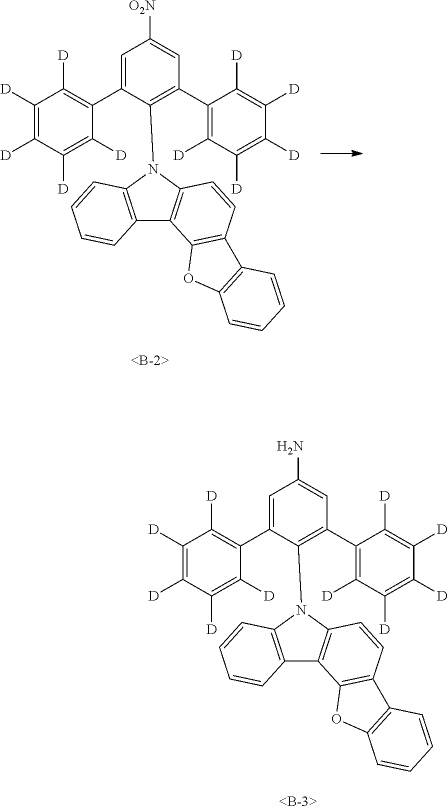 [SMILES: [2H]c1c([2H])c([2H])c(-c2cc([N+](=O)[O-])cc(-c3c([2H])c([2H])c([2H])c([2H])c3[2H])c2-n2c3ccccc3c3c4oc5ccccc5c4ccc32)c([2H])c1[2H] ; [2H]c1c([2H])c([2H])c(-c2cc(N)cc(-c3c([2H])c([2H])c([2H])c([2H])c3[2H])c2-n2c3ccccc3c3c4oc5ccccc5c4ccc32)c([2H])c1[2H]]

<B-3> was obtained in the same manner as in Synthesis Example 1-3, except that <B-2> was used instead of <A-2>. (Yield 83%)

### Synthesis Example 2-4: Synthesis of B-4

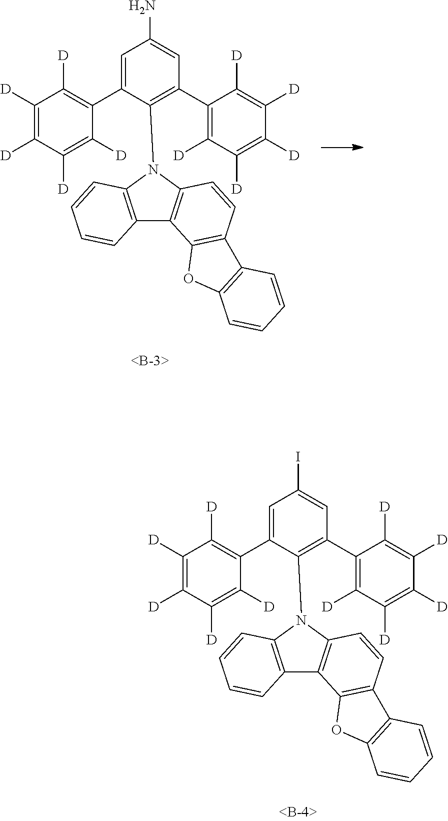 [SMILES: [2H]c1c([2H])c([2H])c(-c2cc(N)cc(-c3c([2H])c([2H])c([2H])c([2H])c3[2H])c2-n2c3ccccc3c3c4oc5ccccc5c4ccc32)c([2H])c1[2H] ; [2H]c1c([2H])c([2H])c(-c2cc(I)cc(-c3c([2H])c([2H])c([2H])c([2H])c3[2H])c2-n2c3ccccc3c3c4oc5ccccc5c4ccc32)c([2H])c1[2H]]

<B-4> was obtained in the same manner as in Synthesis Example 1-4, except that <B-3> was used instead of <A-3>. (Yield 82%)

### Synthesis Example 2-5: Synthesis of [BH-2]

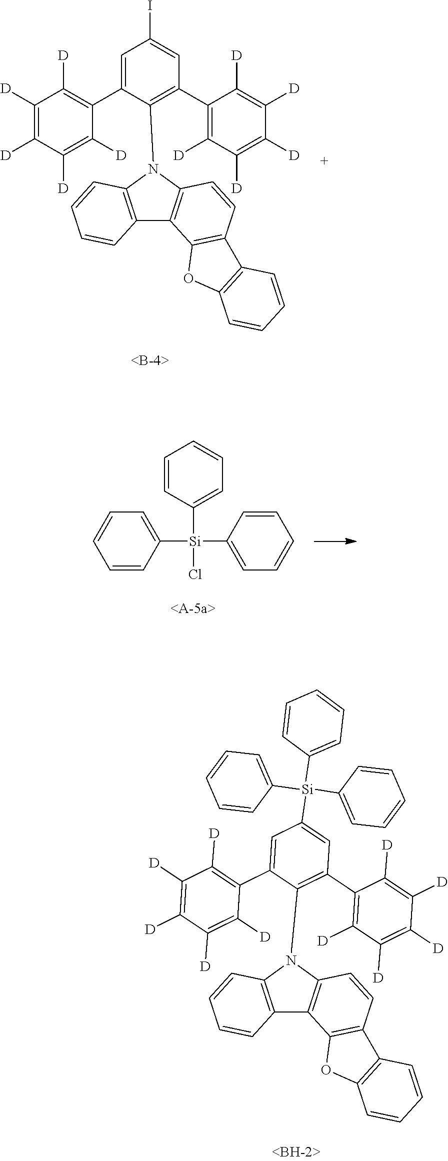 [SMILES: [2H]c1c([2H])c([2H])c(-c2cc(I)cc(-c3c([2H])c([2H])c([2H])c([2H])c3[2H])c2-n2c3ccccc3c3c4oc5ccccc5c4ccc32)c([2H])c1[2H] ; Cl[Si](c1ccccc1)(c1ccccc1)c1ccccc1 ; [2H]c1c([2H])c([2H])c(-c2cc([Si](c3ccccc3)(c3ccccc3)c3ccccc3)cc(-c3c([2H])c([2H])c([2H])c([2H])c3[2H])c2-n2c3ccccc3c3c4oc5ccccc5c4ccc32)c([2H])c1[2H]]

[BH-2] was obtained in the same manner as in Synthesis Example 1-5, except that <B-4> was used instead of <A-4>. (Yield 46%)

MS (MALDI-TOF): m/z 753.33 [M⁺]

### Synthesis Example 3: Synthesis of [BH-3]

### Synthesis Example 3-1: Synthesis of C-1

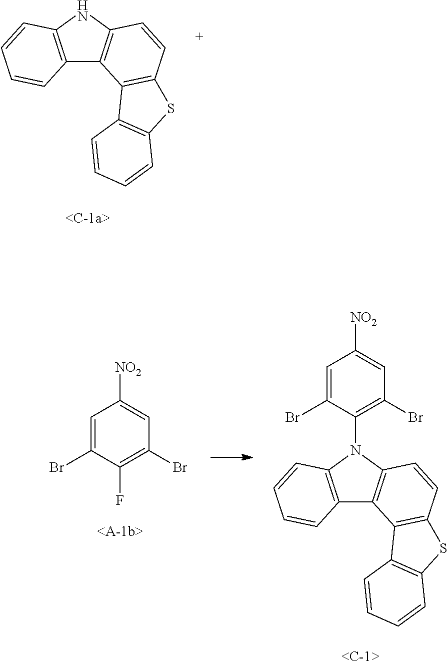 [SMILES: c1ccc2c(c1)[nH]c1ccc3sc4ccccc4c3c12 ; O=[N+]([O-])c1cc(Br)c(F)c(Br)c1 ; O=[N+]([O-])c1cc(Br)c(-n2c3ccccc3c3c4c(ccc32)sc2ccccc24)c(Br)c1]

<C-1> was obtained in the same manner as in Synthesis Example 1-1, except that <C-1a> was used instead of <A-1a>. (Yield 48%)

### Synthesis Example 3-2: Synthesis of C-2

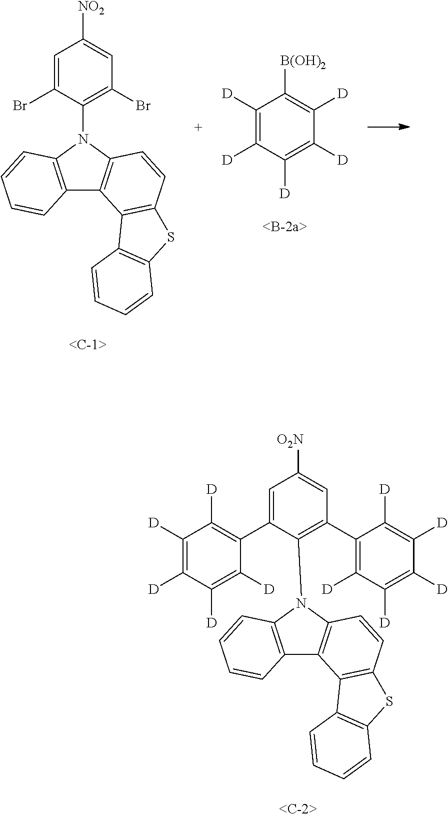 [SMILES: O=[N+]([O-])c1cc(Br)c(-n2c3ccccc3c3c4c(ccc32)sc2ccccc24)c(Br)c1 ; [2H]c1c([2H])c([2H])c(B(O)O)c([2H])c1[2H] ; [2H]c1c([2H])c([2H])c(-c2cc([N+](=O)[O-])cc(-c3c([2H])c([2H])c([2H])c([2H])c3[2H])c2-n2c3ccccc3c3c4c(ccc32)sc2ccccc24)c([2H])c1[2H]]

<C-2> was obtained in the same manner as in Synthesis Example 1-2, except that <C-1> was used instead of <A-1> and <B-2a> was used instead of <A-2a>. (Yield 54%)

### Synthesis Example 3-3: Synthesis of C-3

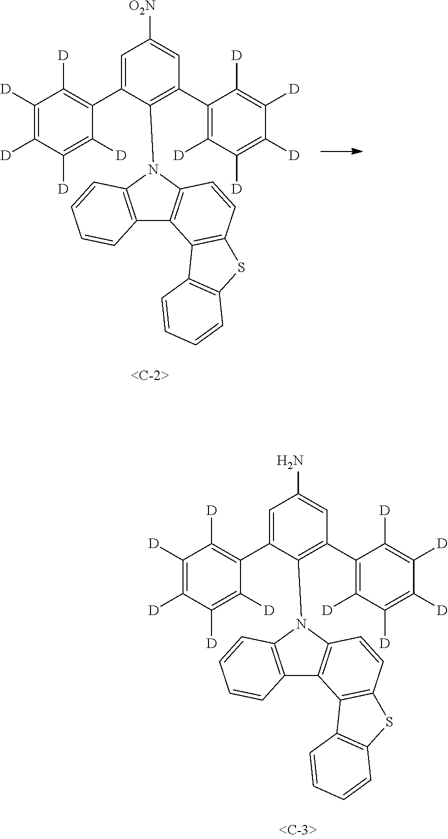 [SMILES: [2H]c1c([2H])c([2H])c(-c2cc([N+](=O)[O-])cc(-c3c([2H])c([2H])c([2H])c([2H])c3[2H])c2-n2c3ccccc3c3c4c(ccc32)sc2ccccc24)c([2H])c1[2H] ; [2H]c1c([2H])c([2H])c(-c2cc(N)cc(-c3c([2H])c([2H])c([2H])c([2H])c3[2H])c2-n2c3ccccc3c3c4c(ccc32)sc2ccccc24)c([2H])c1[2H]]

<C-3> was obtained in the same manner as in Synthesis Example 1-3, except that <C-2> was used instead of <A-2>. (Yield 81%)

### Synthesis Example 3-4: Synthesis of C-4

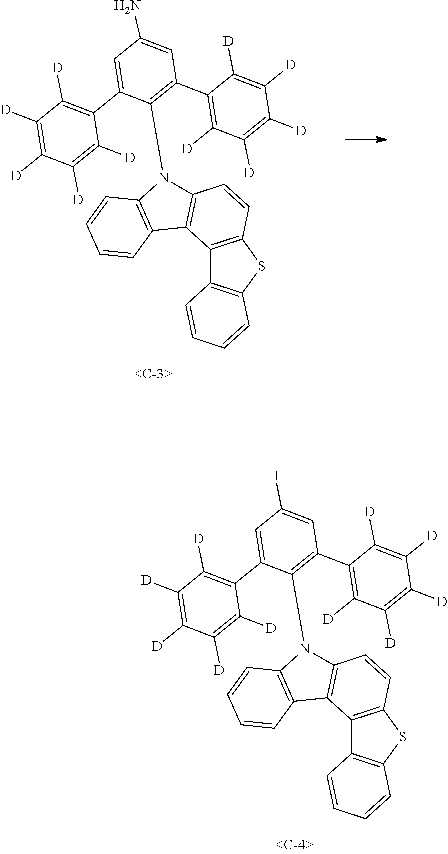 [SMILES: [2H]c1c([2H])c([2H])c(-c2cc(N)cc(-c3c([2H])c([2H])c([2H])c([2H])c3[2H])c2-n2c3ccccc3c3c4c(ccc32)sc2ccccc24)c([2H])c1[2H] ; [2H]c1c([2H])c([2H])c(-c2cc(I)cc(-c3c([2H])c([2H])c([2H])c([2H])c3[2H])c2-n2c3ccccc3c3c4c(ccc32)sc2ccccc24)c([2H])c1[2H]]

<C-4> was obtained in the same manner as in Synthesis Example 1-4, except that <C-3> was used instead of <A-3>. (Yield 83%)

### Synthesis Example 3-5: Synthesis of [BH-3]

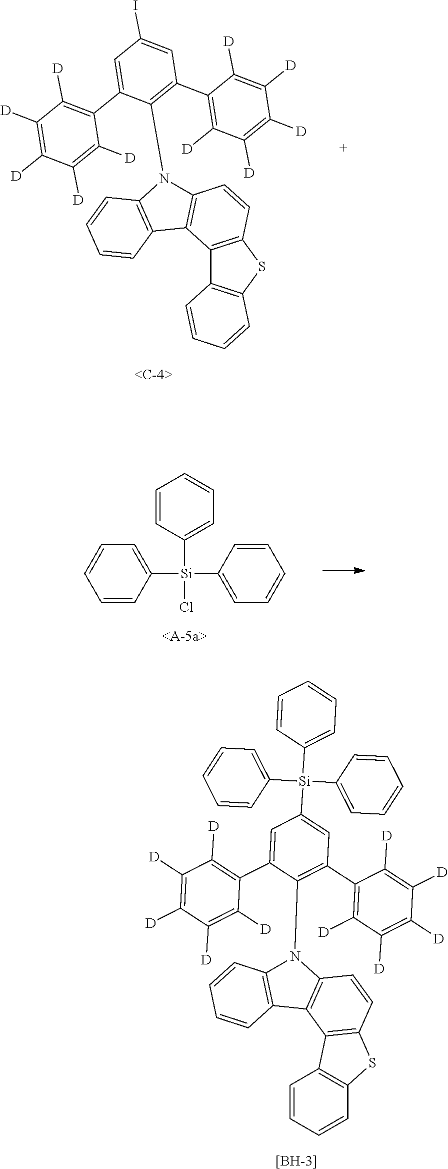

[BH-3] was obtained in the same manner as in Synthesis Example 1-5, except that <C-4> was used instead of <A-4>. (Yield 49%)

MS (MALDI-TOF): m/z 769.30 [M⁺]

### Synthesis Example 4: Synthesis of [BH-4]

### Synthesis Example 4-1: Synthesis of D-1

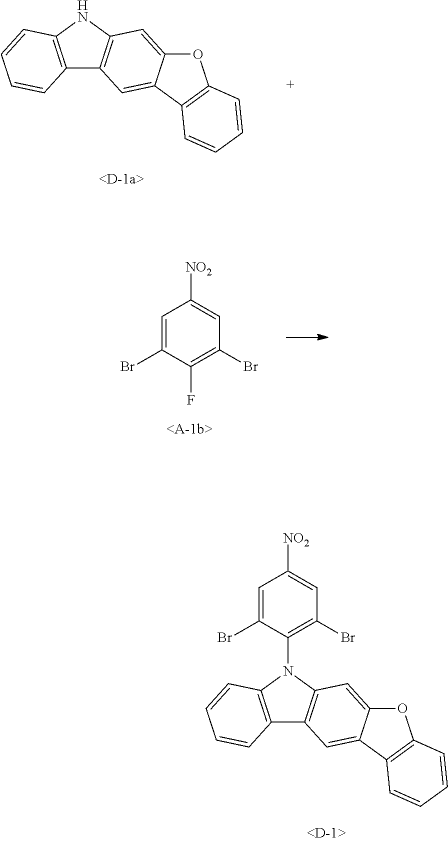 [SMILES: c1ccc2c(c1)[nH]c1cc3oc4ccccc4c3cc12 ; O=[N+]([O-])c1cc(Br)c(F)c(Br)c1 ; O=[N+]([O-])c1cc(Br)c(-n2c3ccccc3c3cc4c(cc32)oc2ccccc24)c(Br)c1]

<D-1> was obtained in the same manner as in Synthesis Example 1-1, except that <D-1a> was used instead of <A-1a>. (Yield 46%)

### Synthesis Example 4-2: Synthesis of D-2

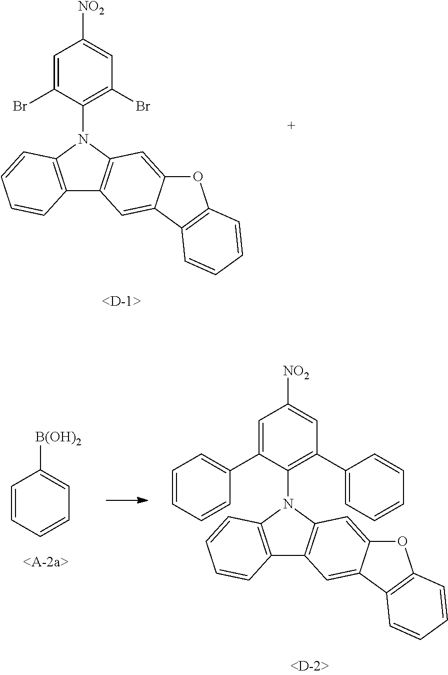 [SMILES: O=[N+]([O-])c1cc(Br)c(-n2c3ccccc3c3cc4c(cc32)oc2ccccc24)c(Br)c1 ; OB(O)c1ccccc1 ; O=[N+]([O-])c1cc(-c2ccccc2)c(-n2c3ccccc3c3cc4c(cc32)oc2ccccc24)c(-c2ccccc2)c1]

<D-2> was obtained in the same manner as in Synthesis Example 1-2, except that <D-1> was used instead of <A-1>. (Yield 51%)

### Synthesis Example 4-3: Synthesis of D-3

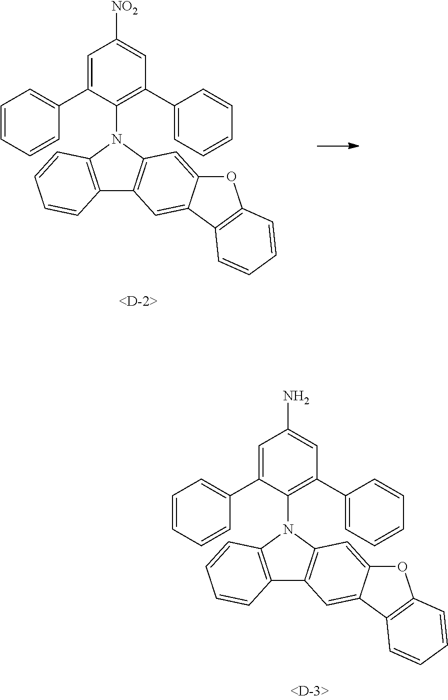 [SMILES: O=[N+]([O-])c1cc(-c2ccccc2)c(-n2c3ccccc3c3cc4c(cc32)oc2ccccc24)c(-c2ccccc2)c1 ; Nc1cc(-c2ccccc2)c(-n2c3ccccc3c3cc4c(cc32)oc2ccccc24)c(-c2ccccc2)c1]

<D-3> was obtained in the same manner as in Synthesis Example 1-3, except that <D-2> was used instead of <A-2>. (Yield 79%)

### Synthesis Example 4-4: Synthesis of D-4

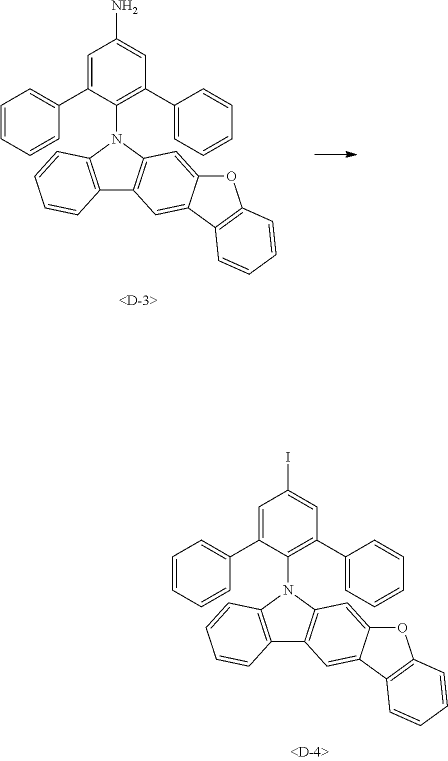 [SMILES: Nc1cc(-c2ccccc2)c(-n2c3ccccc3c3cc4c(cc32)oc2ccccc24)c(-c2ccccc2)c1 ; Ic1cc(-c2ccccc2)c(-n2c3ccccc3c3cc4c(cc32)oc2ccccc24)c(-c2ccccc2)c1]

<D-4> was obtained in the same manner as in Synthesis Example 1-4, except that <D-3> was used instead of <A-3>. (Yield 84%)

### Synthesis Example 4-5: Synthesis of [BH-4]

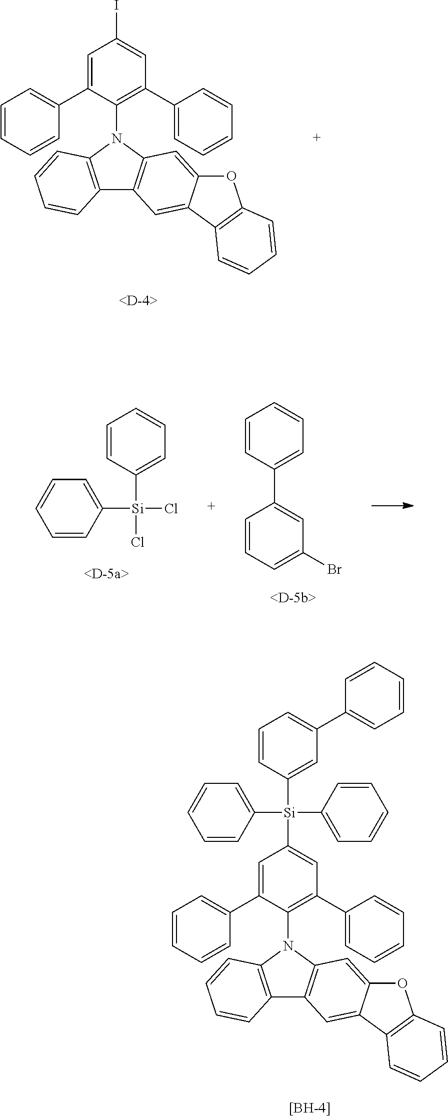

To a first round bottom flask, <D-5b>(4 g) and diethyl ether (30 mL) were introduced, and the mixture was cooled to −78° C. and stirred under a nitrogen condition. Then, n-BuLi (7.3 mL) was slowly added dropwise thereto, and the result was stirred for 2 hours at the low temperature. To a second round bottom flask, diethyl ether (25 mL) and <D-5a> (4 g) were introduced, and after adding the reaction material of the first round bottom flask thereto, the result was kept for 2 hours at −78° C. To a third round bottom flask, <D-4> (10.5 g) and THF (30 mL) were introduced, and after slowing adding n-BuLi (7.3 mL) dropwise thereto, the result was stirred for 1 hour at −78° C. Then, the reaction material of the second round bottom flask was added thereto, and the result was stirred for 24 hours at room temperature. After the reaction was finished, the reaction material was separated into layers. The organic layer was dried with MgSO₄, then concentrated under reduced pressure, and then separated and purified by column chromatography to obtain [BH-4]. (7.3 g, 52%)

MS (MALDI-TOF): m/z 819.30 [M⁺]

### Synthesis Example 5: Synthesis of [BH-5]

### Synthesis Example 5-1: Synthesis of E-1

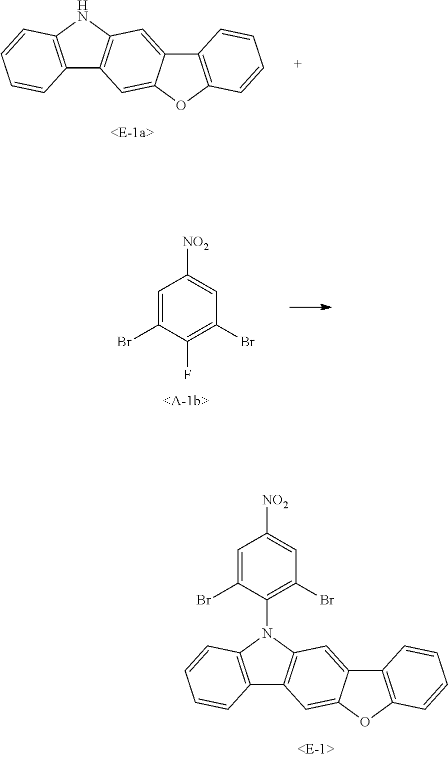 [SMILES: c1ccc2c(c1)[nH]c1cc3c(cc12)oc1ccccc13 ; O=[N+]([O-])c1cc(Br)c(F)c(Br)c1 ; O=[N+]([O-])c1cc(Br)c(-n2c3ccccc3c3cc4oc5ccccc5c4cc32)c(Br)c1]

<E-1> was obtained in the same manner as in Synthesis Example 1-1, except that <E-1a> was used instead of <A-1a>. (Yield 52%)

### Synthesis Example 5-2: Synthesis of E-2

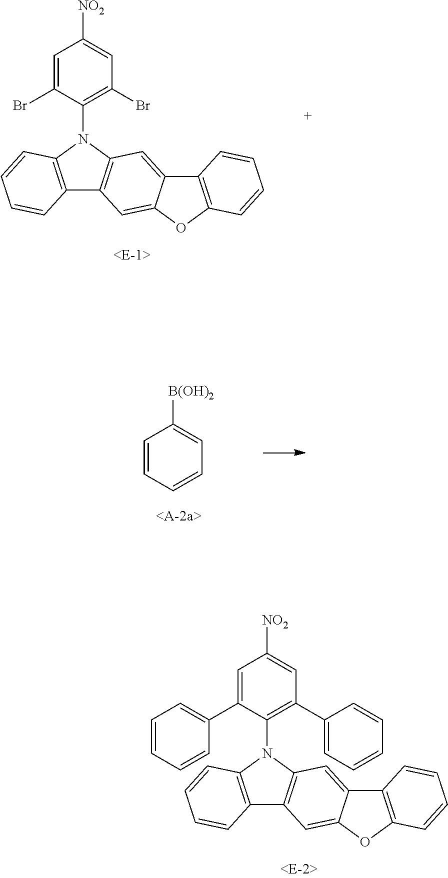 [SMILES: O=[N+]([O-])c1cc(Br)c(-n2c3ccccc3c3cc4oc5ccccc5c4cc32)c(Br)c1 ; OB(O)c1ccccc1 ; O=[N+]([O-])c1cc(-c2ccccc2)c(-n2c3ccccc3c3cc4oc5ccccc5c4cc32)c(-c2ccccc2)c1]

<E-2> was obtained in the same manner as in Synthesis Example 1-2, except that <E-1> was used instead of <A-1>. (Yield 50%)

### Synthesis Example 5-3: Synthesis of E-3

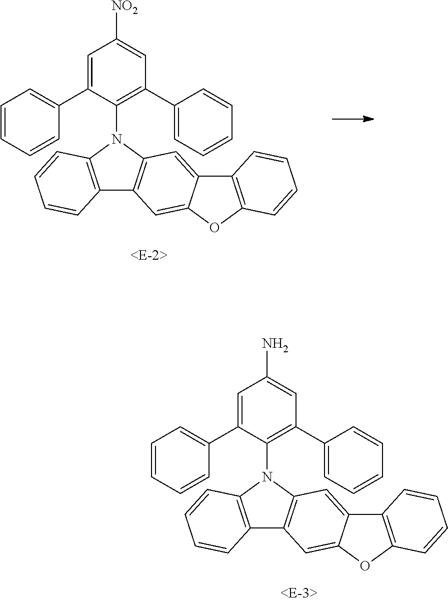 [SMILES: O=[N+]([O-])c1cc(-c2ccccc2)c(-n2c3ccccc3c3cc4oc5ccccc5c4cc32)c(-c2ccccc2)c1 ; Nc1cc(-c2ccccc2)c(-n2c3ccccc3c3cc4oc5ccccc5c4cc32)c(-c2ccccc2)c1]

<E-3> was obtained in the same manner as in Synthesis Example 1-3, except that <E-2> was used instead of <A-2>. (Yield 77%)

### Synthesis Example 5-4: Synthesis of E-4

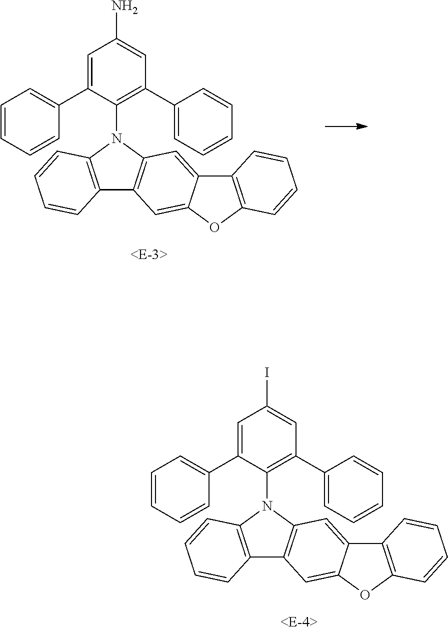 [SMILES: Nc1cc(-c2ccccc2)c(-n2c3ccccc3c3cc4oc5ccccc5c4cc32)c(-c2ccccc2)c1 ; Ic1cc(-c2ccccc2)c(-n2c3ccccc3c3cc4oc5ccccc5c4cc32)c(-c2ccccc2)c1]

<E-4> was obtained in the same manner as in Synthesis Example 1-4, except that <E-3> was used instead of <A-3>. (Yield 81%)

### Synthesis Example 5-5: Synthesis of [BH-5]

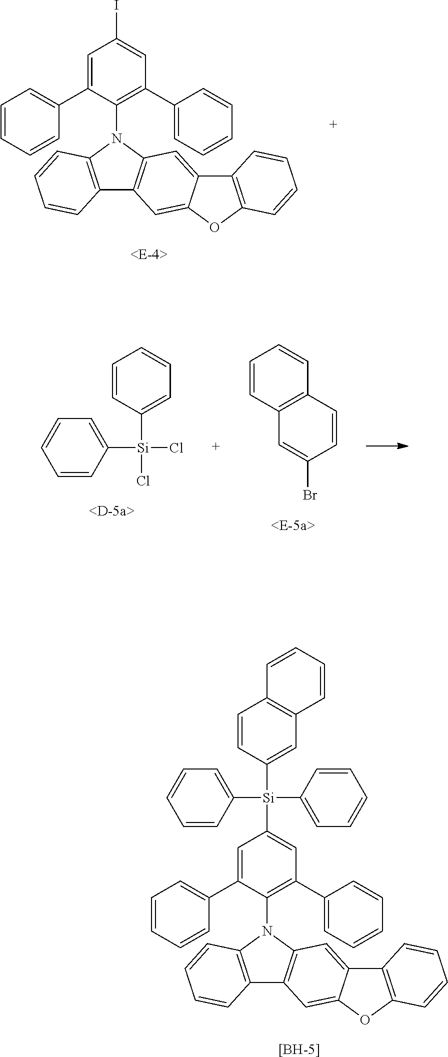

[BH-5] was obtained in the same manner as in Synthesis Example 4-5, except that <E-4> was used instead of <D-4> and <E-5a> was used instead of <D-5b>. (Yield 50%)

MS (MALDI-TOF): m/z 793.28 [M⁺]

### Synthesis Example 6: Synthesis of [BH-6]

### Synthesis Example 6-1: Synthesis of F-1

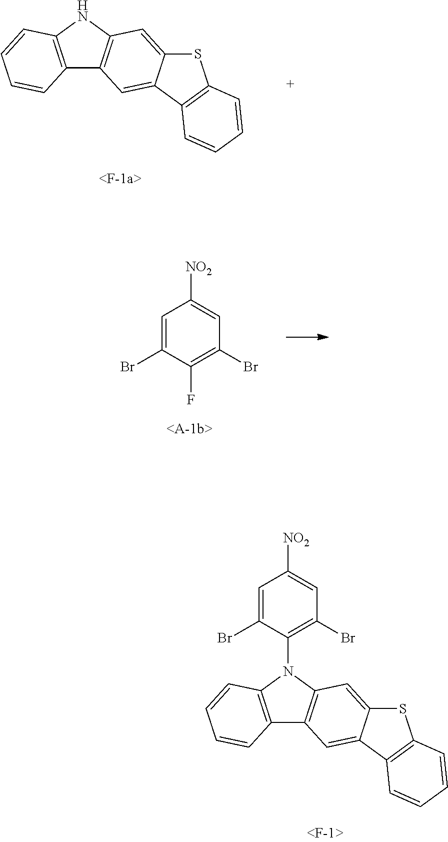 [SMILES: c1ccc2c(c1)[nH]c1cc3sc4ccccc4c3cc12 ; O=[N+]([O-])c1cc(Br)c(F)c(Br)c1 ; O=[N+]([O-])c1cc(Br)c(-n2c3ccccc3c3cc4c(cc32)sc2ccccc24)c(Br)c1]

<F-1> was obtained in the same manner as in Synthesis Example 1-1, except that <F-1a> was used instead of <A-1a>. (Yield 51%)

### Synthesis Example 6-2: Synthesis of F-2

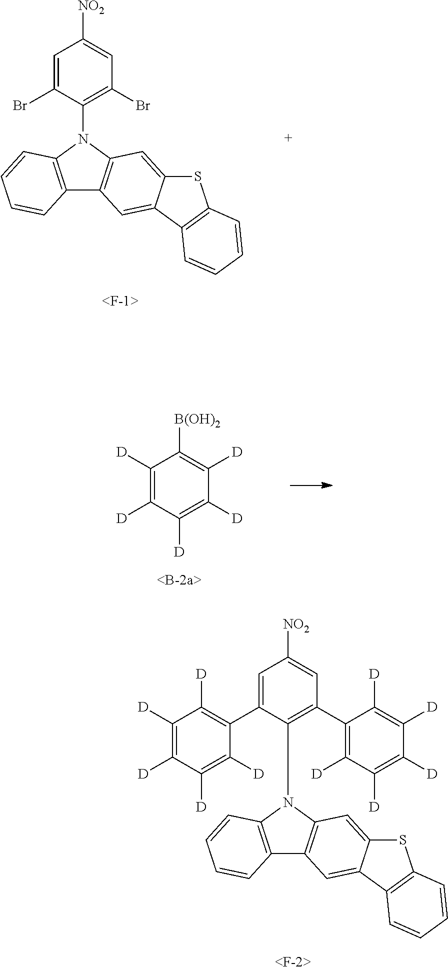 [SMILES: O=[N+]([O-])c1cc(Br)c(-n2c3ccccc3c3cc4c(cc32)sc2ccccc24)c(Br)c1 ; [2H]c1c([2H])c([2H])c(B(O)O)c([2H])c1[2H] ; [2H]c1c([2H])c([2H])c(-c2cc([N+](=O)[O-])cc(-c3c([2H])c([2H])c([2H])c([2H])c3[2H])c2-n2c3ccccc3c3cc4c(cc32)sc2ccccc24)c([2H])c1[2H]]

<F-2> was obtained in the same manner as in Synthesis Example 1-2, except that <F-1> was used instead of <A-1> and <B-2a> was used instead of <A-2a>. (Yield 55%)

### Synthesis Example 6-3: Synthesis of F-3

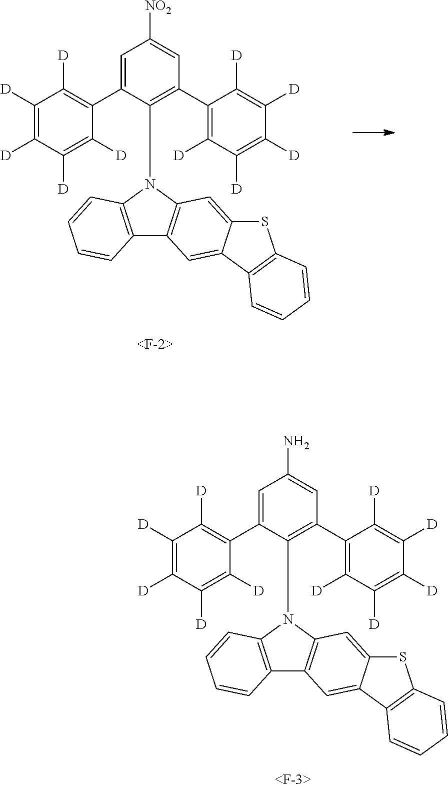 [SMILES: [2H]c1c([2H])c([2H])c(-c2cc([N+](=O)[O-])cc(-c3c([2H])c([2H])c([2H])c([2H])c3[2H])c2-n2c3ccccc3c3cc4c(cc32)sc2ccccc24)c([2H])c1[2H] ; [2H]c1c([2H])c([2H])c(-c2cc(N)cc(-c3c([2H])c([2H])c([2H])c([2H])c3[2H])c2-n2c3ccccc3c3cc4c(cc32)sc2ccccc24)c([2H])c1[2H]]

<F-3> was obtained in the same manner as in Synthesis Example 1-3, except that <F-2> was used instead of <A-2>. (Yield 80%)

### Synthesis Example 6-4: Synthesis of F-4

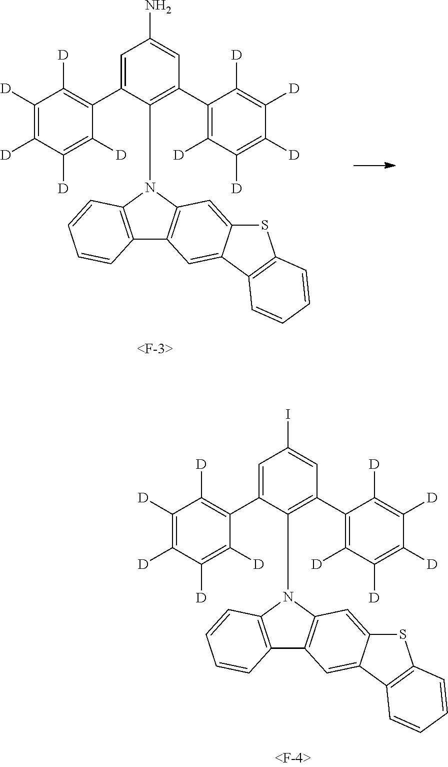 [SMILES: [2H]c1c([2H])c([2H])c(-c2cc(N)cc(-c3c([2H])c([2H])c([2H])c([2H])c3[2H])c2-n2c3ccccc3c3cc4c(cc32)sc2ccccc24)c([2H])c1[2H] ; [2H]c1c([2H])c([2H])c(-c2cc(I)cc(-c3c([2H])c([2H])c([2H])c([2H])c3[2H])c2-n2c3ccccc3c3cc4c(cc32)sc2ccccc24)c([2H])c1[2H]]

<F-4> was obtained in the same manner as in Synthesis Example 1-4, except that <F-3> was used instead of <A-3>. (Yield 81%)

### Synthesis Example 6-5: Synthesis of [BH-6]

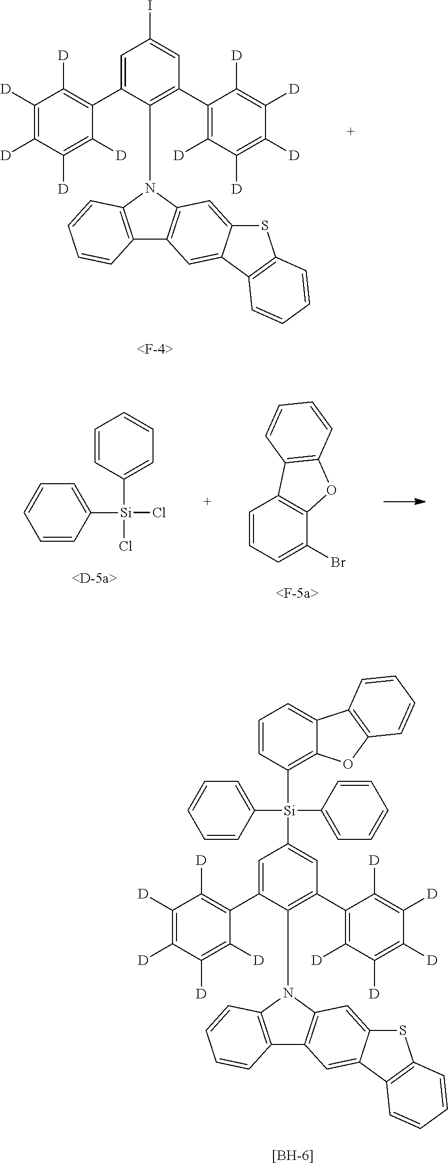

[BH-6] was obtained in the same manner as in Synthesis Example 4-5, except that <F-4> was used instead of <D-4> and <F-5a> was used instead of <D-5b>. (Yield 48%)

MS (MALDI-TOF): m/z 859.31 [M⁺]

### Synthesis Example 7: Synthesis of [BH-7]

### Synthesis Example 7-1: Synthesis of G-1

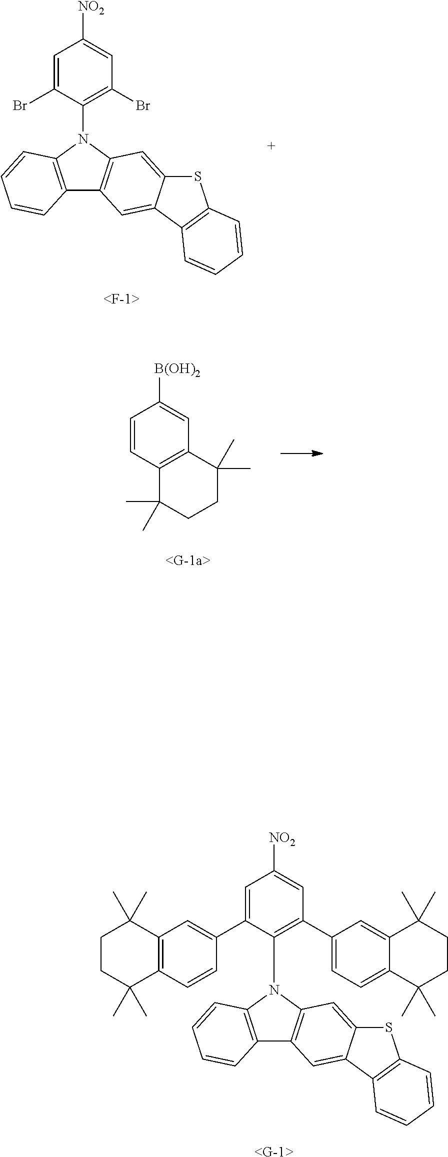

<G-1> was obtained in the same manner as in Synthesis Example 1-2, except that <F-1> was used instead of <A-1> and <G-1a> was used instead of <A-2a>. (Yield 45%)

### Synthesis Example 7-2: Synthesis of G-2

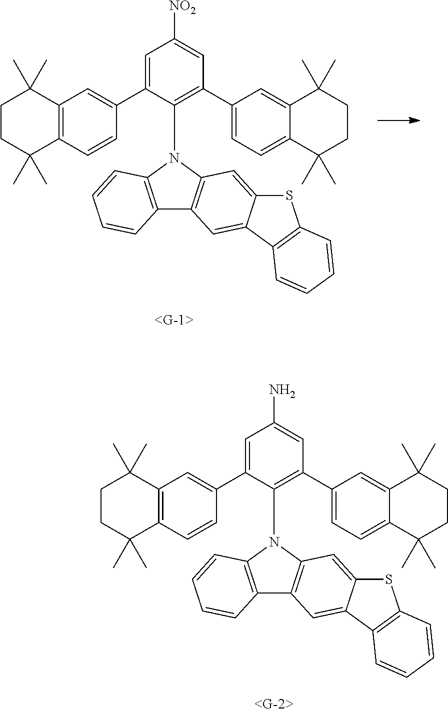

<G-2> was obtained in the same manner as in Synthesis Example 1-3, except that <G-1> was used instead of <A-2>. (Yield 74%)

### Synthesis Example 7-3: Synthesis of G-3

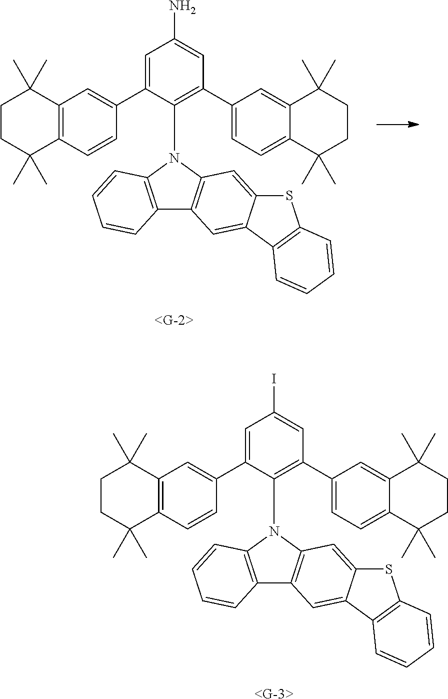

<G-3> was obtained in the same manner as in Synthesis Example 1-4, except that <G-2> was used instead of <A-3>. (Yield 79%)

### Synthesis Example 7-4: Synthesis of [BH-7]

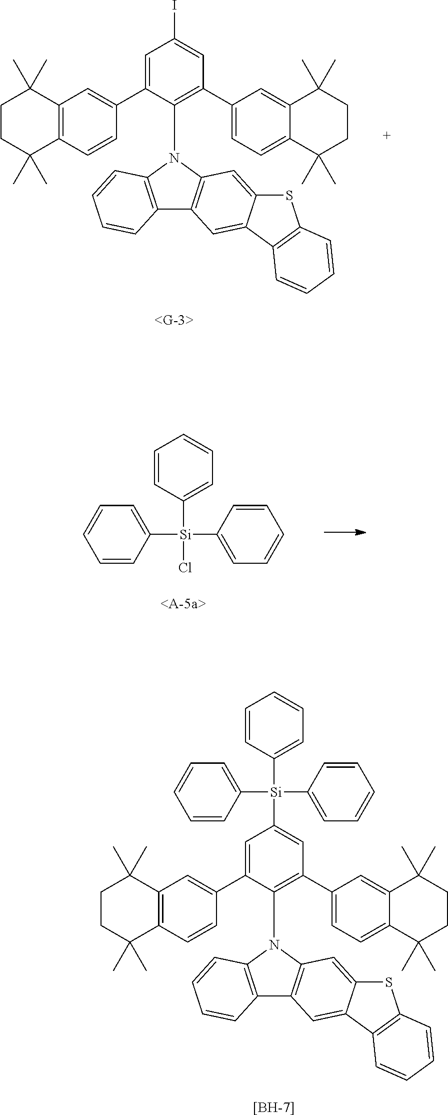

[BH-7] was obtained in the same manner as in Synthesis Example 1-5, except that <G-3> was used instead of <A-4>. (Yield 49%)

MS (MALDI-TOF): m/z 979.46 [M⁺]

### Synthesis Example 8: Synthesis of [BH-8]

### Synthesis Example 8-1: Synthesis of H-1

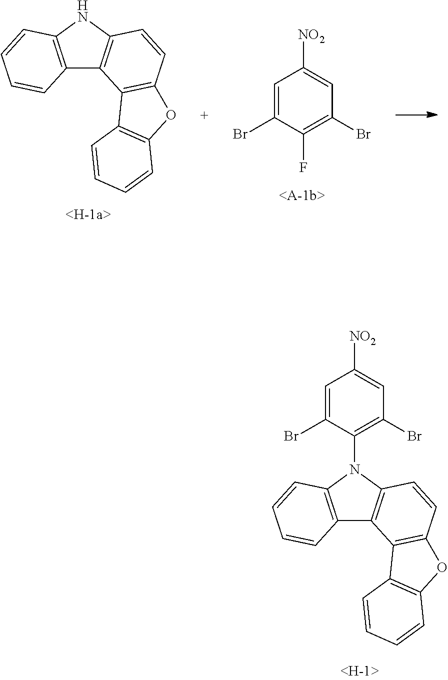 [SMILES: c1ccc2c(c1)[nH]c1ccc3oc4ccccc4c3c12 ; O=[N+]([O-])c1cc(Br)c(F)c(Br)c1 ; O=[N+]([O-])c1cc(Br)c(-n2c3ccccc3c3c4c(ccc32)oc2ccccc24)c(Br)c1]

<H-1> was obtained in the same manner as in Synthesis Example 1-1, except that <H-1a> was used instead of <A-1a>. (Yield 82%)

### Synthesis Example 8-2: Synthesis of H-2

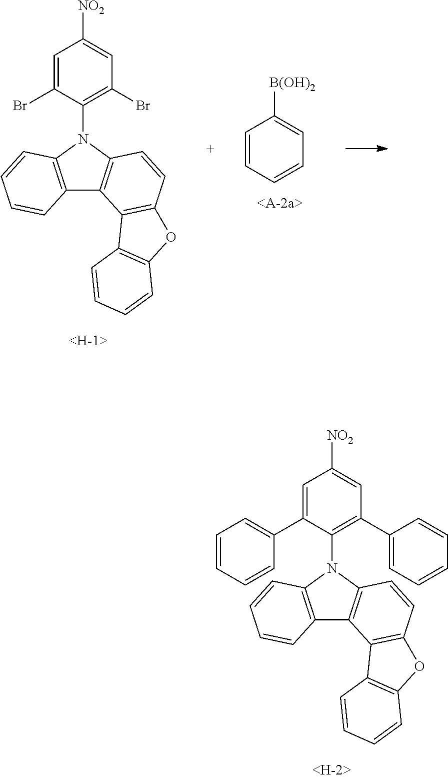 [SMILES: O=[N+]([O-])c1cc(Br)c(-n2c3ccccc3c3c4c(ccc32)oc2ccccc24)c(Br)c1 ; OB(O)c1ccccc1 ; O=[N+]([O-])c1cc(-c2ccccc2)c(-n2c3ccccc3c3c4c(ccc32)oc2ccccc24)c(-c2ccccc2)c1]

<H-2> was obtained in the same manner as in Synthesis Example 1-2, except that <H-1> was used instead of <A-1>. (Yield 53%)

### Synthesis Example 8-3: Synthesis of H-3

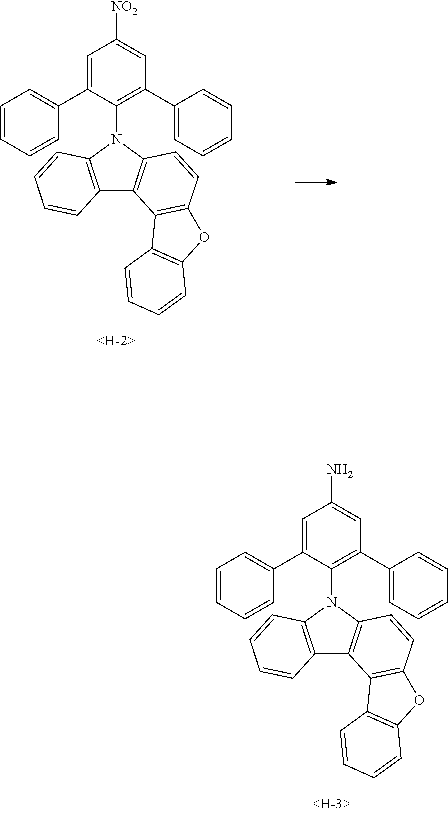 [SMILES: O=[N+]([O-])c1cc(-c2ccccc2)c(-n2c3ccccc3c3c4c(ccc32)oc2ccccc24)c(-c2ccccc2)c1 ; Nc1cc(-c2ccccc2)c(-n2c3ccccc3c3c4c(ccc32)oc2ccccc24)c(-c2ccccc2)c1]

<H-3> was obtained in the same manner as in Synthesis Example 1-3, except that <H-2> was used instead of <A-2>. (Yield 79%)

### Synthesis Example 8-4: Synthesis of H-4

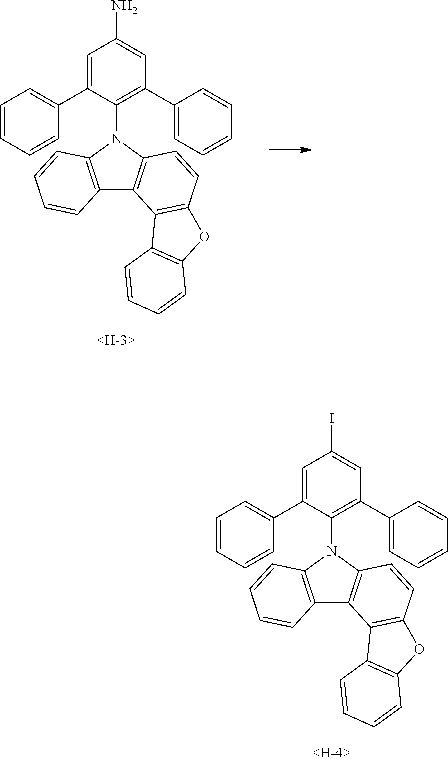 [SMILES: Nc1cc(-c2ccccc2)c(-n2c3ccccc3c3c4c(ccc32)oc2ccccc24)c(-c2ccccc2)c1 ; Ic1cc(-c2ccccc2)c(-n2c3ccccc3c3c4c(ccc32)oc2ccccc24)c(-c2ccccc2)c1]

<H-4> was obtained in the same manner as in Synthesis Example 1-4, except that <H-3> was used instead of <A-3>. (Yield 84%)

### Synthesis Example 8-5: Synthesis of [BH-8]

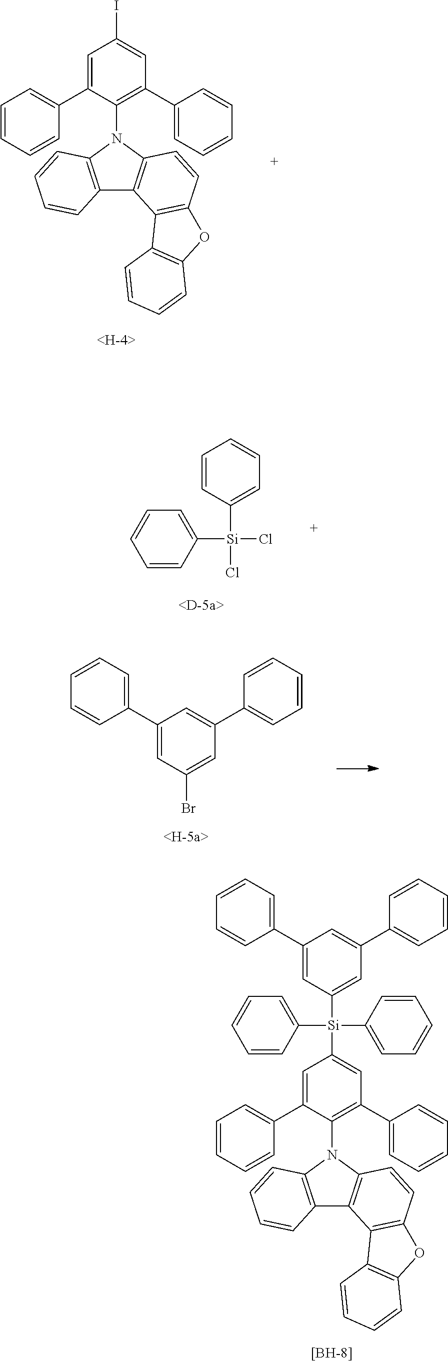

[BH-8] was obtained in the same manner as in Synthesis Example 4-5, except that <H-4> was used instead of <D-4> and <H-5a> was used instead of <D-5b>. (Yield 46%)

MS (MALDI-TOF): m/z 895.33 [M⁺]

### Synthesis Example 9: Synthesis of [BH-9]

### Synthesis Example 9-1: Synthesis of I-1

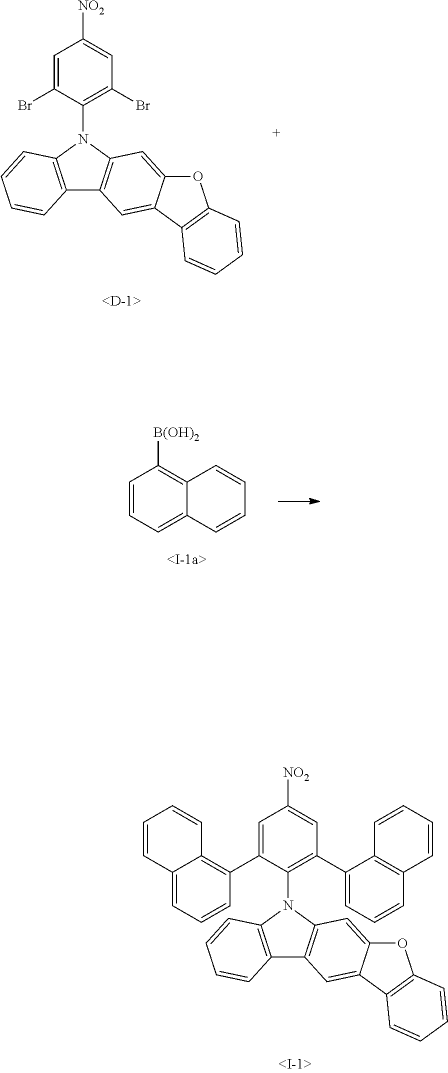 [SMILES: O=[N+]([O-])c1cc(Br)c(-n2c3ccccc3c3cc4c(cc32)oc2ccccc24)c(Br)c1 ; OB(O)c1cccc2ccccc12 ; O=[N+]([O-])c1cc(-c2cccc3ccccc23)c(-n2c3ccccc3c3cc4c(cc32)oc2ccccc24)c(-c2cccc3ccccc23)c1]

<1-1> was obtained in the same manner as in Synthesis Example 1-2, except that <D-1> was used instead of <A-1> and <I-1a> was used instead of <A-2a>. (Yield 50%)

### Synthesis Example 9-2: Synthesis of I-2

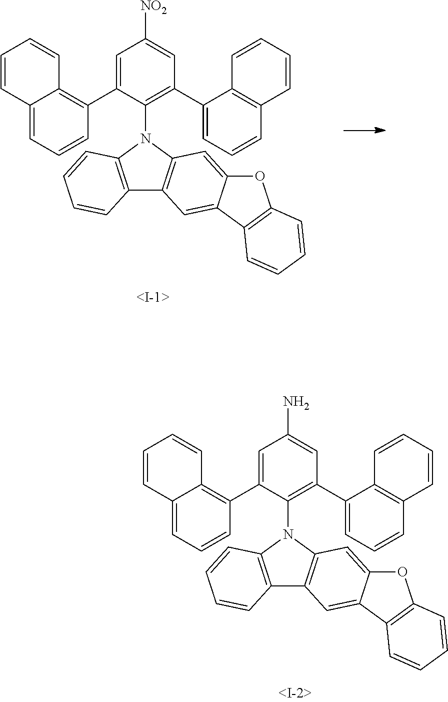 [SMILES: O=[N+]([O-])c1cc(-c2cccc3ccccc23)c(-n2c3ccccc3c3cc4c(cc32)oc2ccccc24)c(-c2cccc3ccccc23)c1 ; Nc1cc(-c2cccc3ccccc23)c(-n2c3ccccc3c3cc4c(cc32)oc2ccccc24)c(-c2cccc3ccccc23)c1]

<1-2> was obtained in the same manner as in Synthesis Example 1-3, except that <1-1> was used instead of <A-2>. (Yield 77%)

### Synthesis Example 9-3: Synthesis of I-3

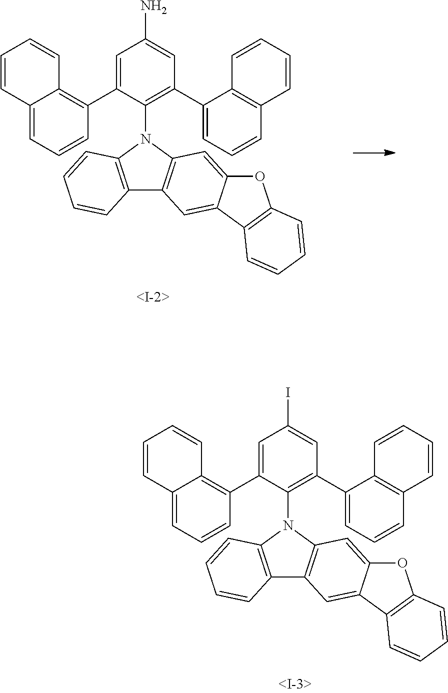 [SMILES: Nc1cc(-c2cccc3ccccc23)c(-n2c3ccccc3c3cc4c(cc32)oc2ccccc24)c(-c2cccc3ccccc23)c1 ; Ic1cc(-c2cccc3ccccc23)c(-n2c3ccccc3c3cc4c(cc32)oc2ccccc24)c(-c2cccc3ccccc23)c1]

<1-3> was obtained in the same manner as in Synthesis Example 1-4, except that <1-2> was used instead of <A-3>. (Yield 81%)

### Synthesis Example 9-4: Synthesis of [BH-9]

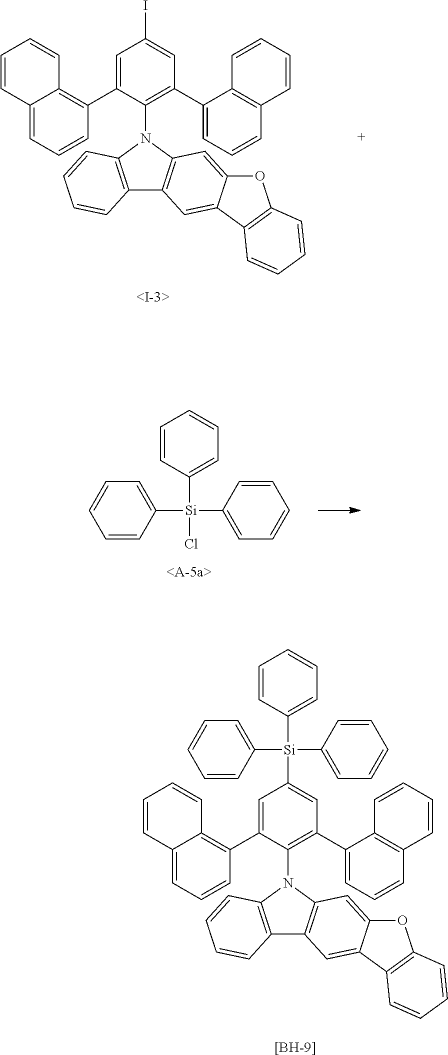

[BH-9] was obtained in the same manner as in Synthesis Example 1-5, except that <1-3> was used instead of <A-4>. (Yield 49%)

MS (MALDI-TOF): m/z 843.30 [M⁺]

### Synthesis Example 10: Synthesis of [BH-10]

### Synthesis Example 10-1: Synthesis of J-1

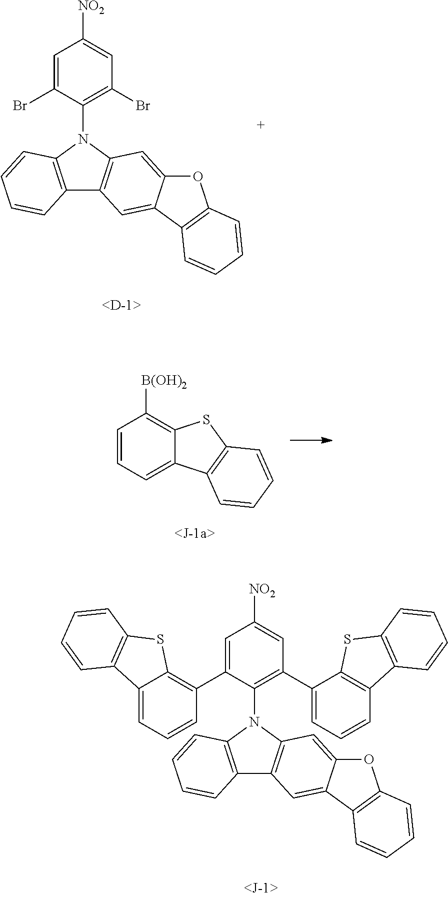 [SMILES: O=[N+]([O-])c1cc(Br)c(-n2c3ccccc3c3cc4c(cc32)oc2ccccc24)c(Br)c1 ; OB(O)c1cccc2c1sc1ccccc12 ; O=[N+]([O-])c1cc(-c2cccc3c2sc2ccccc23)c(-n2c3ccccc3c3cc4c(cc32)oc2ccccc24)c(-c2cccc3c2sc2ccccc23)c1]

<J-1> was obtained in the same manner as in Synthesis Example 1-2, except that <D-1> was used instead of <A-1> and <J-1a> was used instead of <A-2a>. (Yield 56%)

### Synthesis Example 10-2: Synthesis of J-2

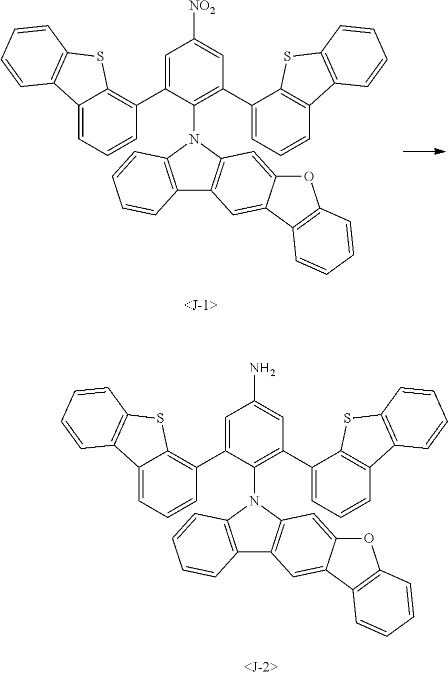 [SMILES: O=[N+]([O-])c1cc(-c2cccc3c2sc2ccccc23)c(-n2c3ccccc3c3cc4c(cc32)oc2ccccc24)c(-c2cccc3c2sc2ccccc23)c1 ; Nc1cc(-c2cccc3c2sc2ccccc23)c(-n2c3ccccc3c3cc4c(cc32)oc2ccccc24)c(-c2cccc3c2sc2ccccc23)c1]

<J-2> was obtained in the same manner as in Synthesis Example 1-3, except that <J-1> was used instead of <A-2>. (Yield 75%)

### Synthesis Example 10-3: Synthesis of J-3

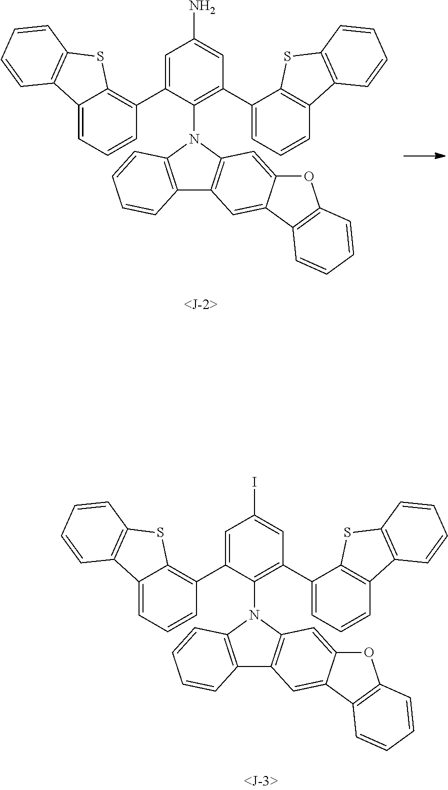 [SMILES: Nc1cc(-c2cccc3c2sc2ccccc23)c(-n2c3ccccc3c3cc4c(cc32)oc2ccccc24)c(-c2cccc3c2sc2ccccc23)c1 ; Ic1cc(-c2cccc3c2sc2ccccc23)c(-n2c3ccccc3c3cc4c(cc32)oc2ccccc24)c(-c2cccc3c2sc2ccccc23)c1]

<J-3> was obtained in the same manner as in Synthesis Example 1-4, except that <J-2> was used instead of <A-3>. (Yield 83%)

### Synthesis Example 10-4: Synthesis of [BH-10]

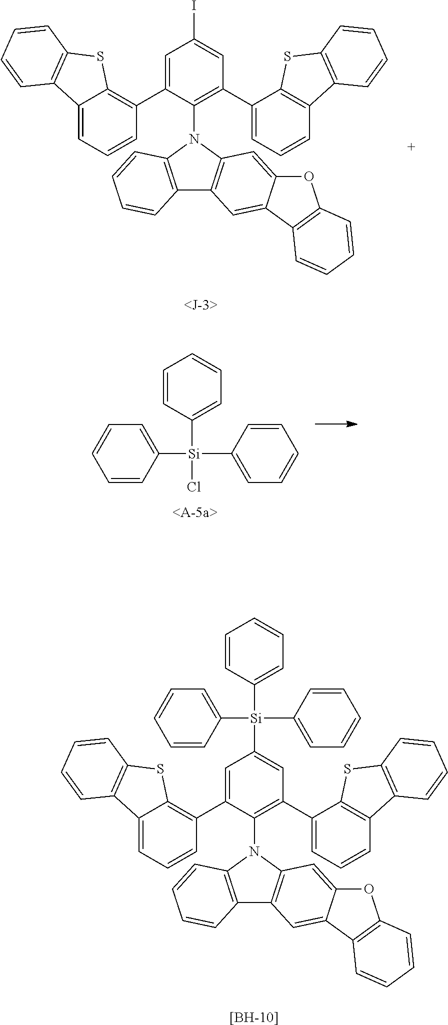

[BH-10] was obtained in the same manner as in Synthesis Example 1-5, except that <J-3> was used instead of <A-4>. (Yield 53%)

MS (MALDI-TOF): m/z 955.24 [M⁺]

### Synthesis Example 11: Synthesis of [BH-11]

### Synthesis Example 11-1: Synthesis of K-1

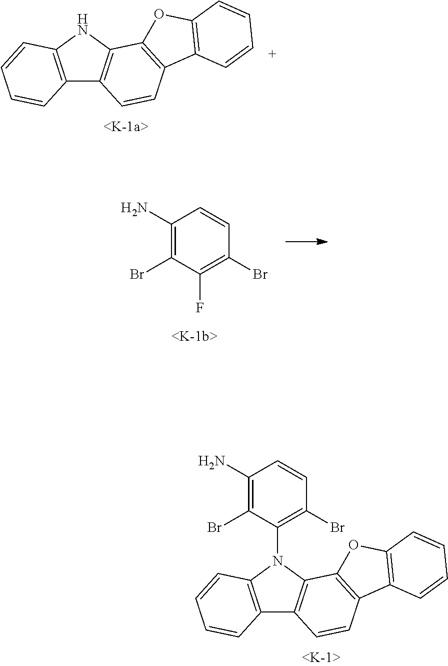 [SMILES: c1ccc2c(c1)[nH]c1c2ccc2c3ccccc3oc21 ; Nc1ccc(Br)c(F)c1Br ; Nc1ccc(Br)c(-n2c3ccccc3c3ccc4c5ccccc5oc4c32)c1Br]

<K-1> was obtained in the same manner as in Synthesis Example 1-1, except that <K-1a> was used instead of <A-1a> and <K-1b> was used instead of <A-1b>. (Yield 42%)

### Synthesis Example 11-2: Synthesis of K-2

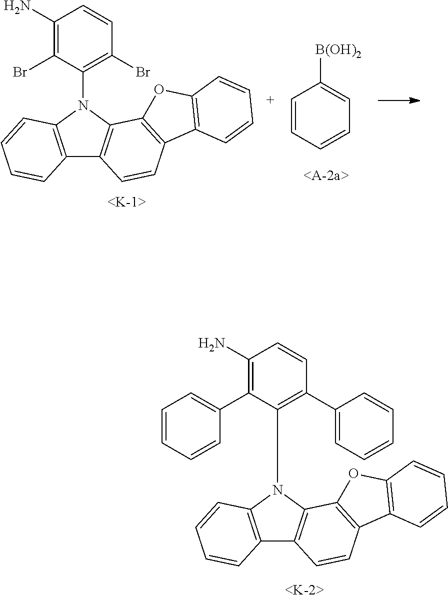

<K-2> was obtained in the same manner as in Synthesis Example 1-2, except that <K-1> was used instead of <A-1>. (Yield 37%)

### Synthesis Example 11-3: Synthesis of K-3

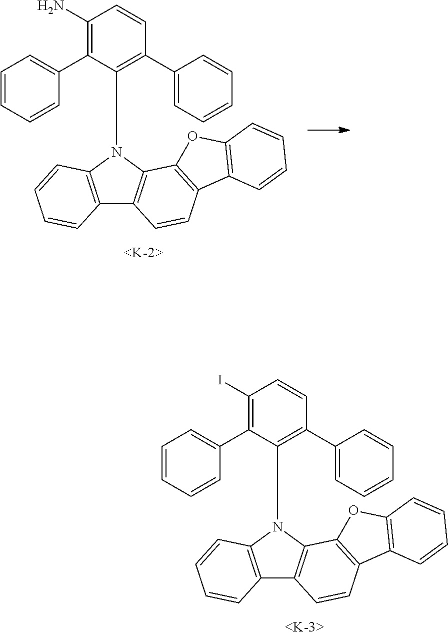 [SMILES: Nc1ccc(-c2ccccc2)c(-n2c3ccccc3c3ccc4c5ccccc5oc4c32)c1-c1ccccc1 ; Ic1ccc(-c2ccccc2)c(-n2c3ccccc3c3ccc4c5ccccc5oc4c32)c1-c1ccccc1]

<K-3> was obtained in the same manner as in Synthesis Example 1-4, except that <K-2> was used instead of <A-3>. (Yield 86%)

### Synthesis Example 11-4: Synthesis of [BH-11]

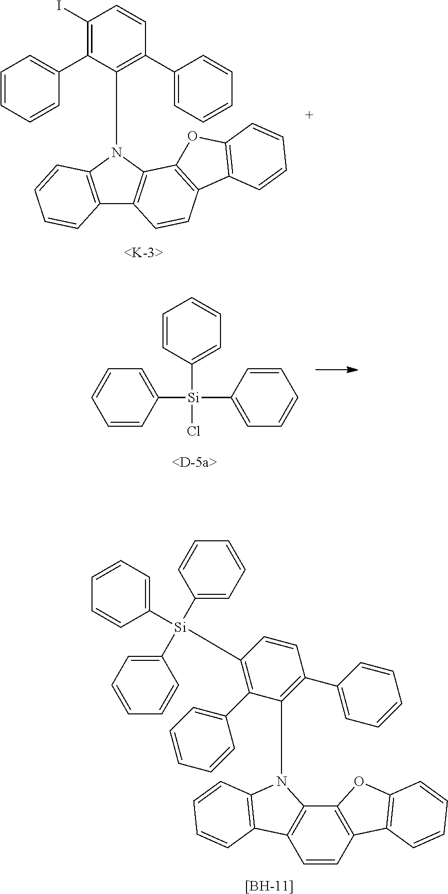

[BH-11] was obtained in the same manner as in Synthesis Example 1-5, except that <K-3> was used instead of <A-4>. (Yield 42%)

MS (MALDI-TOF): m/z 743.26 [M⁺]

### Synthesis Example 12: Synthesis of [BH-12]

### Synthesis Example 12-1: Synthesis of [BH-12]

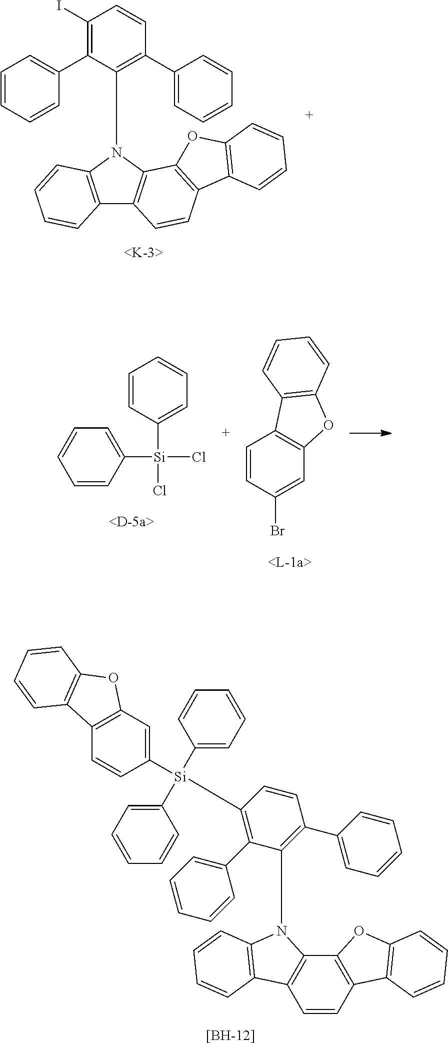

[BH-12] was obtained in the same manner as in Synthesis Example 4-5, except that <K-3> was used instead of <D-4> and < L-1a> was used instead of <D-5b>. (Yield 46%)

MS (MALDI-TOF): m/z 833.28 [M⁺]

### Synthesis Example 13: Synthesis of [BH-13]

### Synthesis Example 13-1: Synthesis of M-1

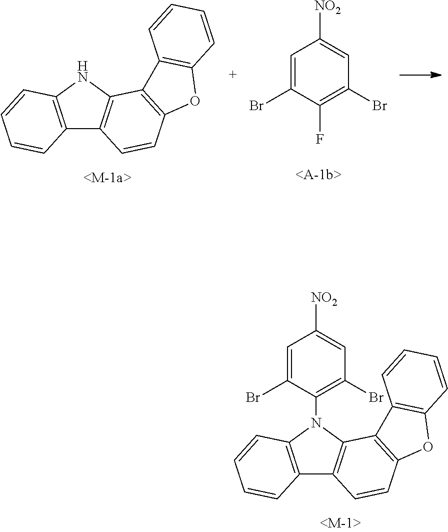 [SMILES: c1ccc2c(c1)[nH]c1c2ccc2oc3ccccc3c21 ; O=[N+]([O-])c1cc(Br)c(F)c(Br)c1 ; O=[N+]([O-])c1cc(Br)c(-n2c3ccccc3c3ccc4oc5ccccc5c4c32)c(Br)c1]

<M-1> was obtained in the same manner as in Synthesis Example 1-1, except that <M-1a> was used instead of <A-1a>. (Yield 42%)

### Synthesis Example 13-2: Synthesis of M-2

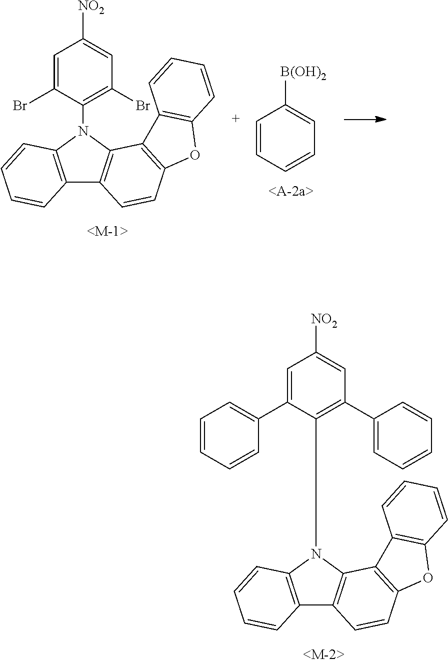 [SMILES: O=[N+]([O-])c1cc(Br)c(-n2c3ccccc3c3ccc4oc5ccccc5c4c32)c(Br)c1 ; OB(O)c1ccccc1 ; O=[N+]([O-])c1cc(-c2ccccc2)c(-n2c3ccccc3c3ccc4oc5ccccc5c4c32)c(-c2ccccc2)c1]

<M-2> was obtained in the same manner as in Synthesis Example 1-2, except that <M-1> was used instead of <A-1>. (Yield 45%)

### Synthesis Example 13-3: Synthesis of M-3

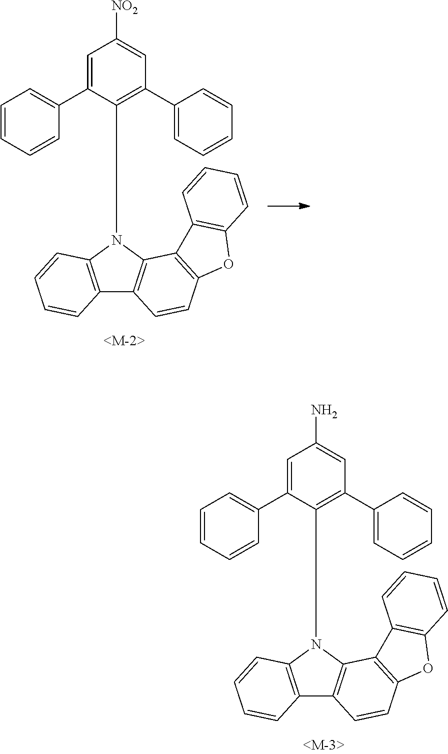 [SMILES: O=[N+]([O-])c1cc(-c2ccccc2)c(-n2c3ccccc3c3ccc4oc5ccccc5c4c32)c(-c2ccccc2)c1 ; Nc1cc(-c2ccccc2)c(-n2c3ccccc3c3ccc4oc5ccccc5c4c32)c(-c2ccccc2)c1]

<M-3> was obtained in the same manner as in Synthesis Example 1-3, except that <M-2> was used instead of <A-2>. (Yield 85%)

### Synthesis Example 13-4: Synthesis of M-4

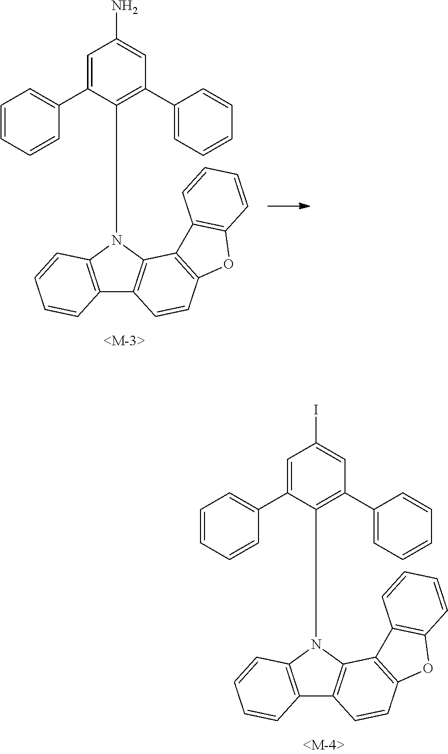 [SMILES: Nc1cc(-c2ccccc2)c(-n2c3ccccc3c3ccc4oc5ccccc5c4c32)c(-c2ccccc2)c1 ; Ic1cc(-c2ccccc2)c(-n2c3ccccc3c3ccc4oc5ccccc5c4c32)c(-c2ccccc2)c1]

<M-4> was obtained in the same manner as in Synthesis Example 1-4, except that <M-3> was used instead of <A-3>. (Yield 83%)

### Synthesis Example 13-5: Synthesis of [BH-13]

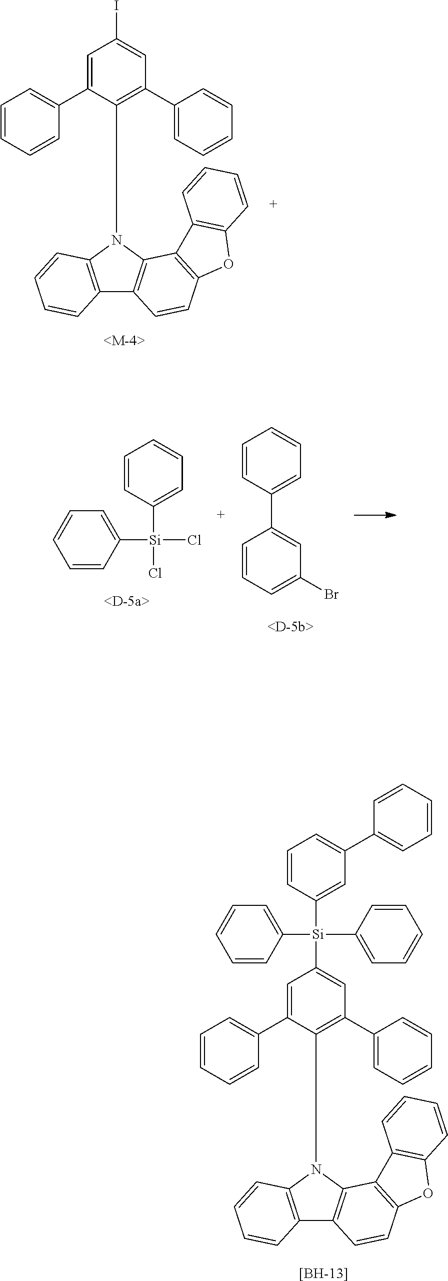

[BH-13] was obtained in the same manner as in Synthesis Example 4-5, except that <M-4> was used instead of <D-4>. (Yield 51%)

MS (MALDI-TOF): m/z 819.30 [M⁺]

### Examples 1 to 13: Manufacture of Organic Light Emitting Device

An ITO glass was patterned to have a light emitting area of 2 mm×2 mm, and then cleaned. The ITO glass was installed in a vacuum chamber, and after setting the base pressure at 1×10⁻⁶ torr, HAT-CN (50 Å) was deposited as a hole injecting layer, BCFN (600 Å) was deposited as a hole transport layer, and then PBCz (50 Å) was deposited as an electron blocking layer on the ITO. As a light emitting layer, the organic compound according to the present invention as a first host compound, the following ET-1 as a second host compound and the following PBD as a dopant compound were mixed in 12 wt % of the total weight of the light emitting layer and then deposited (350 Å). mSiTrz (50 Å) was deposited as a hole blocking layer, mSiTrz:Liq (300 Å) were deposited in a ratio of 1:1 as an electron injection and transport layer, and then Liq (10 Å) was deposited as an electron injecting layer sequentially, and Al (1000 Å) was deposited as a cathode to manufacture an organic light emitting device. Luminous characteristics of the organic light emitting device were measured at 0.4 mA.

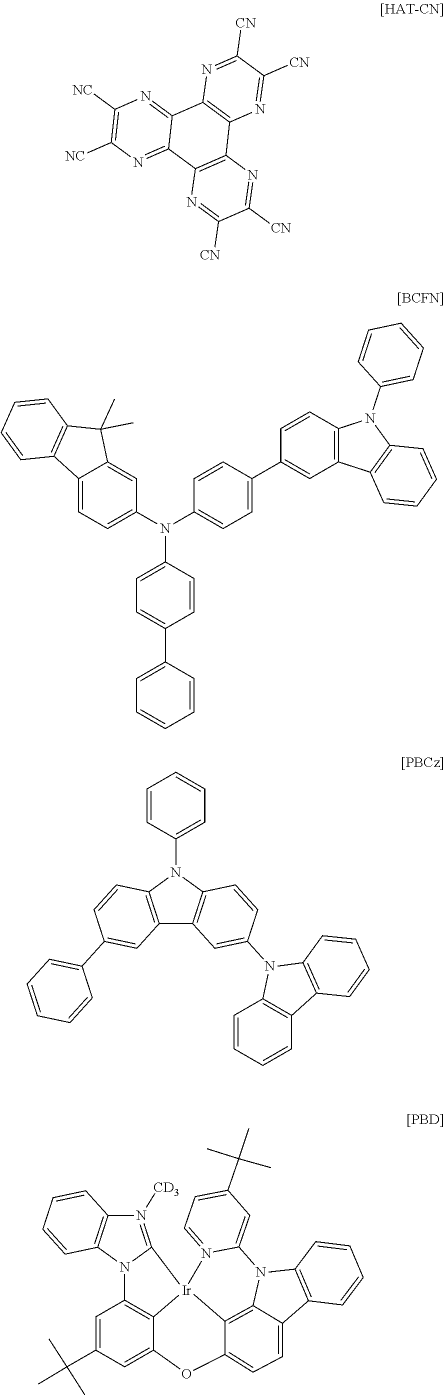

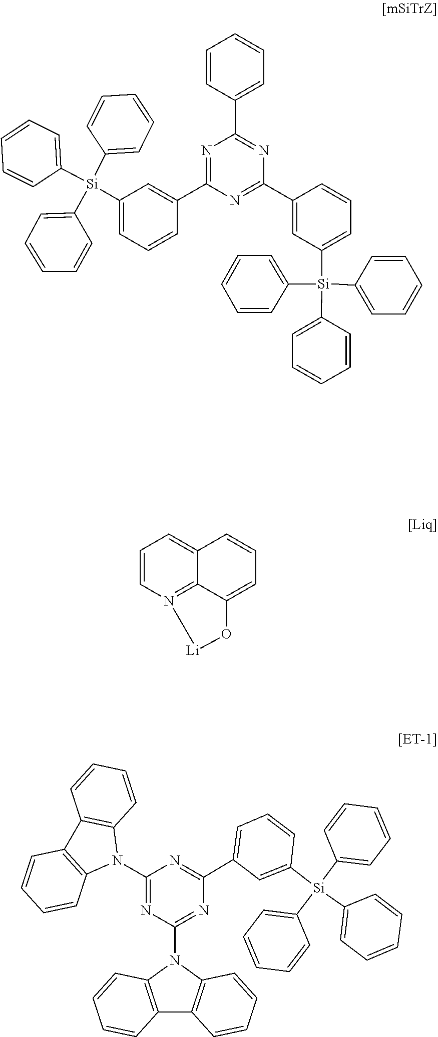

### Comparative Examples 1 and 2

Organic light emitting devices for Comparative Examples were manufactured in the same manner as in Examples, except that the following [RH-1] and [RH-2] were used as the host compound instead of the organic compound according to the present invention in the device structure of Examples, and luminous characteristics of the organic light emitting devices were measured at 0.4 mA. The structures of [RH-1]and [RH-2] are as follows.

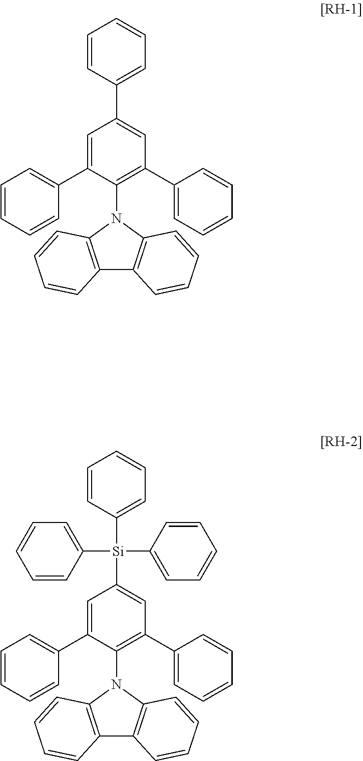 [SMILES: c1ccc(-c2cc(-c3ccccc3)c(-n3c4ccccc4c4ccccc43)c(-c3ccccc3)c2)cc1 ; c1ccc(-c2cc([Si](c3ccccc3)(c3ccccc3)c3ccccc3)cc(-c3ccccc3)c2-n2c3ccccc3c3ccccc32)cc1]

TABLE 1

| | | | | External | | Light |
|---|---|---|---|---|---|---|
| | Host (1:1) | | Driving | Quantum | Lifetime | Emitting |
| | First | Second | Voltage | Efficiency | (T95, | Color |
| Category | Host | Host | (V) | (EQE, %) | hr) | (Color) |
| Example 1 | BH-1 | ET-1 | 4.2 | 14.7 | 145 | Blue |
| Example 2 | BH-2 | ET-1 | 4.2 | 15.6 | 173 | Blue |
| Example 3 | BH-3 | ET-1 | 4.2 | 15.4 | 165 | Blue |
| Example 4 | BH-4 | ET-1 | 4.2 | 15.8 | 162 | Blue |
| Example 5 | BH-5 | ET-1 | 4.2 | 15.4 | 160 | Blue |
| Example 6 | BH-6 | ET-1 | 4.3 | 15.6 | 142 | Blue |
| Example 7 | BH-7 | ET-1 | 4.2 | 15.2 | 159 | Blue |
| Example 8 | BH-8 | ET-1 | 4.5 | 14.9 | 146 | Blue |
| Example 9 | BH-9 | ET-1 | 4.3 | 15.5 | 158 | Blue |
| Example 10 | BH-10 | ET-1 | 4.5 | 15.8 | 144 | Blue |
| Example 11 | BH-11 | ET-1 | 4.6 | 15.1 | 145 | Blue |
| Example 12 | BH-12 | ET-1 | 4.6 | 14.9 | 134 | Blue |
| Example 13 | BH-13 | ET-1 | 4.6 | 15.0 | 160 | Blue |
| Comparative | RH-1 | ET-1 | 5.2 | 9.6 | 67 | Blue |
| Example 1 | | | | | | |
| Comparative | RH-2 | ET-1 | 5.1 | 11.7 | 90 | Blue |
| Example 2 | | | | | | |

As shown in [Table 1], the device employing the compound according to the present invention as a light emitting layer host compound in the organic light emitting device may be embodied as a high-efficiency and long-lifetime organic light emitting device with excellent external quantum efficiency and lifetime properties at a low driving voltage compared to the devices (Comparative Examples 1 and 2) employing compounds widely used in the related art having structures in contrast to the characteristic structures of the organic compound according to the present invention.

### Examples 14 to 18: Manufacture of Organic Light Emitting Device

Organic light emitting devices were manufactured and experimented in the same manner as the organic light emitting devices used in Examples 1 to 13, except that, as the dopant compound according to the present invention, a compound of the following TBD was further mixed in 0.5 wt % of the total weight of the light emitting layer. Luminous characteristics of the organic light emitting devices were measured at 0.4 mA, and the measurement results are shown in the following Table 2. Herein, the structure of [TBD] is as follows.

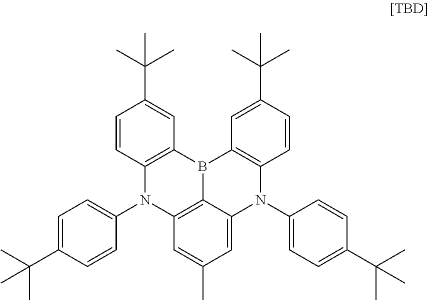 [SMILES: Cc1cc2c3c(c1)N(c1ccc(C(C)(C)C)cc1)c1ccc(C(C)(C)C)cc1B3c1cc(C(C)(C)C)ccc1N2c1ccc(C(C)(C)C)cc1]

### Comparative Examples 3 and 4: Manufacture of Organic Light Emitting Device

Organic light emitting devices for Comparative Examples were manufactured in the same manner as in Examples, except that [RH-1] and [RH-2] were used as the host compound instead of the organic compound according to the present invention in the device structure of Examples, and luminous characteristics of the organic light emitting devices were measured at 0.4 mA.

TABLE 2

| | | | | External | | Light |
|---|---|---|---|---|---|---|
| | Host (1:1) | | Driving | Quantum | Lifetime | Emitting |
| | First | Second | Voltage | Efficiency | (T95, | Color |
| Category | Host | Host | (V) | (EQE, %) | hr) | (Color) |
| Example 14 | BH-2 | ET-1 | 4.4 | 16.1 | 185 | Blue |
| Example 15 | BH-3 | ET-1 | 4.4 | 15.8 | 188 | Blue |
| Example 16 | BH-4 | ET-1 | 4.4 | 16.2 | 177 | Blue |
| Example 17 | BH-5 | ET-1 | 4.5 | 15.7 | 175 | Blue |
| Example 18 | BH-6 | ET-1 | 4.6 | 15.8 | 165 | Blue |
| Comparative | RH-1 | ET-1 | 5.5 | 9.6 | 77 | Blue |
| Example 3 | | | | | | |
| Comparative | RH-2 | ET-1 | 5.4 | 11.7 | 103 | Blue |
| Example 4 | | | | | | |

As shown in [Table 2], the device employing the compound according to the present invention as a light emitting layer host compound in the organic light emitting device may be embodied as a high-efficiency and long-lifetime organic light emitting device with excellent external quantum efficiency and lifetime properties at a low driving voltage compared to the devices (Comparative Examples 3 and 4) employing compounds widely used in the related art having structures in contrast to the characteristic structures of the organic compound according to the present invention.

### Examples 19 to 22: Manufacture of Organic Light Emitting Device

Organic light emitting devices were manufactured and experimented in the same manner as the organic light emitting devices used in Examples 1 to 13, except that the organic compound according to the present invention was used alone as the host in the light emitting layer. Luminous characteristics of the organic light emitting devices were measured at 0.4 mA, and the measurement results are shown in the following Table 3.

### Comparative Example 5: Manufacture of Organic Light Emitting Device

An organic light emitting device for a Comparative Example was manufactured in the same manner as in Examples, except that [RH-2] was used as the host compound instead of the organic compound according to the present invention in the device structure of Examples. Luminous characteristics of the organic light emitting device were measured at 0.4 mA, and the measurement results are shown in the following Table 3.

TABLE 3

| | | | External | | Light |
|---|---|---|---|---|---|
| | | Driving | Quantum | | Emitting |
| | | Voltage | Efficiency | Lifetime | Color |
| Category | Host | (V) | (EQE, %) | (T95, hr) | (Color) |
| Example 19 | BH-2 | 5.7 | 8.6 | 82 | Blue |
| Example 20 | BH-3 | 5.8 | 8.3 | 85 | Blue |
| Example 21 | BH-4 | 5.7 | 8.7 | 79 | Blue |
| Example 22 | BH-5 | 5.9 | 8.4 | 76 | Blue |
| Comparative | RH-2 | 6.5 | 5.7 | 42 | Blue |
| Example 5 | | | | | |

As shown in [Table 3], the device employing the compound according to the present invention as a light emitting layer host compound in the organic light emitting device may be embodied as a high-efficiency and long-lifetime organic light emitting device with excellent external quantum efficiency and lifetime properties at a low driving voltage compared to the device (Comparative Example 5) employing a compound widely used in the art having a structure in contrast to the characteristic structures of the organic compound according to the present invention.

What is claimed is:

1. An organic compound represented by the following [Formula 1]: 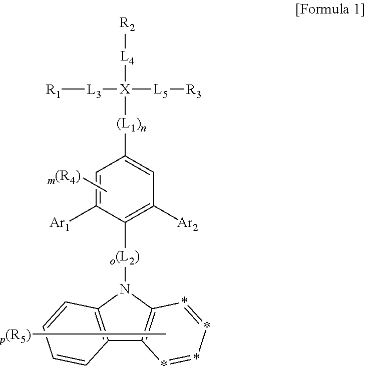
wherein, in [Formula 1],
X is Si or Ge;
R₁ to R₅ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted amine, substituted or unsubstituted silyl, substituted or unsubstituted germanium, and cyano;
Ar₁ and Ar₂ are the same as or different from each other, and each independently any one selected from substituted or unsubstituted C₁-C₃₀ alkyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, and substituted or unsubstituted cyclic groups in which a C₃-C₃₀ aliphatic ring and a C₅-C₃₀ aromatic ring are fused;
L₁ to L₅ are the same as or different from each other, and each independently a single bond, or any one selected from substituted or unsubstituted C₆-C₃₀ arylene, substituted or unsubstituted C₂-C₃₀ heteroarylene, and substituted or unsubstituted divalent cyclic groups in which a C₃-C₂₄ aliphatic ring and a C₅-C₂₄ aromatic ring are fused together; and
two adjacent carbon atoms represented by * in [Formula 1] are linked to sites represented by * of the following [Structural Formula A] to form a ring, (however, remaining two *s in [Formula 1] not forming a ring are substituted with R₅), 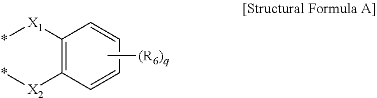
in [Structural Formula A],
X₁ and X₂ are the same as or different from each other, and each independently a single bond, or any one selected from O, S, Se, NR₇, CR₈R₉, SiR₁₀R₁₁ and GeR₁₂R₁₃;
R₆ to R₁₃ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted amine, substituted or unsubstituted silyl, substituted or unsubstituted germanium, and cyano;
m is an integer of 2, and R₄s are the same as or different from each other;
p is an integer of 6, and R₅s are the same as or different from each other;
q is an integer of 4, and R₆s are the same as or different from each other;
n and o are an integer of 1 to 3, and when they are each an integer of 2 or greater, L₁s and L₂s are the same as or different from each other;
when X₁ is a single bond, one of the carbon atoms represented by * in [Formula 1] is linked to a carbon atom of benzene linked to X₁ in [Structural Formula A] through the single bond;
when X₂ is a single bond, one of the carbon atoms represented by * in [Formula 1] is linked to a carbon atom of benzene linked to X₂ in [Structural Formula A] through the single bond;
the adjacent plurality of R₅s and R₆s are optionally linked to each other to further form an alicyclic or aromatic monocyclic or polycyclic ring;
R₈ and R₉, R₁₀ and R₁₁, and R₁₂ are R₁₃ are optionally linked to each other to further form an alicyclic or aromatic monocyclic or polycyclic ring; and
the term ‘substituted’ in the ‘substituted or unsubstituted’ in [Formula 1] and [Structural Formula A] means being substituted with one, or two or more substituents selected from the group consisting of deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl and nitro, or being substituted with a substituent in which two or more of the above-mentioned substituents are linked, and hydrogen atoms in the substituents are optionally substituted with one or more deuterium atoms, and two or more adjacent ones of the substituents are optionally linked to each other to further form an alicyclic or aromatic monocyclic or polycyclic ring.

2. The organic compound according to claim 1, wherein Ar₁ and Ar₂ are the same as or different from each other, and each independently any one selected from substituted or unsubstituted C₆-C₃₀ aryl, substituted or unsubstituted C₂-C₃₀ heteroaryl, and substituted or unsubstituted cyclic groups in which a C₃-C₂₄ aliphatic ring and a C₅-C₂₄ aromatic ring are fused together.

3. The organic compound according to claim 1, wherein R₁ to R₃ are the same as or different from each other, and each independently any one selected from substituted or unsubstituted C₆-C₃₀ aryl, substituted or unsubstituted C₂-C₃₀ heteroaryl, and substituted or unsubstituted cyclic groups in which a C₃-C₂₄ aliphatic ring and a C₅-C₂₄ aromatic ring are fused together.

4. The organic compound according to claim 1, wherein at least one of X₁ and X₂ is a single bond.

5. The organic compound according to claim 4, wherein at least one of X₁ and X₂ is O or S.

6. The organic compound according to claim 1, wherein R₄ to R₆ are the same as or different from each other, and each independently hydrogen or deuterium.

7. The organic compound according to claim 1, wherein the organic compound represented by [Formula 1] is represented by the following [Formula 1-1] to [Formula 1-12]: 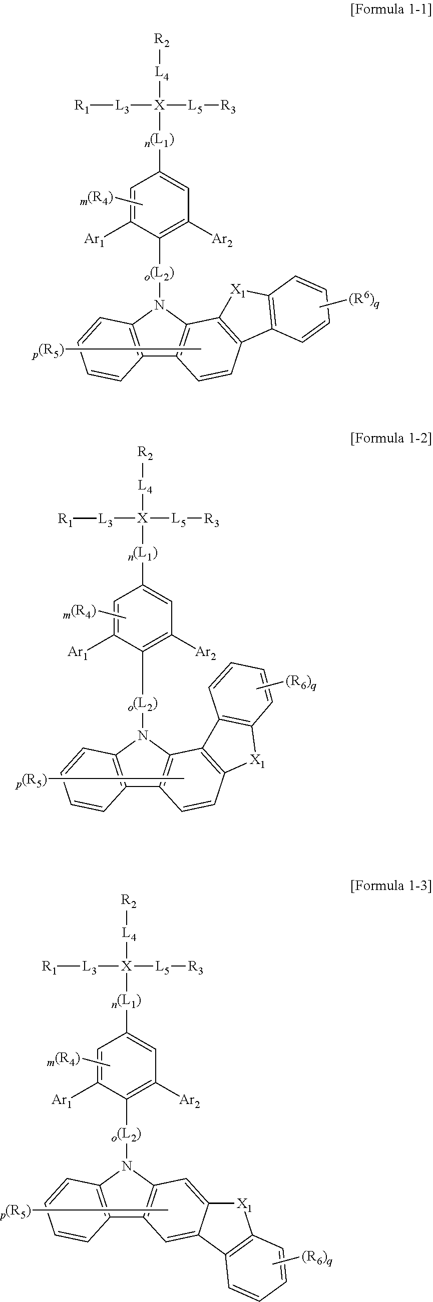 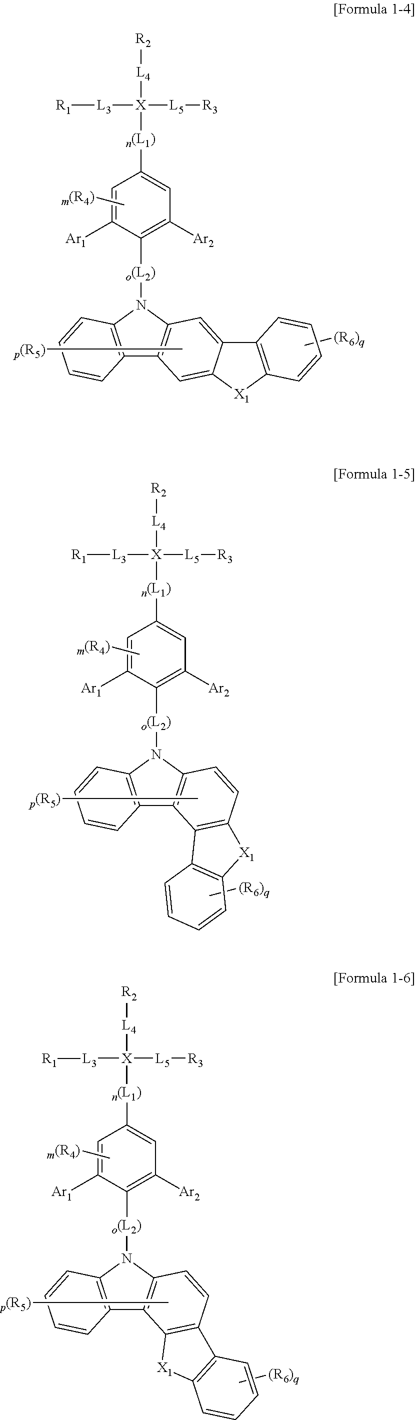 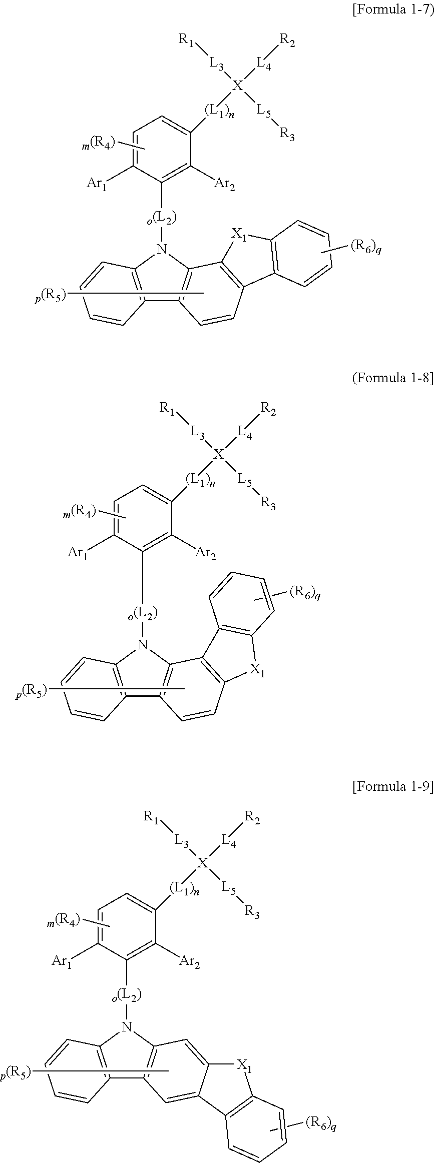 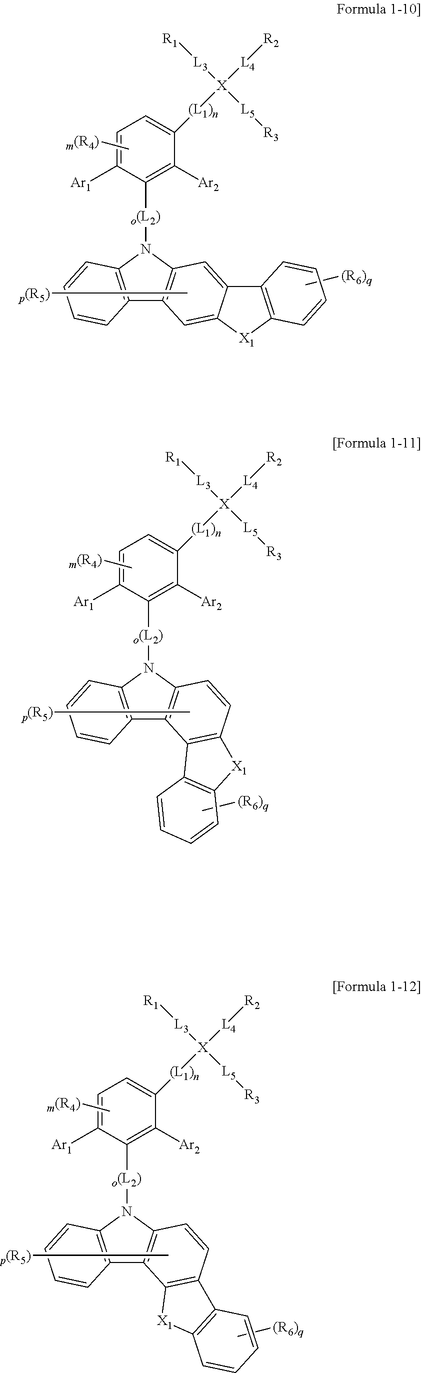
in [Formula 1-1] to [Formula 1-12],
X is Si or Ge;
X₁s are each independently any one selected from O, S, Se, NR₇, CR₈R₉, SiR₁₀R₁₁ and GeR₁₂R₁₃;
R₁ to R₁₃ are the same as or different from each other, and each independently any one selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, substituted or unsubstituted cyclic groups in which a C₃-C₃₀ aliphatic ring and a C₅-C₃₀ aromatic ring are fused together, substituted or unsubstituted amine, substituted or unsubstituted silyl, substituted or unsubstituted germanium, and cyano;
Ar₁ and Ar₂ are the same as or different from each other, and each independently any one selected from substituted or unsubstituted C₁-C₃₀ alkyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, and substituted or unsubstituted cyclic groups in which a C₃-C₃₀ aliphatic ring and a C₅-C₃₀ aromatic ring are fused together;
L₁ to L₅ are the same as or different from each other, and each independently a single bond, or any one selected from substituted or unsubstituted C₆-C₃₀ arylene, substituted or unsubstituted C₂-C₃₀ heteroarylene, and substituted or unsubstituted divalent cyclic groups in which a C₃-C₂₄ aliphatic ring and a C₅-C₂₄ aromatic ring are fused together;
m is an integer of 2, and R₄s are the same as or different from each other;
p is an integer of 6, and R₅s are the same as or different from each other;
q is an integer of 4, and R₆s are the same as or different from each other;
n and o are an integer of 1 to 3, and when they are each an integer of 2 or greater, L₁s and L₂s are the same as or different from each other;
the adjacent plurality of R₅s and R₆s are optionally linked to each other to further form an alicyclic or aromatic monocyclic or polycyclic ring;
R₈ and R₉, R₁₀ and R₁₁, and R₁₂ and R₁₃ are optionally linked to each other to further form an alicyclic or aromatic monocyclic or polycyclic ring; and
the term ‘substituted’ in the ‘substituted or unsubstituted’ in [Formula 1-1] to [Formula 1-12] means being substituted with one, or two or more substituents selected from the group consisting of deuterium, C₁-C₂₄ alkyl, C₁-C₂₄ haloalkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arylthionyl, cyano, halogen, hydroxyl and nitro, or being substituted with a substituent in which two or more of the above-mentioned substituents are linked, and hydrogen atoms in the substituents are optionally substituted with one or more deuterium atoms, and two or more adjacent ones of the substituents are optionally linked to each other to further form an alicyclic or aromatic monocyclic or polycyclic ring.

8. The organic compound according to claim 1, wherein [Formula 1] is any one selected from compounds represented by the following formulae:

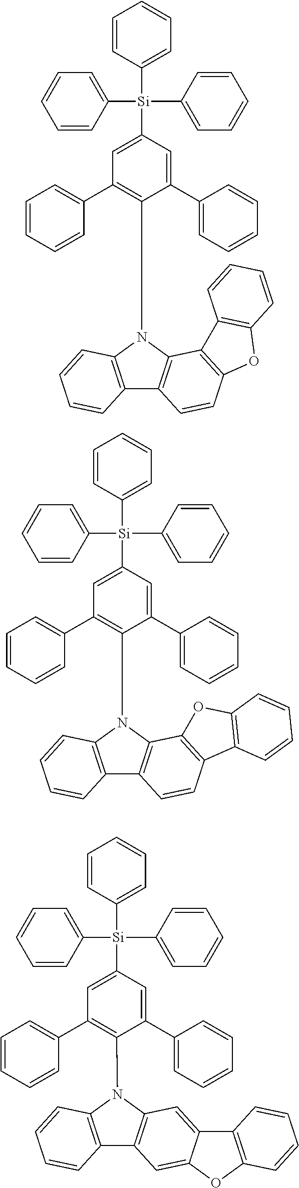

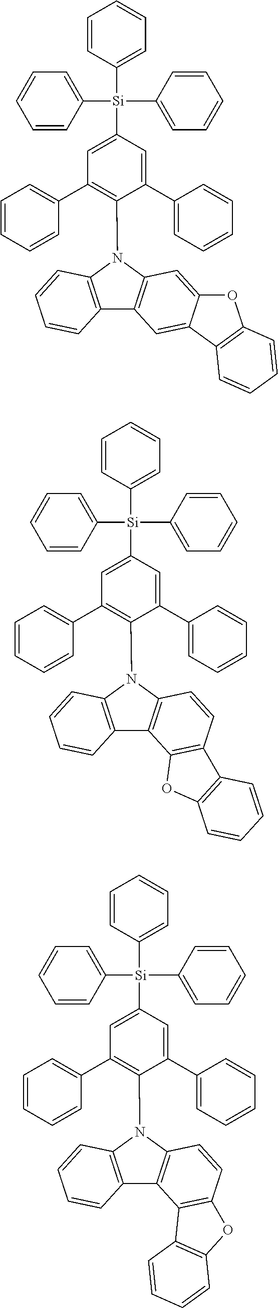 [SMILES: c1ccc(-c2cc([Si](c3ccccc3)(c3ccccc3)c3ccccc3)cc(-c3ccccc3)c2-n2c3ccccc3c3cc4c(cc32)oc2ccccc24)cc1 ; c1ccc(-c2cc([Si](c3ccccc3)(c3ccccc3)c3ccccc3)cc(-c3ccccc3)c2-n2c3ccccc3c3c4oc5ccccc5c4ccc32)cc1 ; c1ccc(-c2cc([Si](c3ccccc3)(c3ccccc3)c3ccccc3)cc(-c3ccccc3)c2-n2c3ccccc3c3c4c(ccc32)oc2ccccc24)cc1]

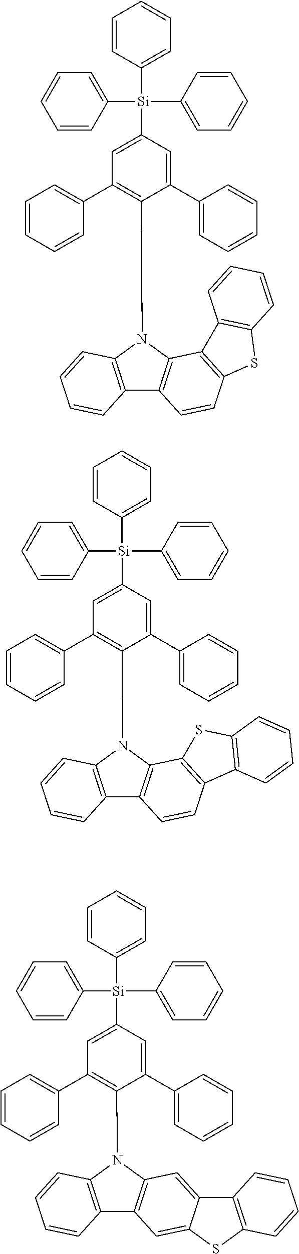

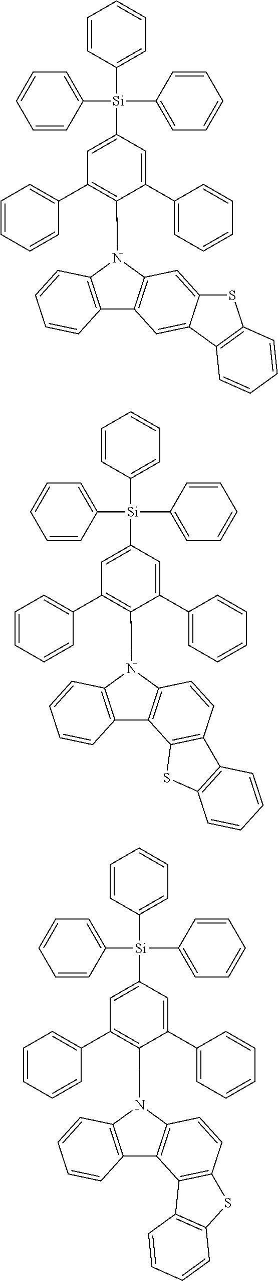 [SMILES: c1ccc(-c2cc([Si](c3ccccc3)(c3ccccc3)c3ccccc3)cc(-c3ccccc3)c2-n2c3ccccc3c3cc4c(cc32)sc2ccccc24)cc1 ; c1ccc(-c2cc([Si](c3ccccc3)(c3ccccc3)c3ccccc3)cc(-c3ccccc3)c2-n2c3ccccc3c3c4sc5ccccc5c4ccc32)cc1 ; c1ccc(-c2cc([Si](c3ccccc3)(c3ccccc3)c3ccccc3)cc(-c3ccccc3)c2-n2c3ccccc3c3c4c(ccc32)sc2ccccc24)cc1]

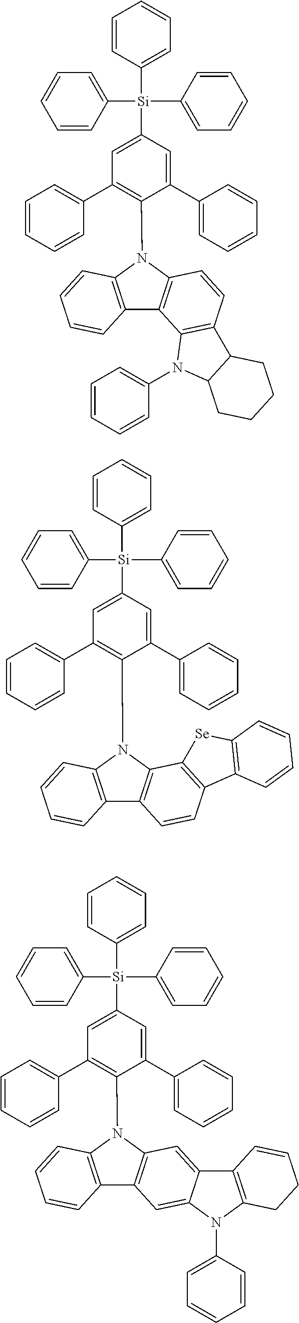

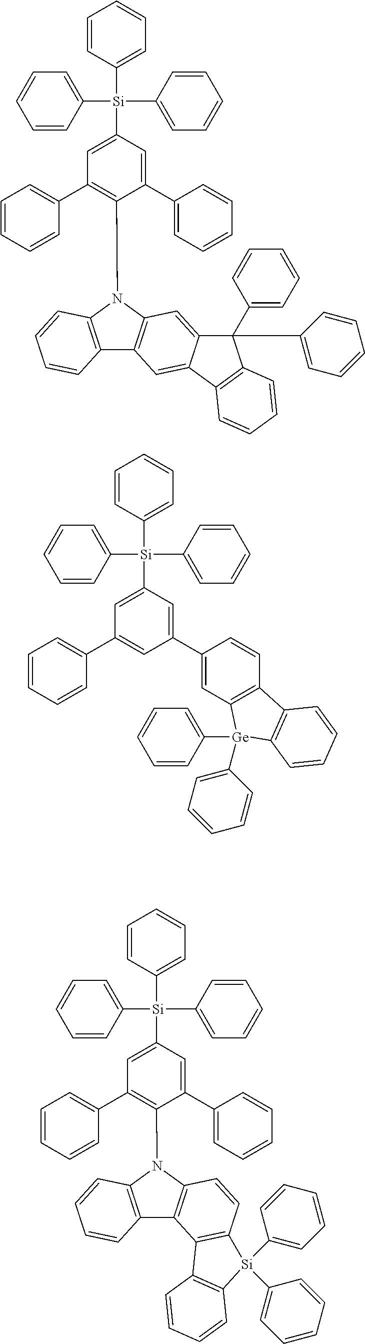

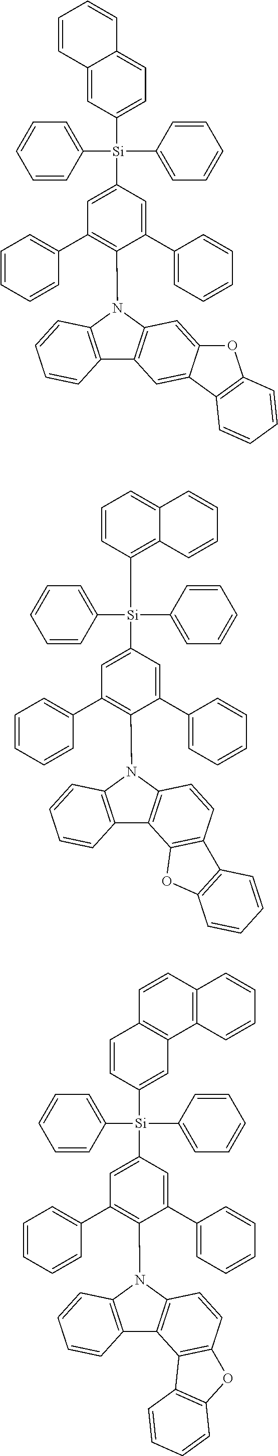

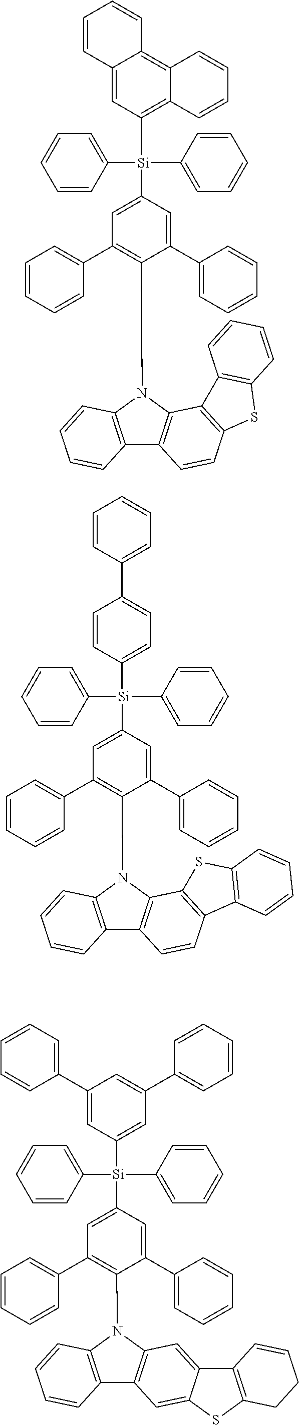

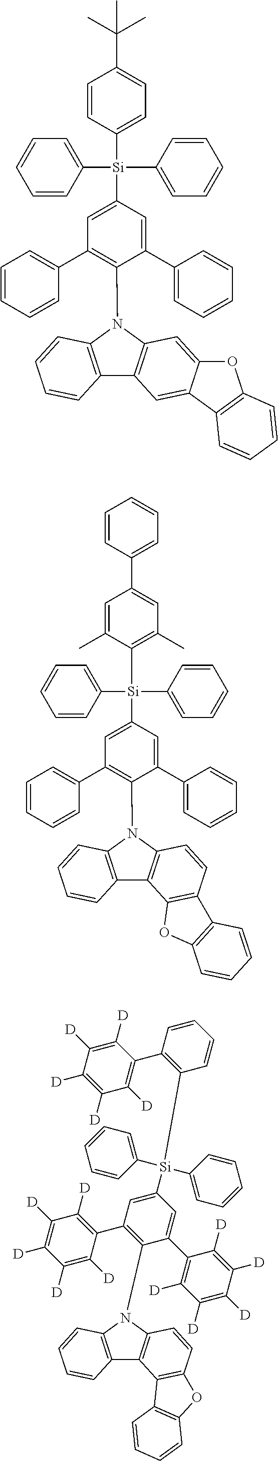 [SMILES: CC(C)(C)c1ccc([Si](c2ccccc2)(c2ccccc2)c2cc(-c3ccccc3)c(-n3c4ccccc4c4cc5c(cc43)oc3ccccc35)c(-c3ccccc3)c2)cc1 ; Cc1cc(-c2ccccc2)cc(C)c1[Si](c1ccccc1)(c1ccccc1)c1cc(-c2ccccc2)c(-n2c3ccccc3c3c4oc5ccccc5c4ccc32)c(-c2ccccc2)c1 ; [2H]c1c([2H])c([2H])c(-c2ccccc2[Si](c2ccccc2)(c2ccccc2)c2cc(-c3c([2H])c([2H])c([2H])c([2H])c3[2H])c(-n3c4ccccc4c4c5c(ccc43)oc3ccccc35)c(-c3c([2H])c([2H])c([2H])c([2H])c3[2H])c2)c([2H])c1[2H]]

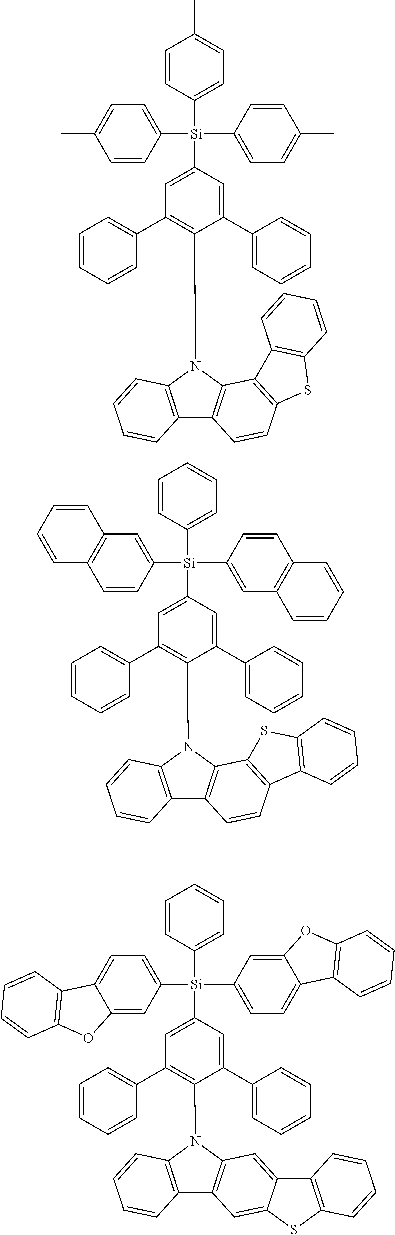

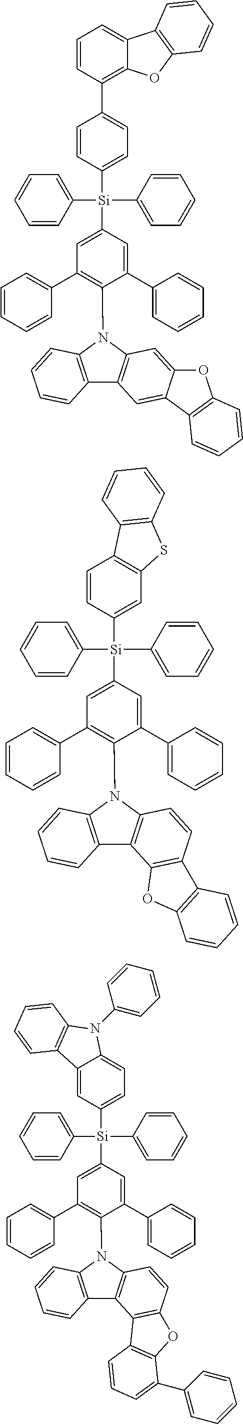 [SMILES: c1ccc(-c2cc([Si](c3ccccc3)(c3ccccc3)c3ccc(-c4cccc5c4oc4ccccc45)cc3)cc(-c3ccccc3)c2-n2c3ccccc3c3cc4c(cc32)oc2ccccc24)cc1 ; c1ccc(-c2cc([Si](c3ccccc3)(c3ccccc3)c3ccc4c(c3)sc3ccccc34)cc(-c3ccccc3)c2-n2c3ccccc3c3c4oc5ccccc5c4ccc32)cc1 ; c1ccc(-c2cc([Si](c3ccccc3)(c3ccccc3)c3ccc4c(c3)c3ccccc3n4-c3ccccc3)cc(-c3ccccc3)c2-n2c3ccccc3c3c4c(ccc32)oc2c(-c3ccccc3)cccc24)cc1]

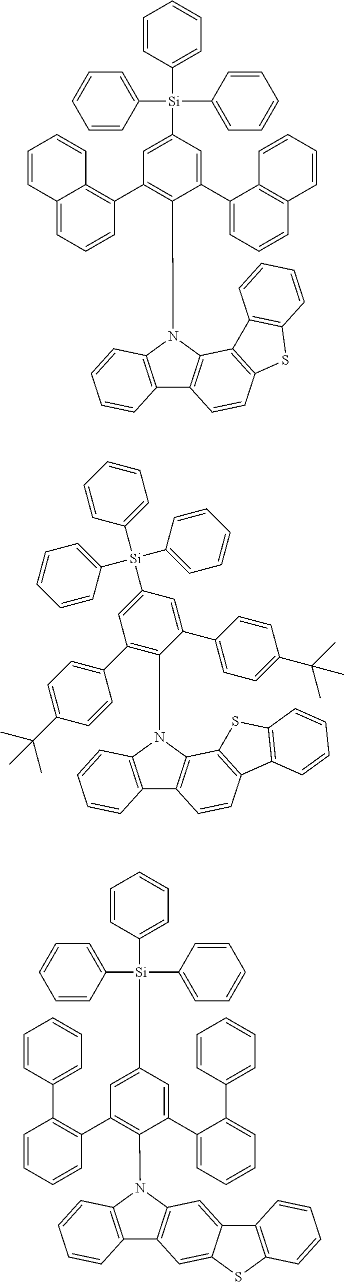 [SMILES: c1ccc([Si](c2ccccc2)(c2ccccc2)c2cc(-c3cccc4ccccc34)c(-n3c4ccccc4c4ccc5sc6ccccc6c5c43)c(-c3cccc4ccccc34)c2)cc1 ; CC(C)(C)c1ccc(-c2cc([Si](c3ccccc3)(c3ccccc3)c3ccccc3)cc(-c3ccc(C(C)(C)C)cc3)c2-n2c3ccccc3c3ccc4c5ccccc5sc4c32)cc1 ; c1ccc(-c2ccccc2-c2cc([Si](c3ccccc3)(c3ccccc3)c3ccccc3)cc(-c3ccccc3-c3ccccc3)c2-n2c3ccccc3c3cc4sc5ccccc5c4cc32)cc1]

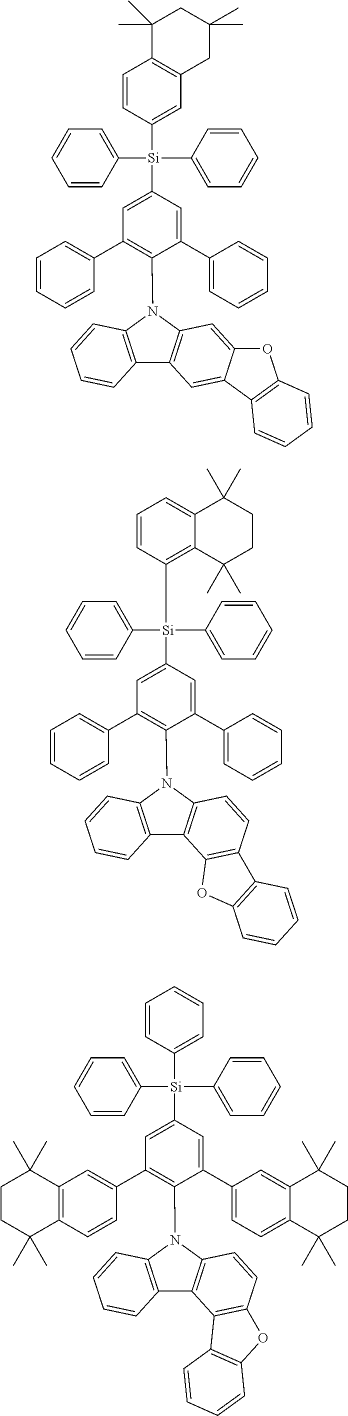

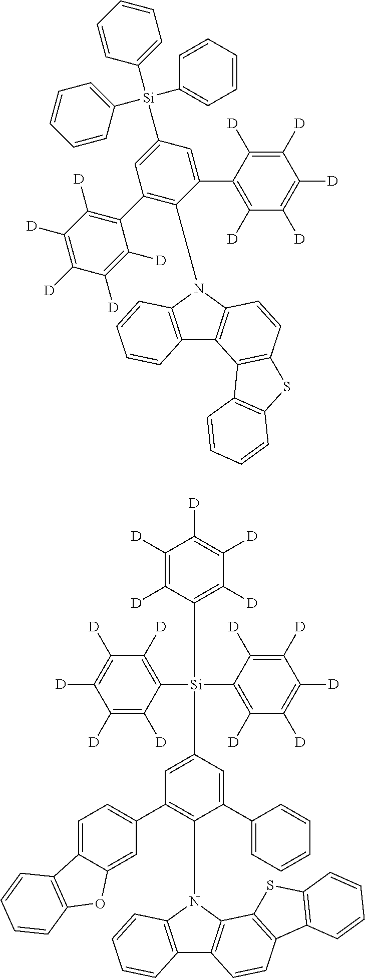 [SMILES: [2H]c1c([2H])c([2H])c(-c2cc([Si](c3ccccc3)(c3ccccc3)c3ccccc3)cc(-c3c([2H])c([2H])c([2H])c([2H])c3[2H])c2-n2c3ccccc3c3c4c(ccc32)sc2ccccc24)c([2H])c1[2H] ; [2H]c1c([2H])c([2H])c([Si](c2cc(-c3ccccc3)c(-n3c4ccccc4c4ccc5c6ccccc6sc5c43)c(-c3ccc4c(c3)oc3ccccc34)c2)(c2c([2H])c([2H])c([2H])c([2H])c2[2H])c2c([2H])c([2H])c([2H])c([2H])c2[2H])c([2H])c1[2H]]

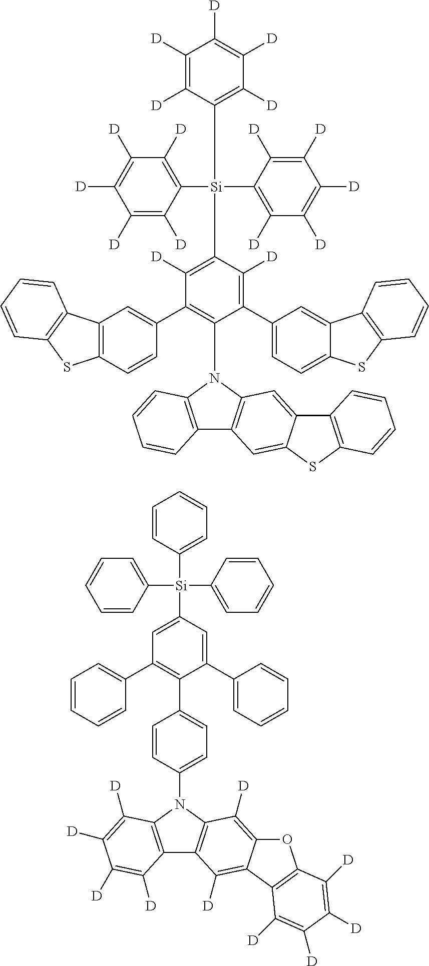

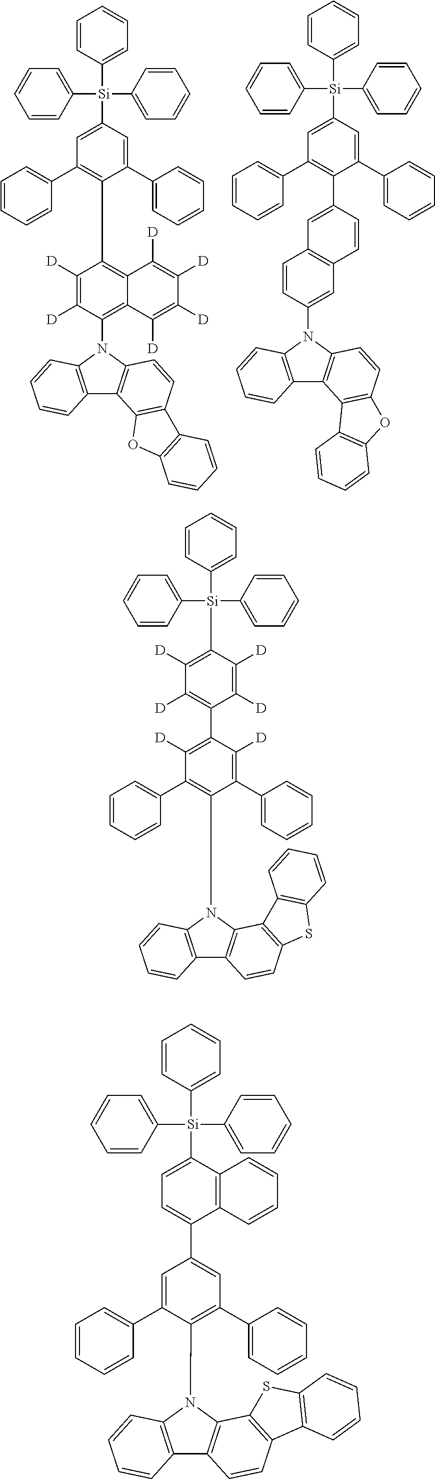

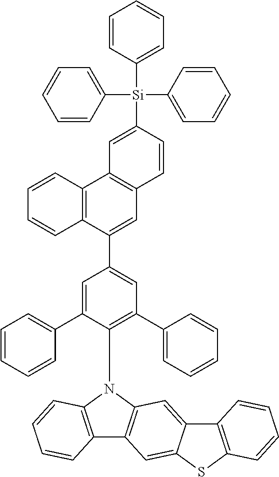 [SMILES: c1ccc(-c2cc(-c3cc4ccc([Si](c5ccccc5)(c5ccccc5)c5ccccc5)cc4c4ccccc34)cc(-c3ccccc3)c2-n2c3ccccc3c3cc4sc5ccccc5c4cc32)cc1]

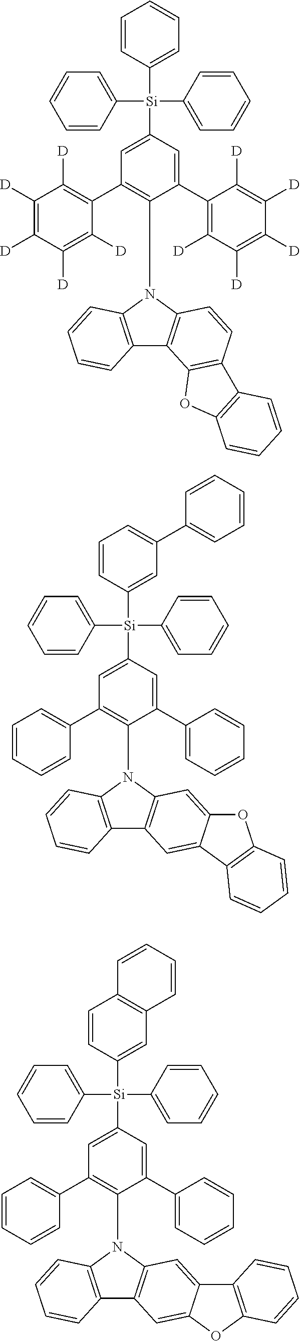

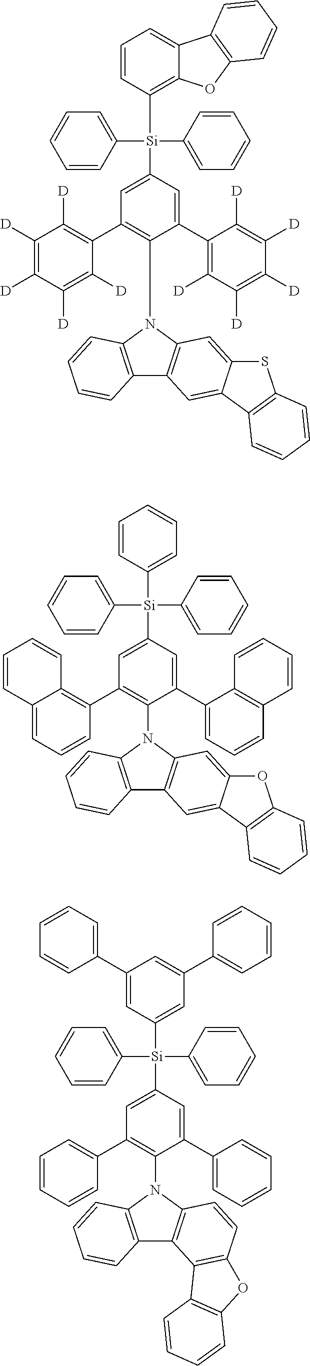

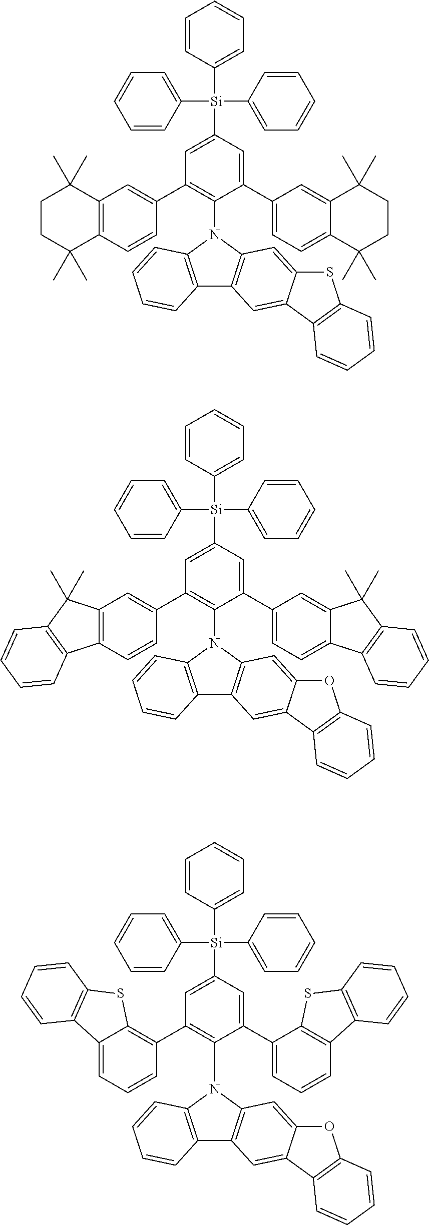 [SMILES: CC1(C)CCC(C)(C)c2cc(-c3cc([Si](c4ccccc4)(c4ccccc4)c4ccccc4)cc(-c4ccc5c(c4)C(C)(C)CCC5(C)C)c3-n3c4ccccc4c4cc5c(cc43)sc3ccccc35)ccc21 ; CC1(C)c2ccccc2-c2ccc(-c3cc([Si](c4ccccc4)(c4ccccc4)c4ccccc4)cc(-c4ccc5c(c4)C(C)(C)c4ccccc4-5)c3-n3c4ccccc4c4cc5c(cc43)oc3ccccc35)cc21 ; c1ccc([Si](c2ccccc2)(c2ccccc2)c2cc(-c3cccc4c3sc3ccccc34)c(-n3c4ccccc4c4cc5c(cc43)oc3ccccc35)c(-c3cccc4c3sc3ccccc34)c2)cc1]

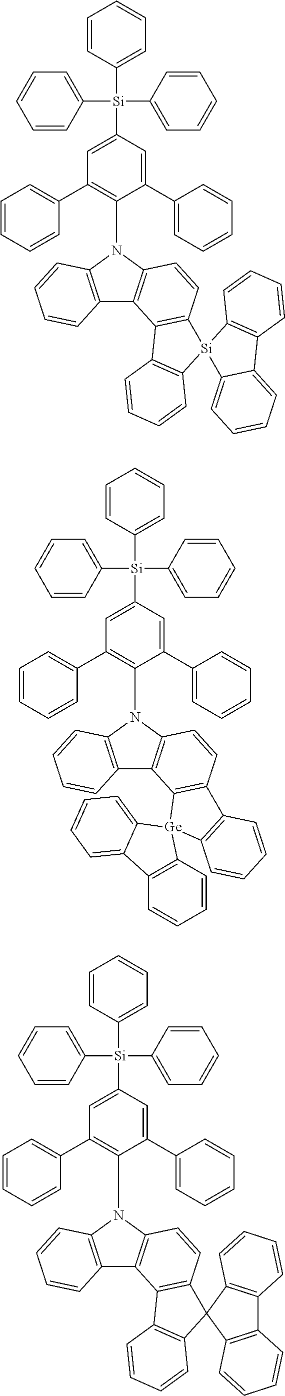

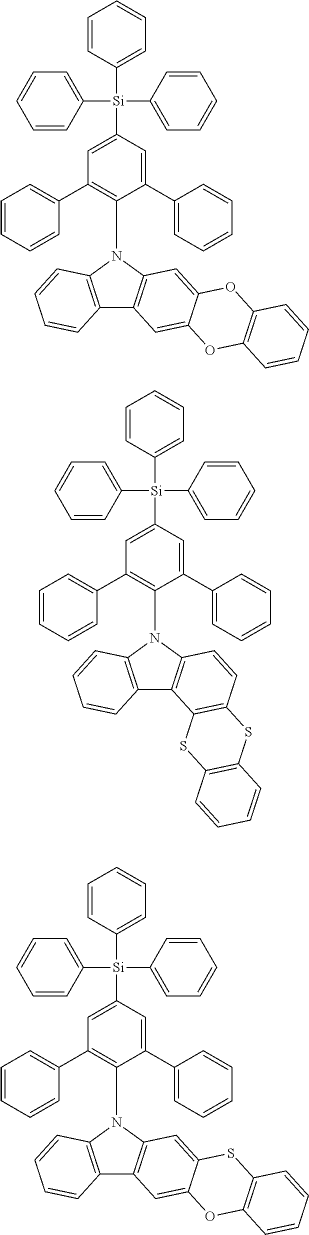 [SMILES: c1ccc(-c2cc([Si](c3ccccc3)(c3ccccc3)c3ccccc3)cc(-c3ccccc3)c2-n2c3ccccc3c3cc4c(cc32)Oc2ccccc2O4)cc1 ; c1ccc(-c2cc([Si](c3ccccc3)(c3ccccc3)c3ccccc3)cc(-c3ccccc3)c2-n2c3ccccc3c3c4c(ccc32)Sc2ccccc2S4)cc1 ; c1ccc(-c2cc([Si](c3ccccc3)(c3ccccc3)c3ccccc3)cc(-c3ccccc3)c2-n2c3ccccc3c3cc4c(cc32)Sc2ccccc2O4)cc1]

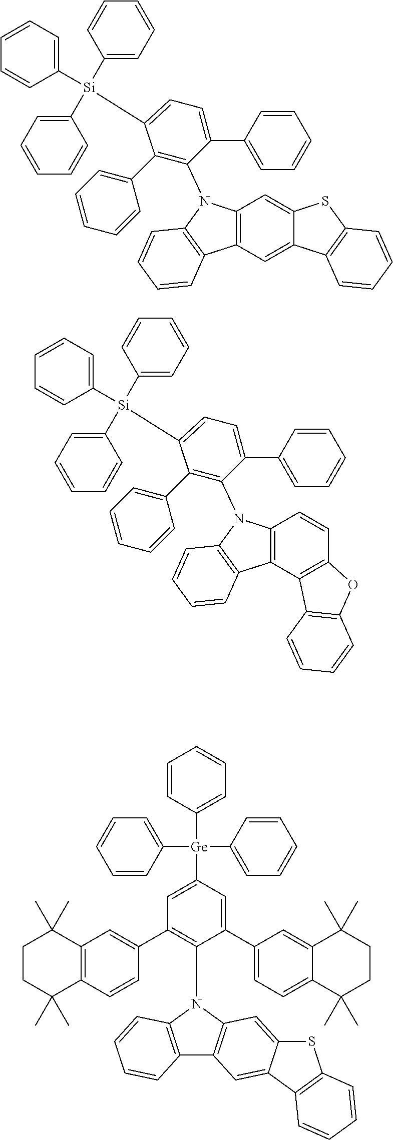

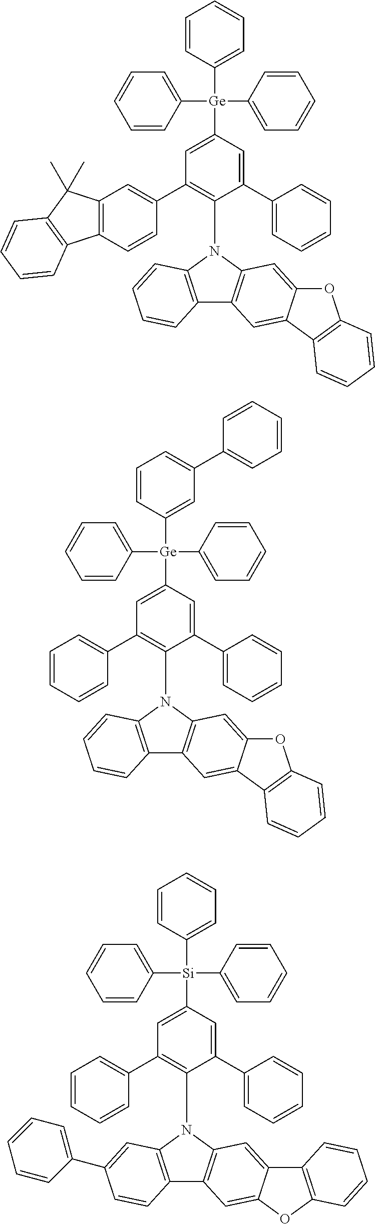

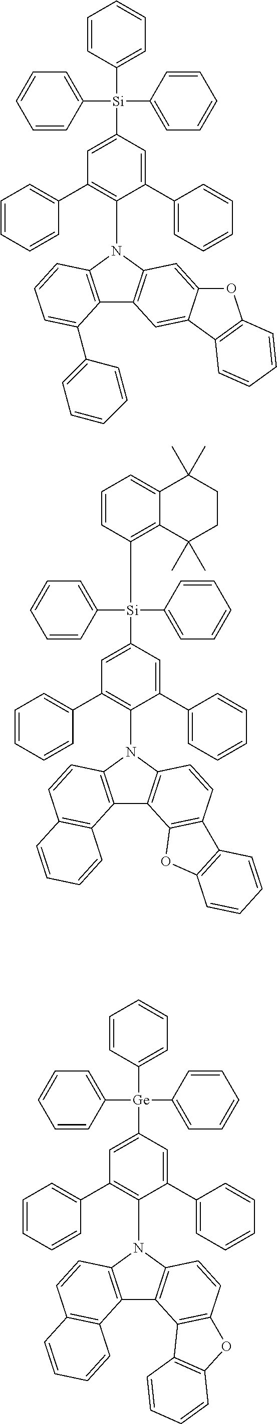

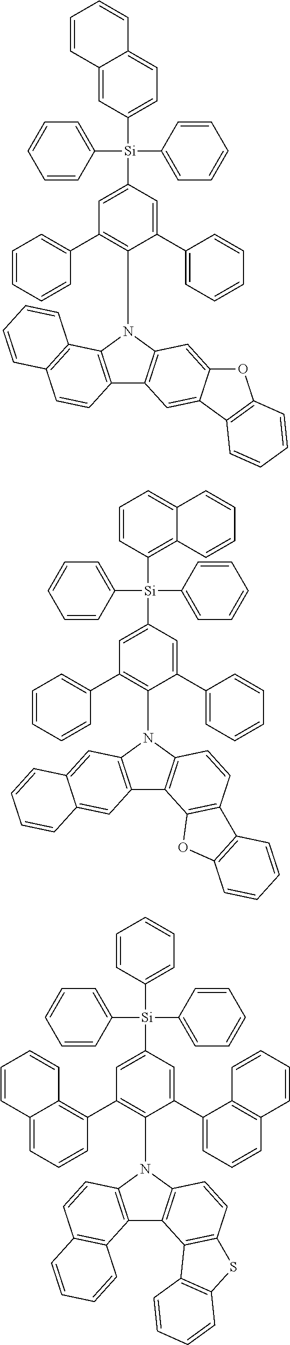

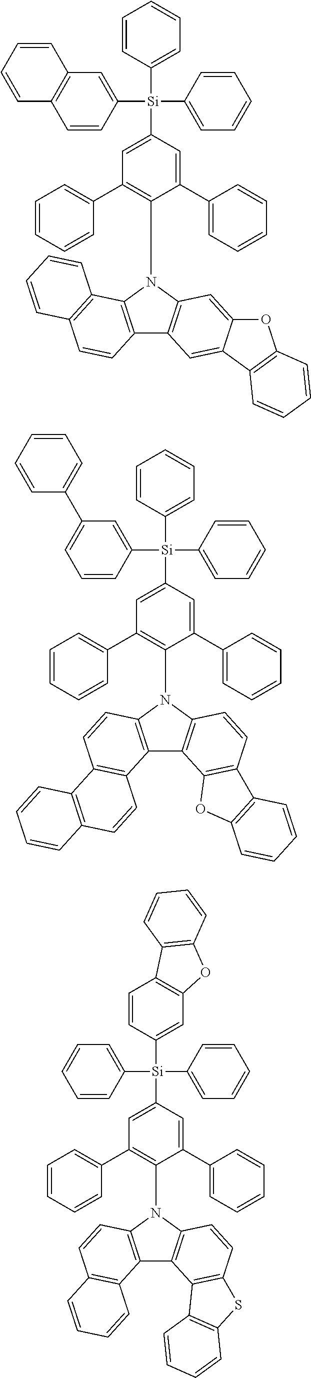 [SMILES: c1ccc(-c2cc([Si](c3ccccc3)(c3ccccc3)c3ccc4ccccc4c3)cc(-c3ccccc3)c2-n2c3cc4oc5ccccc5c4cc3c3ccc4ccccc4c32)cc1 ; c1ccc(-c2cccc([Si](c3ccccc3)(c3ccccc3)c3cc(-c4ccccc4)c(-n4c5ccc6c7ccccc7ccc6c5c5c6oc7ccccc7c6ccc54)c(-c4ccccc4)c3)c2)cc1 ; c1ccc(-c2cc([Si](c3ccccc3)(c3ccccc3)c3ccc4c(c3)oc3ccccc34)cc(-c3ccccc3)c2-n2c3ccc4ccccc4c3c3c4c(ccc32)sc2ccccc24)cc1]

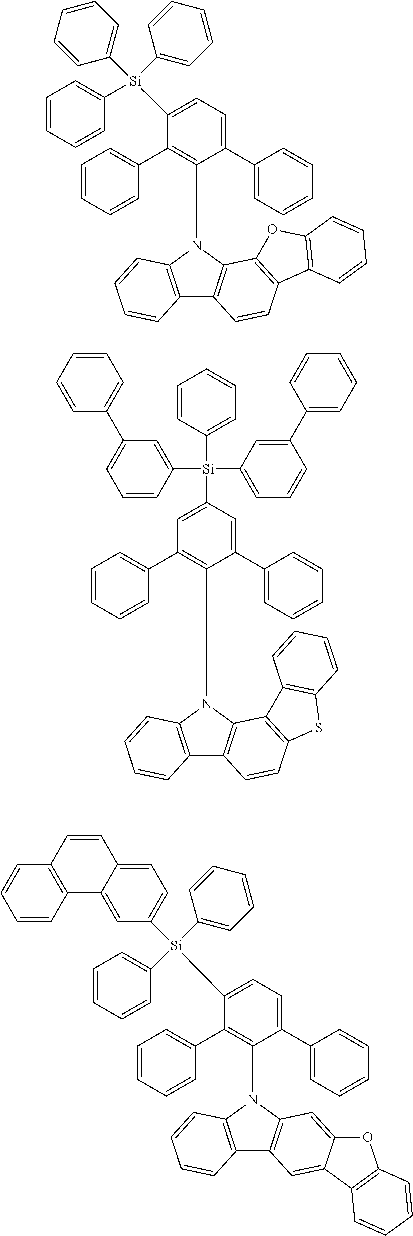

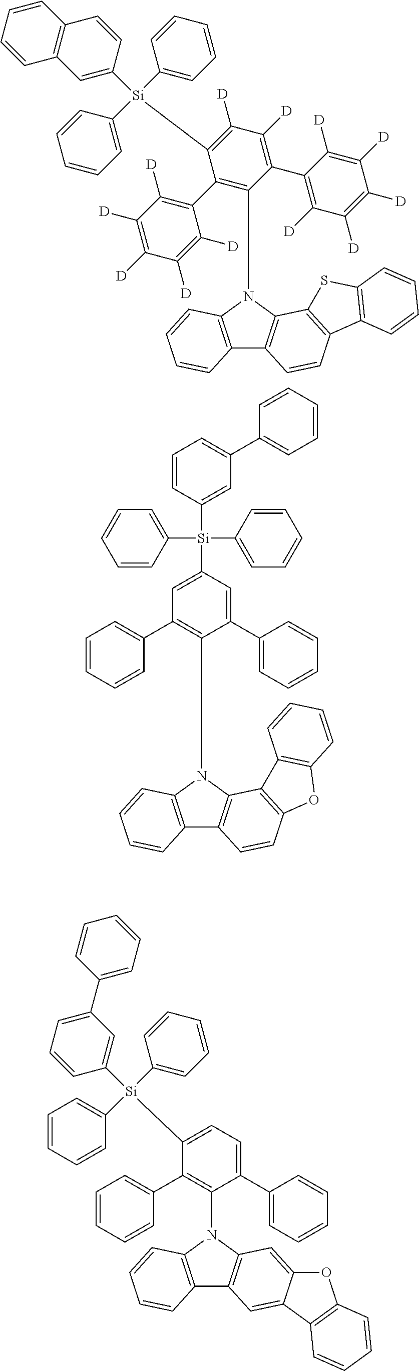

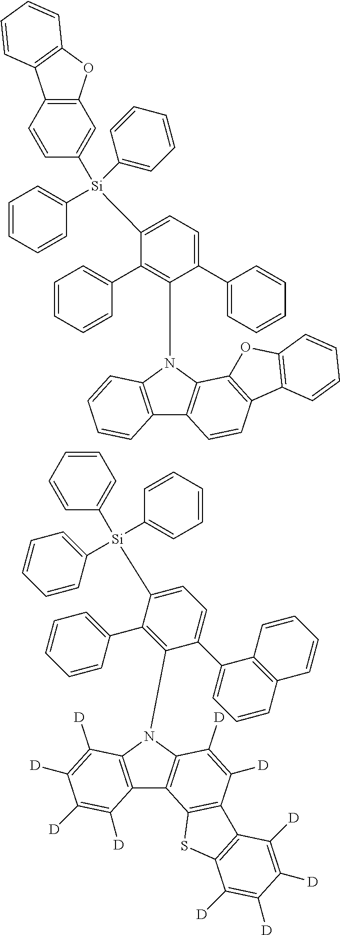

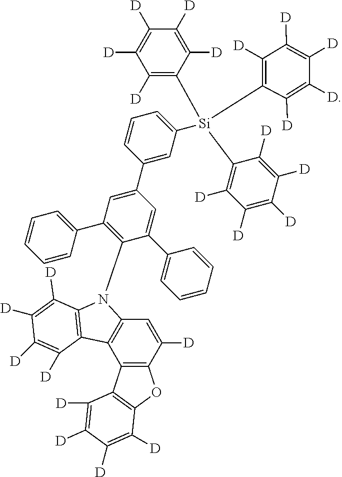

9. An organic light emitting device comprising:
a first electrode;
a second electrode opposite to the first electrode; and
an organic layer interposed between the first electrode and the second electrode,
wherein the organic layer comprises a light emitting layer comprising a host and a dopant; and
the host comprises at least one type of the organic compound represented by [Formula 1] according to claim 1.

10. The organic light emitting device according to claim 9, wherein the host is used by mixing and laminating one or more types of other compounds in addition to the one type of the organic compound represented by [Formula 1].

11. The organic light emitting device according to claim 9, wherein the organic compound represented by Formula 1 is used as a host that emits blue phosphorescence.

12. The organic light emitting device according to claim 9, wherein the dopant comprises at least one organometallic compound.

13. The organic light emitting device according to claim 12, wherein the light emitting layer further comprises one or more dopants other than the organometallic compound and wherein the two or more dopants are mixed or stacked in the light emitting layer.

14. The organic light emitting device according to claim 13, wherein one of the additional dopants is a polycyclic compound represented by Formula 3: 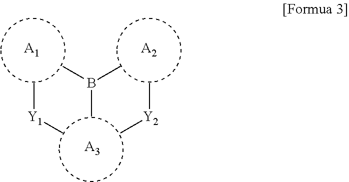
wherein Y₁ and Y₂ are the same as or different from each other and are each independently selected from O, S, NR₃₁, CR₃₂R₃₃, SiR₃₄R₃₅, and GeR₃₆R₃₇, A₁ to A₃ are the same as or different from each other and are each independently selected from substituted or unsubstituted C₆-C₃₀ aromatic hydrocarbon rings, substituted or unsubstituted C₃-C₃₀ aliphatic hydrocarbon rings, substituted or unsubstituted C₂-C₃₀ aromatic heterocyclic rings, substituted or unsubstituted C₂-C₃₀ aliphatic heterocyclic rings, and cyclic groups in which a substituted or unsubstituted C₃-C₂₄ aliphatic ring and a C₅-C₂₄ aromatic ring are fused together, R₃₁ to R₃₇ are the same as or different from each other and are each independently selected from hydrogen, deuterium, substituted or unsubstituted C₁-C₃₀ alkyl, substituted or unsubstituted C₂-C₃₀ alkynyl, substituted or unsubstituted C₂-C₃₀ alkenyl, substituted or unsubstituted C₆-C₅₀ aryl, substituted or unsubstituted C₃-C₅₀ cycloalkyl, substituted or unsubstituted C₂-C₅₀ heterocycloalkyl, substituted or unsubstituted C₂-C₅₀ heteroaryl, cyclic groups in which a substituted or unsubstituted C₃-C₃₀ aliphatic ring and a C₅-C₃₀ aromatic ring are fused together, substituted or unsubstituted C₁-C₃₀ alkoxy, substituted or unsubstituted C₆-C₃₀ aryloxy, substituted or unsubstituted C₁-C₃₀ alkylthioxy, substituted or unsubstituted C₅-C₃₀ arylthioxy, substituted or unsubstituted amine, substituted or unsubstituted silyl, substituted or unsubstituted germanium, nitro, cyano, and halogen, with the proviso that each of R₃₁ to R₃₇ is optionally linked to one or more of the C₁ to C₃ rings to form an alicyclic or aromatic monocyclic or polycyclic ring, R₃₂ and R₁₃ are optionally linked to each other to form an alicyclic or aromatic monocyclic or polycyclic ring, R₃₄ and R₃₅ are optionally linked to each other to form an alicyclic or aromatic monocyclic or polycyclic ring, and R₃₆ and R₃₇ are optionally linked to each other to form an alicyclic or aromatic monocyclic or polycyclic ring, the “substituted” in the definitions of Y₁, Y₂, and C₁ to C₃ in Formula 4 indicating substitution with one or more substituents selected from deuterium, C₁-C₂₄ alkyl, C₂-C₂₄ alkenyl, C₂-C₂₄ alkynyl, C₃-C₃₀ cycloalkyl, C₁-C₂₄ heteroalkyl, C₆-C₃₀ aryl, C₇-C₃₀ arylalkyl, C₇-C₃₀ alkylaryl, C₂-C₃₀ heteroaryl, C₂-C₃₀ heteroarylalkyl, cyclic groups in which a substituted or unsubstituted C₃-C₂₄ aliphatic ring and a C₅-C₂₄ aromatic ring are fused together, C₁-C₂₄ alkoxy, C₁-C₃₀ amine, C₁-C₃₀ silyl, C₁-C₃₀ germanium, C₆-C₂₄ aryloxy, C₆-C₂₄ arythionyl, cyano, halogen, hydroxyl, and nitro, or a combination thereof, provided that when substituted with two or more substituents, the substituents are identical to or different from each other, the “unsubstituted” in the same definition indicating having no substituent, and one or more hydrogen atoms in each of the substituents being optionally replaced by deuterium atoms.

15. The organic light emitting device according to claim 9, wherein the organic light emitting device is used in a display or lighting system selected from flat panel displays, flexible displays, monochromatic flat panel lighting systems, white flat panel lighting systems, flexible monochromatic lighting systems, flexible white lighting systems, displays for automotive applications, displays for virtual reality, and displays for augmented reality.
